(19) United States
(12) Patent Application Publication
(10) Pub. No.: US 2026/0020325 A1
(43) Pub. Date: Jan. 15, 2026

(54) SEMICONDUCTOR DEVICE

(71) Applicant: ROHM CO., LTD., Kyoto (JP)

(72) Inventors: Nozomu NISHIURA, Kyoto (JP); Kentaro NASU, Kyoto (JP); Satoki TANIGUCHI, Kyoto (JP); Kohei MORITA, Kyoto (JP)

(73) Assignee: ROHM CO., LTD., Kyoto (JP)

(21) Appl. No.: 19/337,807

(22) Filed: Sep. 23, 2025

(30) Foreign Application Priority Data
Mar. 30, 2023 (JP) 2023-056606
Mar. 30, 2023 (JP) 2023-056607
Mar. 30, 2023 (JP) 2023-056608
Mar. 30, 2023 (JP) 2023-056609
Mar. 30, 2023 (JP) 2023-056614

(51) Int. Cl. H10D 84/00; H10D 84/01

(52) U.S. Cl. CPC H10D 84/144; H10D 84/0109

(57) ABSTRACT

A semiconductor device includes: a semiconductor chip including a single layer having a first principal surface and a second principal surface on an opposite side to the first principal surface; a first semiconductor region of a first conductivity type formed on the first principal surface side of the semiconductor chip; a second semiconductor region of a second conductivity type formed on the second principal surface side with respect to the first semiconductor region of the semiconductor chip; and a first trench structure including a first trench that penetrates the first semiconductor region from the first principal surface and partitions the first semiconductor region into a first region on one side and a second region on the other side in a cross-sectional view, a control insulating film that covers an inner wall of the first trench, and a control electrode that is embedded in the first trench with the control insulating film interposed therebetween and controls a channel in the second semiconductor region that makes the first region and the second region conductive in a lateral direction along the first principal surface.

### CROSS REFERENCE TO RELATED APPLICATIONS

The present application is a bypass continuation application of International Patent Application No. PCT/JP2024/007832, filed on Mar. 1, 2024, which corresponds to Japanese Patent Applications No. 2023-056606, No. 2023-056607, No. 2023-056608, No. 2023-056609, No. 2023-056614, filed on Mar. 30, 2023 with the Japan Patent Office, and the entire disclosures of these application are incorporated herein by reference.

### TECHNICAL FIELD

The present disclosure relates to a semiconductor device.

### BACKGROUND ART

Patent Literature 1 (WO 2021/065740 A) discloses a semiconductor device including a semiconductor chip having a first principal surface, an n-type drift layer formed in a surface layer portion of the first principal surface, a trench gate structure formed in the first principal surface to be in contact with the drift layer, a p-type channel region formed in the drift layer to cover a side wall of the trench gate structure, and a first source/drain region and a second source/drain region formed at intervals in a region along the side wall of the trench gate structure in the drift layer to oppose each other with the channel region interposed therebetween.

### BRIEF DESCRIPTION OF DRAWINGS

FIG. 1 is a circuit diagram of a semiconductor device according to a first preferred embodiment of the present disclosure.

FIG. 2 is a schematic perspective view of the semiconductor device according to the first preferred embodiment of the present disclosure.

FIG. 3 is a plan view of the semiconductor device of FIG. 2.

FIG. 4 is a plan view illustrating an internal structure of the semiconductor device in FIG. 2.

FIG. 5 is a plan view illustrating an internal structure of the semiconductor device in FIG. 2.

FIG. 6 is a plan view illustrating an internal structure of the semiconductor device in FIG. 2.

FIG. 7 is a plan view illustrating an internal structure of the semiconductor device in FIG. 2.

FIG. 8 is an enlarged view of a part surrounded by a two-dot chain line VIII in FIG. 4.

FIG. 9 is a cross-sectional view taken along line IX-IX of FIG. 8.

FIG. 10 is a cross-sectional view taken along line X-X of FIG. 8.

FIG. 11 is a cross-sectional view taken along line XI-XI of FIG. 8.

FIG. 12 is a cross-sectional view taken along line XII-XII of FIG. 8.

FIGS. 13A to 13J are diagrams illustrating a part of a manufacturing process of the semiconductor device according to the first preferred embodiment of the present disclosure.

FIG. 14 is a cross-sectional view illustrating a current path of the semiconductor device according to the first preferred embodiment of the present disclosure.

FIG. 15 is a plan view illustrating a current path of the semiconductor device according to the first preferred embodiment of the present disclosure.

FIG. 16 is a cross-sectional view illustrating a first modified example of the semiconductor device according to the first preferred embodiment of the present disclosure.

FIG. 17 is a cross-sectional view illustrating a second modified example of the semiconductor device according to the first preferred embodiment of the present disclosure.

FIG. 18 is a cross-sectional view illustrating a third modified example of the semiconductor device according to the first preferred embodiment of the present disclosure.

FIG. 19 is a schematic plan view illustrating an internal structure of a semiconductor device according to a second preferred embodiment of the present disclosure.

FIG. 20 is an enlarged view of a part surrounded by a two-dot chain line XX in FIG. 19.

FIG. 21 is an enlarged view of a part surrounded by a two-dot chain line XX in FIG. 19.

FIG. 22 is a cross-sectional view taken along line XXII-XXII of FIG. 20.

FIG. 23 is a cross-sectional view taken along line XXIII-XXIII of FIG. 20.

FIG. 24 is a cross-sectional view taken along line XXIV-XXIV of FIG. 20.

FIGS. 25A to 25J are diagrams illustrating a part of a manufacturing process of the semiconductor device according to the second preferred embodiment of the present disclosure.

FIG. 26 is a cross-sectional view illustrating a current path of the semiconductor device according to the second preferred embodiment of the present disclosure.

FIG. 27 is a plan view illustrating a current path of the semiconductor device according to the second preferred embodiment of the present disclosure.

FIG. 28 is a diagram for describing an effect of improving a withstand voltage of the semiconductor device according to the second preferred embodiment of the present disclosure.

FIG. 29 is a diagram for describing an effect of improving a withstand voltage of the semiconductor device according to the second preferred embodiment of the present disclosure.

FIG. 30 is a diagram for describing an effect of improving a withstand voltage of the semiconductor device according to the second preferred embodiment of the present disclosure.

FIG. 31 is a diagram for describing an effect of improving a withstand voltage of the semiconductor device according to the second preferred embodiment of the present disclosure.

FIG. 32 is a diagram for describing an effect of improving a withstand voltage of the semiconductor device according to the second preferred embodiment of the present disclosure.

FIG. 33 is a cross-sectional view illustrating a first modified example of the semiconductor device according to the second preferred embodiment of the present disclosure.

FIG. 34 is a cross-sectional view illustrating a second modified example of the semiconductor device according to the second preferred embodiment of the present disclosure.

FIG. 35 is a cross-sectional view illustrating a third modified example of the semiconductor device according to the second preferred embodiment of the present disclosure.

### DESCRIPTION OF EMBODIMENTS

Next, a preferred embodiment of the present disclosure will be described in detail with reference to the attached drawings.

### First Preferred Embodiment

### (1) Structure of Semiconductor Device 1A

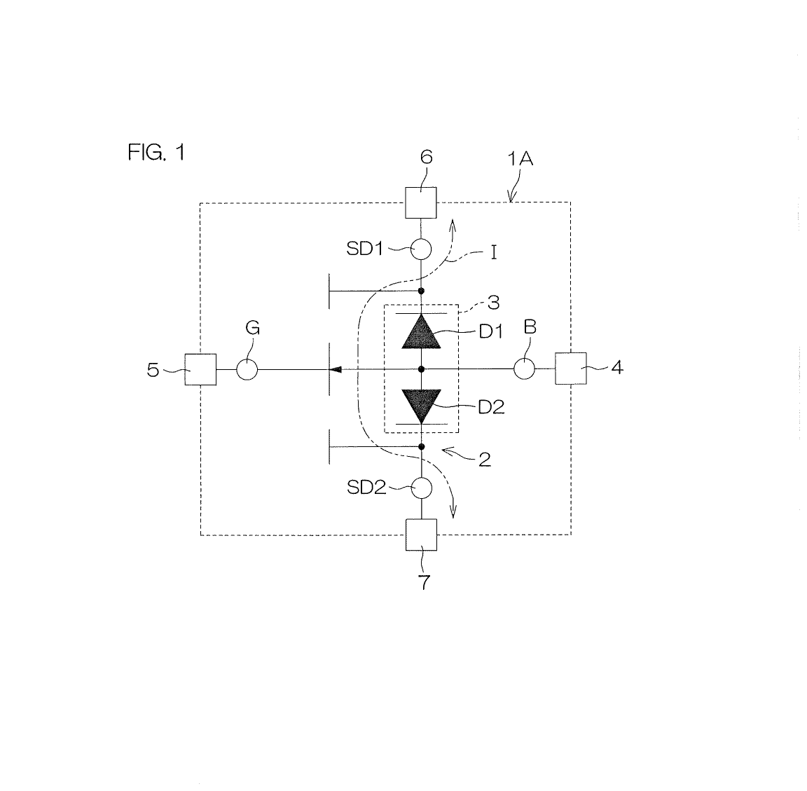

FIG. 1 is a circuit diagram of a semiconductor device 1A according to a first preferred embodiment of the present disclosure.

The semiconductor device 1A includes a common source/drain type MISFET (Metal Insulator Semiconductor Field Effect Transistor) 2. The MISFET 2 includes a base B, a gate G, a first source/drain SD1, and a second source/drain SD2. The first source/drain SD1 and the second source/drain SD2 also serve as a source and a drain. For example, depending on the connection form of the semiconductor device 1A, the first source/drain SD1 may be a source, and the second source/drain SD2 may be a drain. The first source/drain SD1 may be a drain, and the second source/drain SD2 may be a source.

A reference voltage (for example, a ground voltage) is applied to the base B. A gate voltage VG based on the base B is applied to the gate G. The gate G controls conduction and interruption of the current I flowing between the first source/drain SD1 and the second source/drain SD2. A first source/drain voltage VSD1 (first voltage) is applied to the first source/drain SD1. A second source/drain voltage VSD2 (second voltage) different from the first source/drain voltage VSD1 is applied to the second source/drain voltage SD2.

The semiconductor device 1A further includes a diode pair 3 connected to the first source/drain SD1 and the second source/drain SD2. The diode pair 3 regulates (interrupts) the current I flowing between the first source/drain SD1 and the second source/drain SD2 in the off state of the MISFET 2.

Specifically, the diode pair 3 includes a first body diode D1 and a second body diode D2 that are reversely biased. The first body diode D1 and the second body diode D2 include an anode and a cathode, respectively.

An anode of the first body diode D1 is connected to the base B. A cathode of the first body diode D1 is connected to the first source/drain SD1. An anode of the second body diode D2 is connected to the base B. A cathode of the second body diode D2 is connected to the second source/drain SD2.

The semiconductor device 1A is a four-terminal device including four external terminals 4, 5, 6, and 7. Specifically, the external terminals 4 to 7 include a base terminal 4, a gate terminal 5, a first source/drain terminal 6, and a second source/drain terminal 7. The base terminal 4 is connected to the base B. The gate terminal 5 is connected to the gate G. The first source/drain terminal 6 is connected to the first source/drain SD1. The second source/drain terminal 7 is connected to the second source/drain SD2.

The MISFET 2 is a bidirectional device capable of causing a current I to flow in both directions of the first source/drain terminal 6 and the second source/drain terminal 7. That is, when the first source/drain terminal 6 is connected to the high-voltage side (input side), the second source/drain terminal 7 is connected to the low-voltage side (output side). On the other hand, when the first source/drain terminal 6 is connected to the low-voltage side (output side), the second source/drain terminal 7 is connected to the high-voltage side (input side).

When the gate voltage VG (Vth≤VG) equal to or higher than the gate threshold voltage Vth is applied to the gate terminal 5, the current I flows between the first source/drain terminal 6 and the second source/drain terminal 7. When the gate voltage VG (VG<Vth) less than the gate threshold voltage Vth is applied to the gate terminal 5, the current I does not flow between the first source/drain terminal 6 and the second source/drain terminal 7. In this way, the on/off of the MISFET 2 is controlled.

According to the semiconductor device 1A, the function of the circuit in which the drains of two MISFETs that are not of the common source/drain type are connected can be realized by one MISFET 2. Therefore, according to the semiconductor device 1A, it is possible to reduce the on-resistance by shortening the current path. Hereinafter, a specific structure of the semiconductor device 1A will be described.

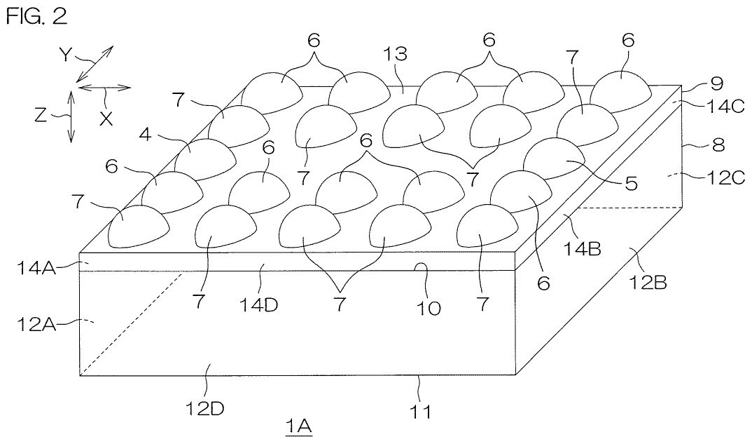

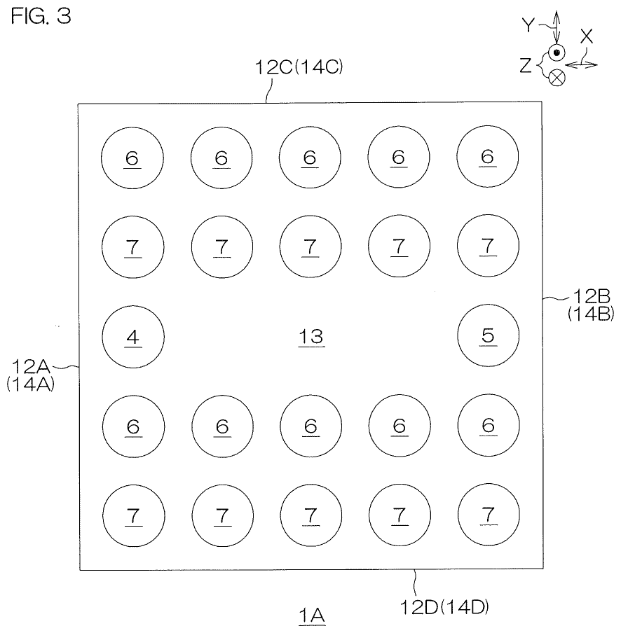

FIG. 2 is a schematic perspective view of the semiconductor device 1A according to the first preferred embodiment of the present disclosure. FIG. 3 is a plan view of the semiconductor device 1A of FIG. 2. Hereinafter, an example in which the semiconductor device 1A includes a chip size package having a chip size as a package size will be described.

Referring to FIGS. 2 and 3, the semiconductor device 1A has a laminated structure including a semiconductor chip 8 and an insulating layer 9.

The semiconductor chip 8 is formed in a rectangular parallelepiped shape. The semiconductor chip 8 includes a first principal surface 10 on one side, a second principal surface 11 on the other side, and side surfaces 12A, 12B, 12C, and 12D connecting the first principal surface 10 and the second principal surface 11. Specifically, the side surfaces 12A to 12D include a first side surface 12A, a second side surface 12B, a third side surface 12C, and a fourth side surface 12D.

The insulating layer 9 is formed on the first principal surface 10. The insulating layer 9 includes an insulating principal surface 13 and insulating side surfaces 14A, 14B, 14C, and 14D. Specifically, the insulating side surfaces 14A to 14D include a first insulating side surface 14A, a second insulating side surface 14B, a third insulating side surface 14C, and a fourth insulating side surface 14D. The insulating side surfaces 14A to 14D extend from the peripheral edge of the insulating principal surface 13 toward the semiconductor chip 8 and are continuous with the side surfaces 12A to 12D. Specifically, the insulating side surfaces 14A to 14D are formed to be flush with the side surfaces 12A to 12D.

The plurality of external terminals 4 to 7 are formed on the insulating principal surface 13. In this form, the plurality of external terminals 4 to 7 are located in a matrix of 5 rows and 5 columns at intervals in the first direction X and the second direction Y.

The base terminal 4 is located in the first column of the third row. The gate terminal 5 is located in the fifth column of the third row. The gate terminal 5 opposes the base terminal 4 in the first direction X. The plurality of first source/drain terminals 6 are located in the first to fifth columns of the first row and the first to fifth columns of the fourth row. The plurality of second source/drain terminals 7 are located in the first to fifth columns of the second row and the first to fifth columns of the fifth row.

The plurality of second source/drain terminals 7 located in the second row oppose the plurality of first source/drain terminals 6 located in the first row in the second direction Y in a one-to-one correspondence relationship. The plurality of second source/drain terminals 7 located in the fifth row oppose the plurality of first source/drain terminals 6 located in the fourth row in the second direction Y in a one-to-one correspondence relationship.

In this form, a space is provided in each of the second column, the third column, and the fourth column of the third row. Any one of the base terminal 4, the gate terminal 5, the first source/drain terminal 6, and the second source/drain terminal 7 may be located in each space. An electrically open terminal may be located in each of the spaces. The number and arrangement of the base terminal 4, the gate terminal 5, the first source/drain terminal 6, and the second source/drain terminal 7 are arbitrary, and are not limited to the number and arrangement illustrated in FIGS. 2 and 3.

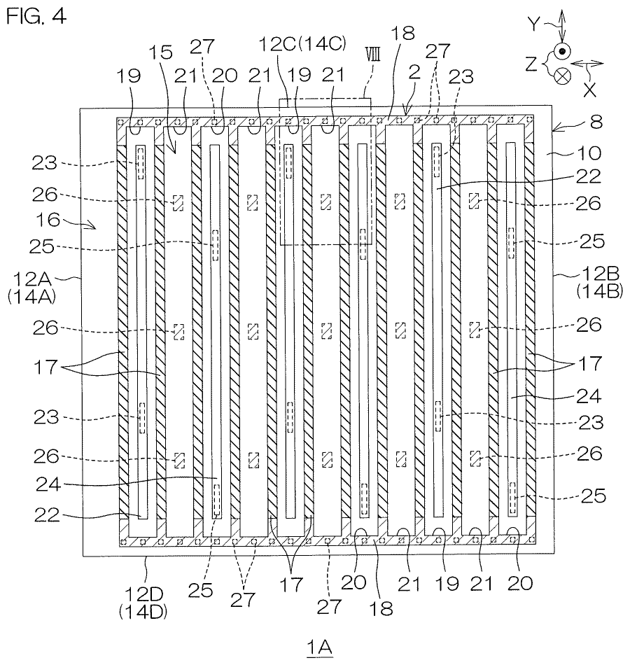

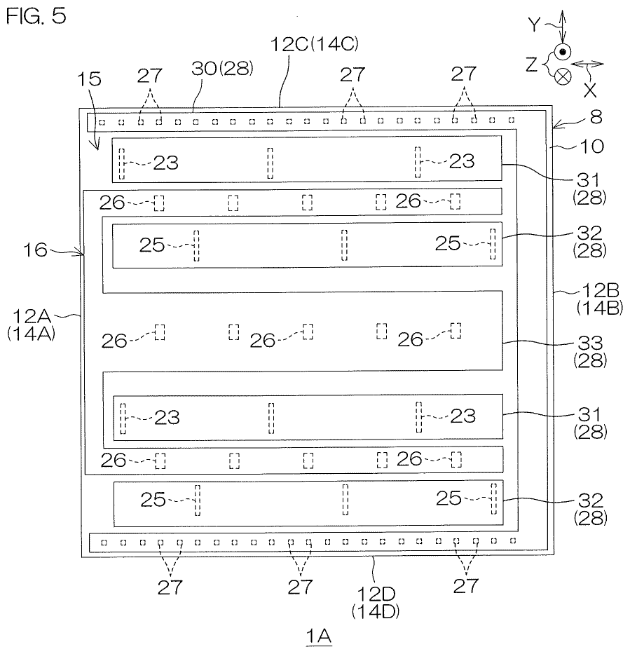

FIGS. 4 to 7 are plan views illustrating an internal structure of the semiconductor device 1A in FIG. 2. FIG. 4 illustrates a planar structure of the semiconductor chip 8, and FIGS. 5 to 7 illustrate a wiring pattern inside the insulating layer 9.

Referring to FIGS. 4 to 7, an active region 15 and an outer peripheral region 16 surrounding the active region 15 are set on the first principal surface 10 of the semiconductor chip 8.

The outer peripheral region 16 may coincide with an annular peripheral edge portion along the side surfaces 12A to 12D of the semiconductor chip 8. The outer peripheral region 16 may be an annular region from the side surfaces 12A to 12D of the semiconductor chip 8 to the inside by about several um. The active region 15 may be a central region of the semiconductor chip 8 surrounded by the outer peripheral region 16. The active region 15 may be, for example, a region where most of the element structure of the MISFET 2 is formed.

Referring to FIG. 4, an element structure of the MISFET 2 is formed in the active region 15. In this form, the element structure is a trench gate lateral type metal insulator semiconductor field effect transistor (MISFET) structure.

The MISFET 2 includes a first trench structure 17 and a trench connection structure 18 as a trench structure formed on the first principal surface 10.

The first trench structure 17 may be referred to as a “trench gate structure.” The plurality of first trench structures 17 are formed in the inner portion of the first principal surface 10 at intervals from the peripheral edge of the first principal surface 10. The plurality of first trench structures 17 are located at intervals in the first direction X, and each formed in a band shape extending in the second direction Y. The plurality of first trench structures 17 are formed in a stripe shape extending in the second direction Y in a plan view. Each of the plurality of first trench structures 17 has a first end portion on one side and a second end portion on the other side in the second direction Y.

The trench connection structure 18 is connected to the first trench structure 17. The plurality of (two in this form) trench connection structures 18 include a trench connection structure 18 on one side (third side surface 12C side) that connects the first end portions of the plurality of first trench structures 17, and a trench connection structure 18 on the other side (fourth side surface 12D side) that connects the second end portions of the plurality of first trench structures 17.

The trench connection structure 18 is formed in the inner portion of the first principal surface 10 with a space from the peripheral edge of the first principal surface 10. The trench connection structure 18 is formed in a band shape extending in a direction (specifically, the first direction X) intersecting the direction in which the plurality of first trench structures 17 extend, and is connected to the first end portion and the second end portion of the plurality of first trench structures 17. As a result, a plurality of closed regions surrounded by the pair of first trench structures 17 and the pair of trench connection structures 18 are formed on the first principal surface 10.

Each of the plurality of closed regions 19 to 21 is sandwiched between the first trench structures 17 in the first direction X, and is formed in a band shape extending in the second direction Y. The plurality of closed regions 19 to 21 are located across the first trench structure 17 in the first direction X, and are formed in a stripe shape as a whole. The plurality of closed regions 19 to 21 may include a first source/drain region 19, a second source/drain region 20, and a drift region 21.

In this form, the first source/drain region 19 and the second source/drain region 20 oppose each other with the drift region 21 interposed therebetween. Between the first source/drain region 19 and the drift region 21 and between the drift region 21 and the second source/drain region 20, a first trench structure 17 for separating these regions is formed.

The plurality of first source/drain regions 19 and the plurality of second source/drain regions 20 are alternately located at intervals in the first direction X such that the drift region 21 is sandwiched between the adjacent first source/drain regions 19 and second source/drain regions 20. In FIG. 4, a set of the first source/drain region 19, the drift region 21, the second source/drain region 20, and the drift region 21 is repeatedly located in the first direction X in order from the left side of the drawing.

In the first source/drain region 19, a first contact region 22 is formed. The first contact region 22 may be referred to as a “first source/drain contact region.” In this form, the band-shaped first contact region 22 extending in the second direction Y is formed in the inner region of each first source/drain region 19. The first contact region 22 has an annular outer peripheral edge at a part spaced inward from the first trench structure 17 and the trench connection structure 18.

A first lower contact 23 is formed in the first contact region 22. The first lower contact 23 may be referred to as a “first source/drain contact.” In this form, the plurality of first lower contacts 23 are formed at intervals in the second direction Y. Each of the first lower contacts 23 is formed in a rectangular shape in a plan view that is long along the second direction Y. Only one first lower contact 23 may be formed in each first contact region 22.

A second contact region 24 is formed in the second source/drain region 20. The second contact region 24 may be referred to as a “second source/drain contact region.” In this form, the band-shaped second contact region 24 extending in the second direction Y is formed in the inner region of each of the second source/drain regions 20. The second contact region 24 has an annular outer peripheral edge at a part spaced inward from the first trench structure 17 and the trench connection structure 18.

A second lower contact 25 is formed in the second contact region 24. The second lower contact 25 may be referred to as a “second source/drain contact.” In this form, the plurality of second lower contacts 25 are formed at intervals in the second direction Y. Each of the second lower contacts 25 is formed in a rectangular shape in a plan view that is long along the second direction Y. Only one second lower contact 25 may be formed in each second contact region 24.

In the drift region 21, a first base contact 26 is formed. In this form, the plurality of first base contacts 26 are formed at intervals in the second direction Y. Each of the first base contacts 26 is formed in a rectangular shape in a plan view that is long along the second direction Y. Only one first base contact 26 may be formed in each drift region 21.

In this form, the first lower contact 23, the second lower contact 25, and the first base contact 26 are electrically separated from each other and fixed at different potentials from each other. The plurality of first lower contacts 23, the plurality of second lower contacts 25, and the plurality of first base contacts 26 are discretely located on the first principal surface 10. In this form, the plurality of first lower contacts 23, the plurality of second lower contacts 25, and the plurality of first base contacts 26 are located with regularity that the contacts of the same type (same potential) are aligned in the first direction X.

In FIG. 4, a row in which the plurality of first lower contacts 23 are aligned in the first direction X, a row in which the plurality of first base contacts 26 are aligned in the first direction X, and a row in which the plurality of second lower contacts 25 are aligned in the first direction X are sequentially formed from the upper side of the drawing. As a result, the plurality of first lower contacts 23, the plurality of second lower contacts 25, and the plurality of first base contacts 26 do not oppose different types of contacts in the first direction X.

A first gate contact 27 is formed in the trench connection structure 18. In this form, the plurality of first gate contacts 27 are located at intervals in the first direction X. The plurality of first gate contacts 27 may include the first gate contacts 27 located at intersections of the trench connection structures 18 and the first trench structures 17. The plurality of first gate contacts 27 may be located at positions opposing at least one of the first source/drain region 19, the second source/drain region 20, and the drift region 21 in the second direction Y.

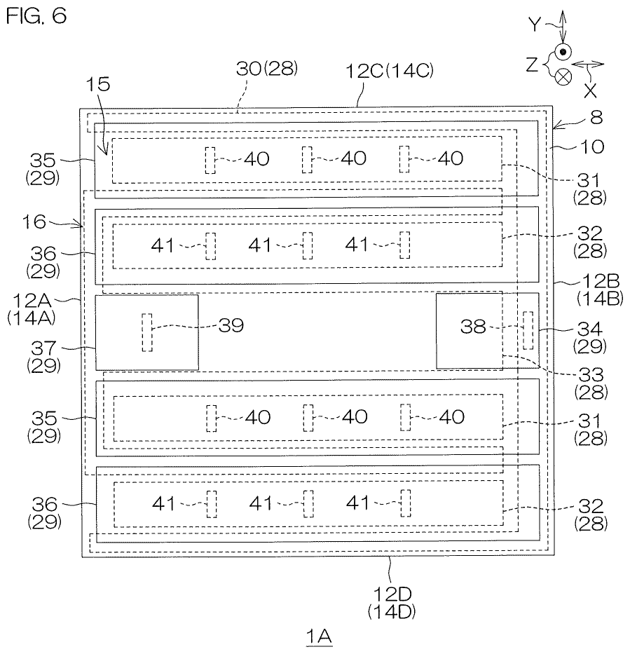

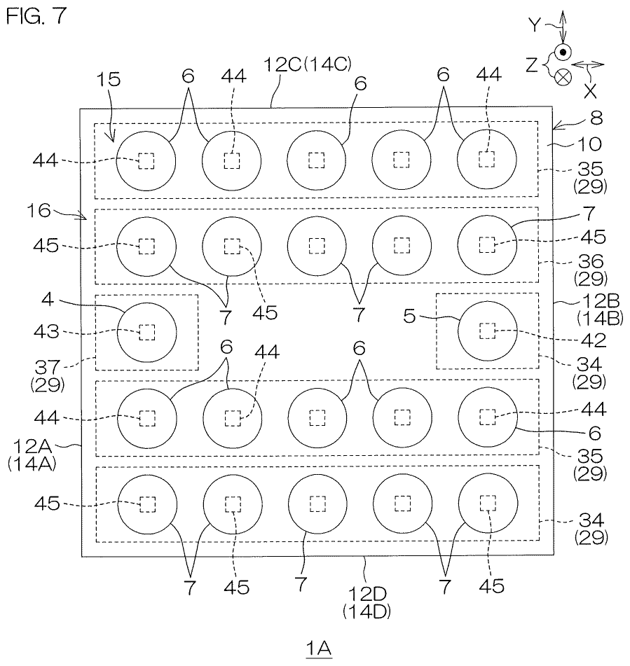

Referring to FIGS. 5 to 7, a plurality of wiring layers are formed on the first principal surface 10 of the semiconductor chip 8, and the plurality of external terminals described above are connected to the uppermost layer of the plurality of wiring layers. The plurality of wiring layers form a multilayer wiring structure, and include, for example, a first wiring layer 28 indicated by a solid line in FIG. 5 and a second wiring layer 29 indicated by a solid line in FIG. 6 in order from the first principal surface 10 upward. As illustrated in FIG. 7, the external terminal is connected to the second wiring layer 29 in this form.

The first wiring layer 28 may be referred to as a “first metal.” Referring to FIG. 5, the first wiring layer 28 includes a first gate wiring layer 30, a first lower wiring layer 31, a second lower wiring layer 32, and a first base wiring layer 33. The first gate wiring layer 30, the first lower wiring layer 31, the second lower wiring layer 32, and the first base wiring layer 33 are physically independent wiring layers. The first lower wiring layer 31 may be referred to as a “first lower source/drain wiring layer.” The second lower wiring layer 32 may be referred to as a “second lower source/drain wiring layer.”

The first gate wiring layer 30 is formed along the outer peripheral region 16 of the semiconductor chip 8. The first gate wiring layer 30 has a shape surrounding the active region 15. For example, the first gate wiring layer 30 surrounds the active region 15 from three sides, and has a shape in which one side surface (in FIG. 5, the first side surface 12A) side of the side surfaces 12A to 12D of the semiconductor chip 8 is opened. The first gate wiring layer 30 is formed by three rectilinear portions along the outer peripheral region 16. Among the three rectilinear portions, a pair of rectilinear portions opposing each other in the second direction Y cover the plurality of first gate contacts 27 and are connected to the plurality of first gate contacts 27.

The first lower wiring layer 31 is formed to cover the first lower contact 23 and is connected to the first lower contact 23. In this form, the first lower wiring layer 31 is formed in a band shape extending in the first direction X to collectively cover the plurality of first lower contacts 23 linearly aligned in the first direction X.

The second lower wiring layer 32 is formed to cover the second lower contact 25 and is connected to the second lower contact 25. In this form, the second lower wiring layer 32 is formed in a band shape extending in the first direction X to collectively cover the plurality of second lower contacts 25 linearly aligned in the first direction X.

The plurality of first lower wiring layers 31 and the plurality of second lower wiring layers 32 are alternately located at intervals in the second direction Y. In this form, two band-shaped first lower wiring layers 31 and two band-shaped second lower wiring layers 32 are formed in a stripe shape at intervals from each other.

The first base wiring layer 33 is formed to cover the first base contact 26 and is connected to the first base contact 26. In this form, the first base wiring layer 33 is formed in a band shape extending in the first direction X to collectively cover the plurality of first base contacts 26 linearly aligned in the first direction X. In this form, one band-shaped first base wiring layer 33 is located in a region between the first lower wiring layer 31 and the second lower wiring layer 32. All the first base wiring layers 33 are collectively connected on the open side (first side surface 12A side) of the first gate wiring layer 30.

The second wiring layer 29 may be referred to as a “second metal.” Referring to FIG. 6, the second wiring layer 29 includes a second gate wiring layer 34, a first upper wiring layer 35, a second upper wiring layer 36, and a second base wiring layer 37. The second gate wiring layer 34, the first upper wiring layer 35, the second upper wiring layer 36, and the second base wiring layer 37 are physically independent wiring layers. The first upper wiring layer 35 may be referred to as a “first upper source/drain wiring layer.” The second upper wiring layer 36 may be referred to as a “second upper source/drain wiring layer.” In FIG. 6, the first wiring layer 28 is indicated by a broken line in order to clarify the relationship between the second wiring layer 29 and the first wiring layer 28.

The second gate wiring layer 34 and the second base wiring layer 37 are each formed in a rectangular shape in a plan view. The second gate wiring layer 34 and the second base wiring layer 37 are formed at positions opposing each other in the first direction X in the central portion of the semiconductor chip 8 in the second direction Y. In this form, the second gate wiring layer 34 is located in the vicinity of the first side surface 12A among the side surfaces 12A to 12D of the semiconductor chip 8, and the second base wiring layer 37 is located in the vicinity of the second side surface 12B on the opposite side. The second gate wiring layer 34 is connected to the first gate wiring layer 30 through the second gate contact 38. The second base wiring layer 37 is connected to the first base wiring layer 33 through the second base contact 39.

The first upper wiring layer 35 is formed in a band shape extending along the first lower wiring layer 31 and covers the first lower wiring layer 31. The first upper wiring layer 35 is connected to the first lower wiring layer 31 through a first upper contact 40. The plurality of first upper contacts 40 located at intervals in the first direction X may be formed.

The second upper wiring layer 36 is formed in a band shape extending along the second lower wiring layer 32 and covers the second lower wiring layer 32. The second upper wiring layer 36 is connected to the second lower wiring layer 32 through a second upper contact 41. The plurality of second upper contacts 41 located at intervals in the first direction X may be formed.

Referring to FIG. 7, the plurality of external terminals are located on the corresponding second wiring layer 29. In FIG. 7, the second wiring layer 29 is indicated by a broken line in order to clarify the relationship between the plurality of external terminals and the second wiring layer 29.

The gate terminal 5 is provided on the second gate wiring layer 34, and is connected to the second gate wiring layer 34 through a gate terminal contact 42. The base terminal 4 is provided on the second base wiring layer 37 and is connected to the second base wiring layer 37 through the base terminal contact 43.

The plurality of first source/drain terminals 6 are located at intervals in the longitudinal direction of the band-shaped first upper wiring layer 35. Each of the first source/drain terminals 6 is connected to the first upper wiring layer 35 through a first terminal contact 44.

The plurality of second source/drain terminals 7 are located at intervals in the longitudinal direction of the band-shaped second upper wiring layer 36. Each of the second source/drain terminals 7 is connected to the second upper wiring layer 36 through the second terminal contact 45.

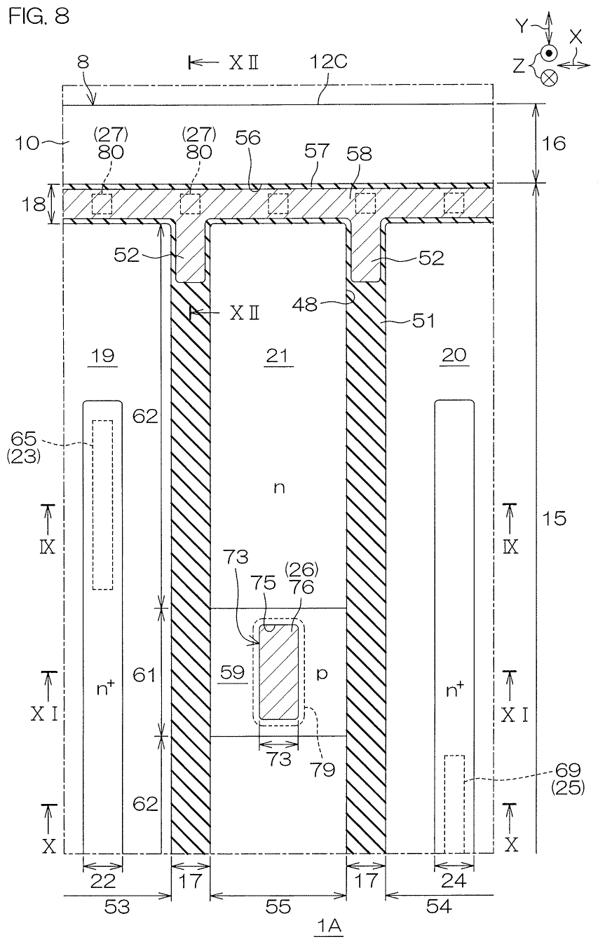

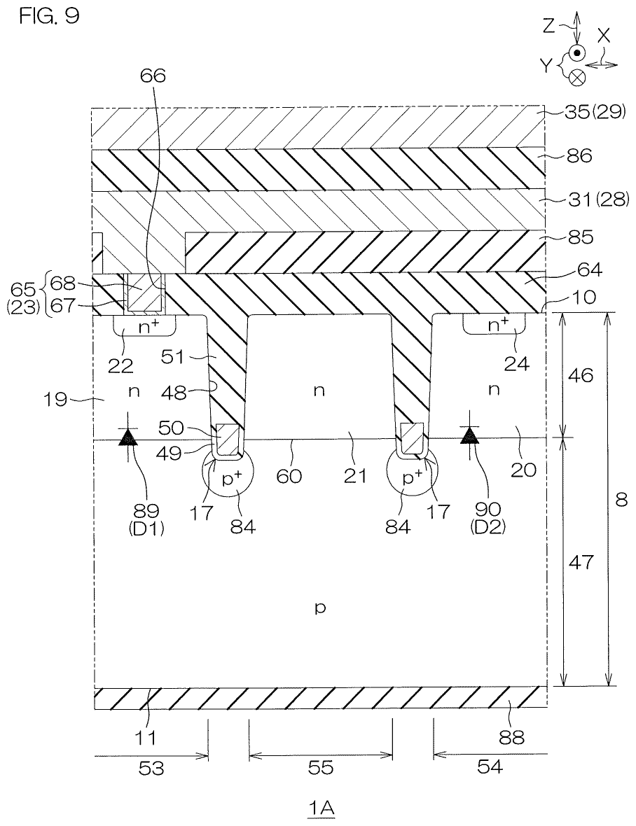

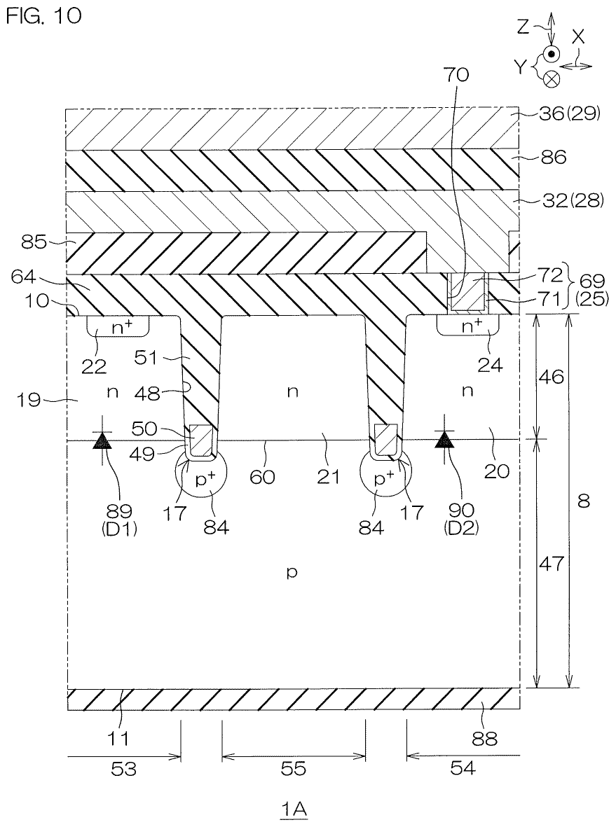

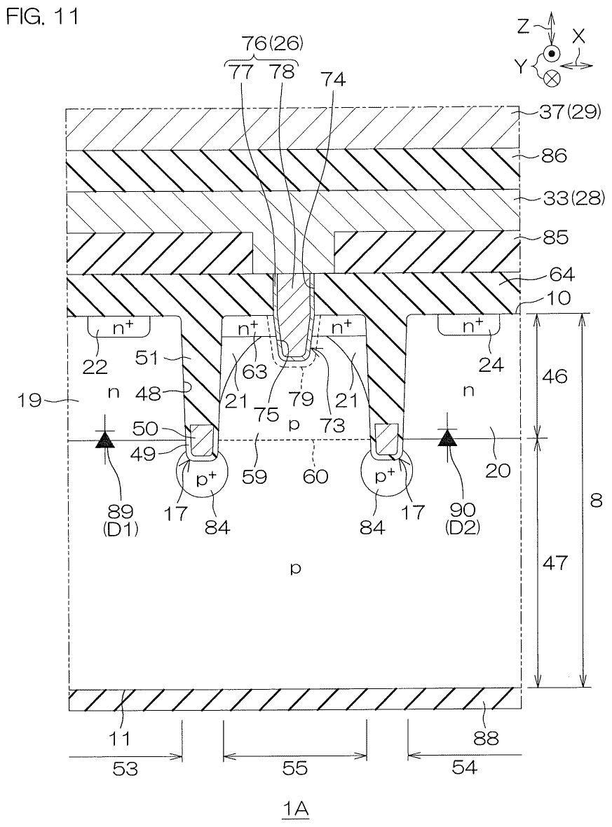

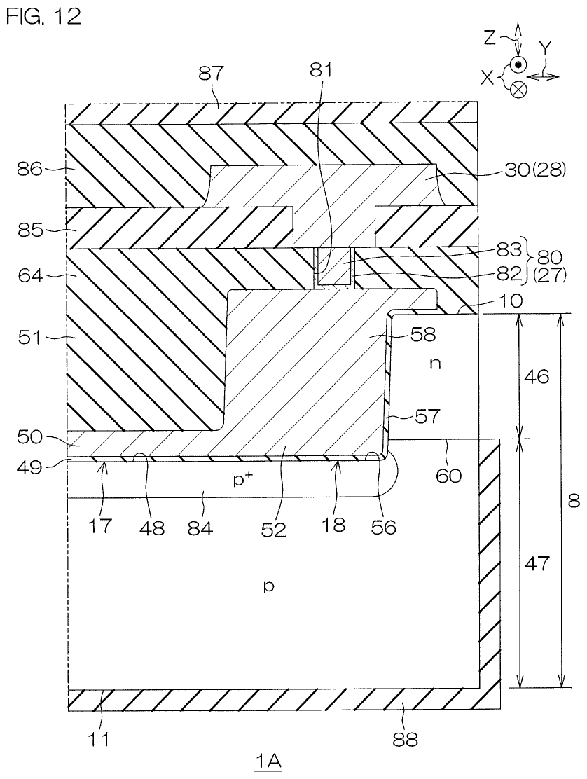

FIG. 8 is an enlarged view of a part surrounded by a two-dot chain line VIII in FIG. 4. FIG. 9 is a cross-sectional view taken along line IX-IX of FIG. 8. FIG. 10 is a cross-sectional view taken along line X-X of FIG. 8. FIG. 11 is a cross-sectional view taken along line XI-XI of FIG. 8. FIG. 12 is a cross-sectional view taken along line XII-XII of FIG. 8.

Referring to FIGS. 9 to 12, the semiconductor device 1A includes the semiconductor chip 8. The semiconductor chip 8 is the semiconductor chip 8 including a single layer. The semiconductor chip 8 formed of a single layer has a single structure of a semiconductor substrate having no epitaxial layer. In this form, the semiconductor chip 8 includes a single crystal of Si (silicon) or a wide bandgap semiconductor without an epitaxial layer. The wide band gap semiconductor is a semiconductor having a band gap exceeding a band gap of Si. The semiconductor chip 8 may be an Si chip or a silicon carbide (SiC) chip.

The semiconductor device 1A includes an n-type (first conductivity type) first semiconductor region 46 formed in a region on the first principal surface 10 side in the semiconductor chip 8. The first semiconductor region 46 may be referred to as a “drift layer.” The first semiconductor region 46 is formed in the semiconductor chip 8 with a space from the second principal surface 11 toward the first principal surface 10 side. The first semiconductor region 46 is formed in a layer shape extending along the first principal surface 10 in the surface layer portion of the first principal surface 10, and is exposed from the entire region of the first principal surface 10 and a part of the first to fourth side surfaces 12A to 12D.

As m matter of course, the first semiconductor region 46 may be formed in the inner portion of the first principal surface 10 with a space from the first to fourth side surfaces 12A to 12D in a plan view. The first semiconductor region 46 may have an n-type impurity concentration of 1×10¹⁴ cm⁻³ or more and 1×10¹⁸ cm⁻³ or less. The first semiconductor region 46 may have a thickness of 0.1 μm or more and 10 μm or less (preferably 0.5 μm or more and 2 μm or less).

The semiconductor device 1A includes a p-type (second conductivity type) second semiconductor region 47 formed in a region closer to the second principal surface 11 side than the first semiconductor region 46 in the semiconductor chip 8. The second semiconductor region 47 may be referred to as a “base layer.” The second semiconductor region 47 may have a p-type impurity concentration of 1×10¹³ cm⁻³ or more and 1×10¹⁶ cm⁻³ or less. More specifically, in the thickness direction of the semiconductor chip 8, the p-type impurity concentration of the second semiconductor region 47 is 1×10¹³ cm⁻³ or more and 1×10¹⁶ cm⁻³ or less over an entire region from the second principal surface 11 to the first semiconductor region 46.

The reason why the p-type impurity concentration of the second semiconductor region 47 is substantially constant in the thickness direction of the semiconductor chip 8 as described above is that the semiconductor chip 8 is constituted by a semiconductor substrate having a single structure without an epitaxial layer. Normally, when an epitaxial layer is grown on a semiconductor substrate (base substrate), even when the epitaxial layer has the same conductivity type as that of the base substrate, the impurity concentration of the epitaxial layer is made relatively low to secure a withstand voltage. On the other hand, the impurity concentration of the base substrate is increased in order to reduce the ohmic resistance of the rear surface electrode formed on the second principal surface 11.

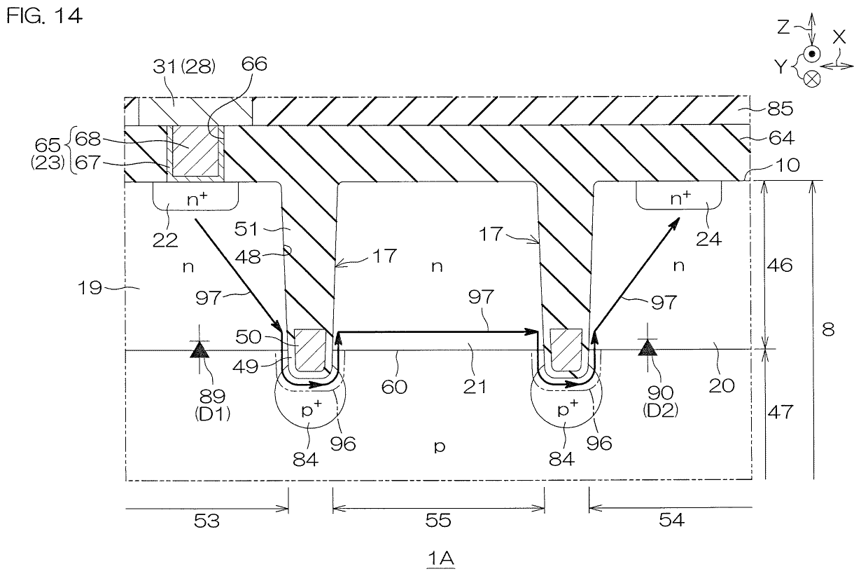

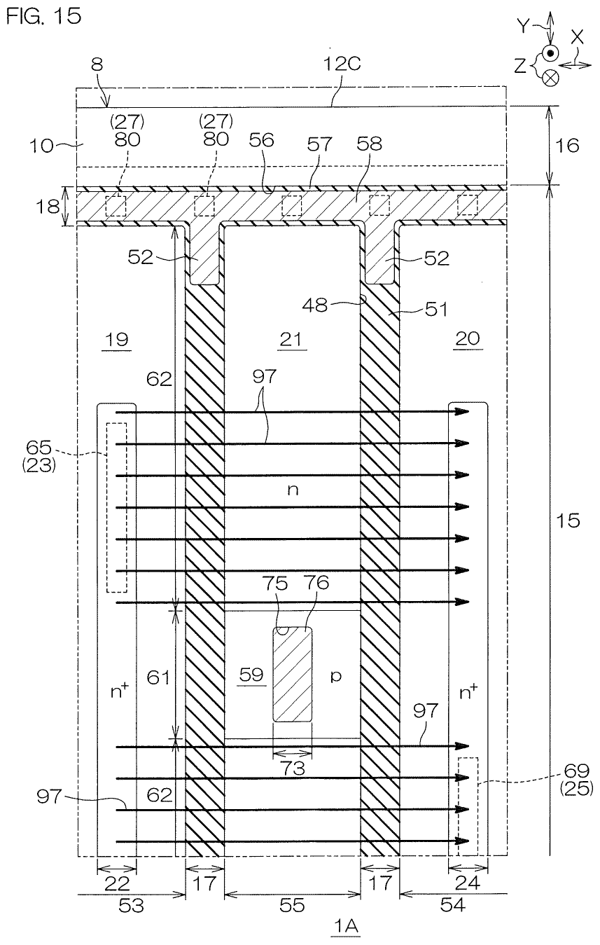

In this form, since the MISFET 2 is of a lateral type and a current path 97 (see FIGS. 14 and 15) is only in the lateral direction along the first principal surface 10, no current flows in the thickness direction of the second semiconductor region 47. Therefore, even when the p-type impurity concentration of the second semiconductor region 47 is low as a whole, there is little concern that the on-resistance increases. For example, the resistance value of the second semiconductor region 47 may be 10 Ω·cm or more and 100 Ω·cm or less over an entire region from the second principal surface 11 to the boundary portion 60 between the first semiconductor region 46 and the second semiconductor region 47 in the thickness direction of the semiconductor chip 8.

The second semiconductor region 47 is formed in a layer shape extending along the first principal surface 10 (first semiconductor region 46) in the semiconductor chip 8, and is exposed from a part of the first to fourth side surfaces 12A to 12D. The second semiconductor region 47 is electrically connected to the first semiconductor region 46 in the semiconductor chip 8. Specifically, the second semiconductor region 47 forms a pn junction portion with the first semiconductor region 46. The second semiconductor region 47 may have a thickness of 0.5 μm or more and 755 μm or less.

The plurality of first trench structures 17 penetrate the first semiconductor region 46 to reach the second semiconductor region 47. In this form, each of the plurality of first trench structures 17 has a bottom wall positioned in the second semiconductor region 47. The plurality of first trench structures 17 are arranged to control inversion and non-inversion of a channel (a channel 96 to be described later) in the second semiconductor region 47.

The plurality of first trench structures 17 may be located at intervals (pitches) of 0.02 μm or more and 20 μm or less (preferably 0.2 μm or more and 5 μm or less). The plurality of first trench structures 17 are preferably located at substantially equal intervals in the first direction X. Each of the plurality of first trench structures 17 may have a width of 0.01 μm or more and 10 μm or less (preferably 0.1 μm or more and 0.5 μm or less) in the first direction X. Each of the plurality of first trench structures 17 may have a depth of 0.2 μm or more and 30 μm or less (preferably 0.5 μm or more and 10 μm or less).

Hereinafter, the internal structure of one first trench structure 17 will be described. The first trench structure 17 includes a first trench 48, a gate insulating film 49 (control insulating film), a gate electrode 50 (control electrode), and an embedded insulator 51.

The first trench 48 may be referred to as a “gate trench.” The first trench 48 is formed on the first principal surface 10 and defines the wall surface (side wall and bottom wall) of the first trench structure 17. The first trench 48 exposes the first semiconductor region 46 and the second semiconductor region 47 from the wall surface.

The first trench 48 may be formed in a tapered shape in which the opening width narrows from the first principal surface 10 side toward the bottom wall side in a cross-sectional view. As a matter of course, the first trenches 48 may be formed perpendicular to the first principal surface 10. The bottom wall side corner portion of the first trench 48 may be formed in a curved shape. As a matter of course, the entire bottom wall of the first trench 48 may be formed in a curved shape toward the second principal surface 11 side.

The gate insulating film 49 covers the side wall and the bottom wall of the first trench 48 in a film shape. In this form, the gate insulating film 49 covers the side wall and the bottom wall on the bottom wall side of the first trench 48, and defines the recessed space on the bottom wall side of the first trench 48. The gate insulating film 49 may have a thickness of 5 nm or more and 1000 nm or less in the normal direction of the wall surface of the first trench 48. The gate insulating film 49 includes at least one of a silicon oxide film, a silicon nitride film, an aluminum oxide film, a zirconium oxide film, a hafnium oxide film, or a tantalum oxide film. The gate insulating film 49 is preferably formed of a silicon oxide film. The gate insulating film 49 is particularly preferably formed of oxide (thermal oxide film) of the semiconductor chip 8.

The gate electrode 50 is embedded in the first trench 48 with the gate insulating film 49 interposed therebetween. Specifically, the gate electrode 50 is embedded in a recessed space defined by the gate insulating film 49 on the bottom wall side of the first trench 48, and opposes the second semiconductor region 47 with the gate insulating film 49 interposed therebetween. The gate electrode 50 crosses the depth position of the boundary portion 60 between the first semiconductor region 46 and the second semiconductor region 47 in the depth direction of the first trench 48.

Referring to FIGS. 8 and 12, the gate electrode 50 includes a plurality of lead-out portions 52 led out from the bottom wall side to the opening side of the first trench 48. The number of the plurality of lead-out portions 52 is arbitrary. In this form, the plurality of lead-out portions 52 include a pair of lead-out portions 52 separated from each other in the second direction Y. In this form, the pair of lead-out portions 52 are formed at both end portions of the first trench 48. The plurality of lead-out portions 52 extend in the second direction Y in a plan view.

The plurality of lead-out portions 52 partition the wall surface of the first trench 48 and the opening side recess on the opening side of the first trench 48. The opening side recess is defined in a band shape extending in the second direction Y in a plan view. The plurality of lead-out portions 52 may protrude upward from the first principal surface 10. The plurality of lead-out portions 52 may be led out from the first trench 48 onto the first principal surface 10 with a part of the gate insulating film 49 interposed therebetween. As a matter of course, the plurality of lead-out portions 52 may be positioned on the bottom wall side of the first trench 48 with respect to the first principal surface 10.

The gate electrode 50 may include at least one of a metal and a non-metal conductor. The gate electrode 50 may include at least one of tungsten, aluminum, copper, an aluminum alloy, a copper alloy, and conductive polysilicon. The gate electrode 50 preferably includes a non-metal conductor (conductive polysilicon). The conductive polysilicon may be p-type polysilicon or n-type polysilicon. The conductive polysilicon is preferably n-type polysilicon.

The embedded insulator 51 is embedded on the opening side of the first trench 48 to cover the gate electrode 50 in the first trench 48. Specifically, the embedded insulator 51 is embedded in the opening side recess defined by the gate electrode 50. The embedded insulator 51 is provided as a field insulator that relaxes the electric field with respect to the first trench 48. The embedded insulator 51 is arranged such that the opposing area with respect to the first semiconductor region 46 exceeds the opposing area of the gate electrode 50 with respect to the second semiconductor region 47.

The embedded insulator 51 has a thickness exceeding the thickness of the gate electrode 50 in the depth direction of the first trench 48. The embedded insulator 51 includes at least one of a silicon oxide film, a silicon nitride film, an aluminum oxide film, a zirconium oxide film, a hafnium oxide film, or a tantalum oxide film. The embedded insulator 51 is preferably formed of a silicon oxide film. The embedded insulator 51 is preferably formed of the same material as the gate insulating film 49. In this case, the embedded insulator 51 is preferably formed of an insulating vapor deposition film and has denseness different from that of the gate insulating film 49.

Referring to FIGS. 8 to 11, the semiconductor device 1A includes a plurality of mesa portions 53 to 55 partitioned into a first principal surface 10 (first semiconductor region 46) by the plurality of first trench structures 17. The plurality of mesa portions 53 to 55 are each partitioned into a band shape extending in the second direction Y in a region between the plurality of pairs of first trench structures 17 adjacent to each other. The plurality of mesa portions 53 to 55 include a plurality of first mesa portions 53, a plurality of second mesa portions 54, and a plurality of drift mesa portions 55.

The first mesa portion 53 and the second mesa portion 54 are located at intervals in the first direction X to sandwich one drift mesa portion 55. The first mesa portion 53 forms the first source/drain region 19 and may be referred to as a “first source/drain mesa portion.” The second mesa portion 54 forms the second source/drain region 20, and may be referred to as a “second source/drain mesa portion.” The drift mesa portion 55 forms a drift region 21.

Referring to FIGS. 8 and 12, the plurality of trench connection structures 18 penetrate the first semiconductor region 46 to reach the second semiconductor region 47. That is, the trench connection structure 18 defines the plurality of mesa portions 53 to 55 (a plurality of first mesa portions 53, a plurality of second mesa portions 54, and a plurality of drift mesa portions 55) together with the plurality of first trench structures 17.

The trench connection structure 18 may have a width of 0.01 μm or more and 10 μm or less (preferably 0.1 μm or more and 2 μm or less) in the second direction Y. The trench connection structure 18 may have a width substantially equal to the width of the first trench structure 17. Each of the trench connection structures 18 may have a depth of 0.2 μm or more and 30 μm or less (preferably 0.5 μm or more and 10 μm or less). The trench connection structure 18 may have a depth substantially equal to the depth of the first trench structure 17.

The trench connection structure 18 includes a connection trench 56, a connection insulating film 57, and a connection electrode 58. The connection trench 56 is formed on the first principal surface 10 to communicate with the plurality of first trenches 48, and defines the wall surface (side wall and bottom wall) of the trench connection structure 18. The wall surfaces (side walls and bottom walls) of the trench connection structure 18 are continuous with the wall surfaces (side walls and bottom walls) of the plurality of first trenches 48. The connection trench 56 exposes the first semiconductor region 46 and the second semiconductor region 47 from the wall surface.

The connection trench 56 may be formed in a tapered shape in which the opening width narrows from the first principal surface 10 side toward the bottom wall side in a cross-sectional view. As a matter of course, the connection trench 56 may be formed perpendicular to the first principal surface 10. The bottom wall side corner portion of the connection trench 56 may be formed in a curved shape. As a matter of course, the entire bottom wall of the connection trench 56 may be formed in a curved shape toward the second principal surface 11 side.

The connection insulating film 57 covers the side wall and the bottom wall of the connection trench 56 in a film shape. In this form, the connection insulating film 57 covers the side wall and the bottom wall on the opening side and the bottom wall side of the connection trench 56, and defines the recessed space in the connection trench 56. The connection insulating film 57 is continuous with the plurality of gate insulating films 49 at a communicating portion with the plurality of first trenches 48.

The connection insulating film 57 may have a thickness of 5 nm or more and 1000 nm or less. The connection insulating film 57 preferably has a thickness substantially equal to the thickness of the gate insulating film 49. The connection insulating film 57 includes at least one of a silicon oxide film, a silicon nitride film, an aluminum oxide film, a zirconium oxide film, a hafnium oxide film, or a tantalum oxide film. The connection insulating film 57 is preferably formed of the same material as the gate insulating layer.

The connection electrode 58 is embedded in the connection trench 56 with the connection insulating film 57 interposed therebetween, and opposes the first semiconductor region 46 and the second semiconductor region 47. The connection electrode 58 is continuous with the plurality of gate electrodes 50 at a communication portion with the plurality of first trenches 48. Specifically, the connection electrode 58 is continuous with the plurality of lead-out portions 52. Thus, the connection electrode 58 is fixed at the same potential as the gate electrode 50.

A portion of the connection electrode 58 continuous with the lead-out portion 52 may be included in a constituent element of the connection electrode 58 or may be included in a constituent element of the gate electrode 50. The connection electrode 58 has an upper end portion positioned on the first principal surface 10 side with respect to the upper end portion of the gate electrode 50.

The connection electrode 58 may protrude upward from the first principal surface 10. The connection electrode 58 may be extended from the connection trench 56 onto the first principal surface 10 with a part of the connection insulating film 57 interposed therebetween. As a matter of course, the connection electrode 58 may be positioned on the bottom wall side of the connection trench 56 with respect to the first principal surface 10.

The connection electrode 58 may include at least one of a metal and a non-metal conductor. The connection electrode 58 may include at least one of tungsten, aluminum, copper, an aluminum alloy, a copper alloy, and conductive polysilicon. The connection electrode 58 is preferably formed of the same material as the gate electrode 50.

In the plurality of first mesa portions 53, the first source/drain region 19 is formed by the first semiconductor region 46. The first contact region 22 is formed in a surface layer portion of the first source/drain region 19. The first contact region 22 has an n-type impurity concentration higher than that of the first semiconductor region 46. The n-type impurity concentration of the first contact region 22 may be 1×10¹⁸ cm⁻³ or more and 1×10²¹ cm⁻³ or less (in this form, about 1×10¹⁹ cm⁻³).

The first contact region 22 is preferably formed in a central portion of the corresponding first mesa portion 53 in a plan view. The first contact region 22 has a length less than the length of the first trench structure 17 in the second direction Y, and is formed with a space from both end portions of the first trench structure 17 inward. Both end portions of the first contact region 22 oppose the trench connection structure 18 with a part of the first semiconductor region 46 interposed therebetween in the second direction Y.

The first contact region 22 extends in the lateral direction (second direction Y) along the first principal surface 10 in a cross-sectional view. Specifically, the first contact region 22 is formed at a depth position on the first principal surface 10 side with respect to the upper end portion of the gate electrode 50. The first contact region 22 opposes the embedded insulator 51 with a part of the first semiconductor region 46 interposed therebetween in the lateral direction along the first principal surface 10. The first contact region 22 is separated from the upper end portion of the gate electrode 50 toward the first principal surface 10 side, and does not oppose the gate electrode 50 in the lateral direction along the first principal surface 10. As a result, the electric field applied to the plurality of first trench structures 17 is relaxed.

The first contact region 22 may have a thickness of 10 nm or more and 150 nm or less (preferably 50 nm or more and 100 nm or less). The first contact region 22 is preferably formed at an interval of 0.1 μm or more and 2 μm or less (preferably 0.5 μm or more and 1.5 μm or less) from the upper end portion of the gate electrode 50 in the thickness direction (normal direction Z) of the semiconductor chip 8.

In the plurality of second mesa portions 54, the second source/drain region 20 is formed by the first semiconductor region 46. The second contact region 24 is formed in a surface layer portion of the second source/drain region 20. The second contact region 24 has an n-type impurity concentration higher than that of the first semiconductor region 46. The n-type impurity concentration of the second contact region 24 may be 1×10¹⁸ cm⁻³ or more and 1×10²¹ cm⁻³ or less (in this form, about 1×10¹⁹ cm⁻³).

The second contact region 24 is preferably formed in a central portion of the corresponding second mesa portion 54 in a plan view. The second contact region 24 has a length less than the length of the first trench structure 17 in the second direction Y, and is formed with a space from both end portions of the first trench structure 17 inward. Both end portions of the second contact region 24 oppose the trench connection structure 18 with a part of the first semiconductor region 46 interposed therebetween in the second direction Y.

The second contact region 24 extends in the lateral direction (second direction Y) along the first principal surface 10 in a cross-sectional view. Specifically, the second contact region 24 is formed at a depth position on the first principal surface 10 side with respect to the upper end portion of the gate electrode 50. The second contact region 24 opposes the embedded insulator 51 with a part of the first semiconductor region 46 interposed therebetween in the lateral direction along the first principal surface 10. The second contact region 24 is separated from the upper end portion of the gate electrode 50 toward the first principal surface 10 side, and does not oppose the gate electrode 50 in the lateral direction along the first principal surface 10. As a result, the electric field applied to the plurality of first trench structures 17 is relaxed.

The second contact region 24 may have a thickness of 10 nm or more and 150 nm or less (preferably 50 nm or more and 100 nm or less). The second contact region 24 is preferably formed at an interval of 0.1 μm or more and 2 μm or less (preferably 0.5 μm or more and 1.5 μm or less) from the upper end portion of the gate electrode 50 in the thickness direction (normal direction Z) of the semiconductor chip 8.

Referring to FIGS. 8 and 11, in the plurality of drift mesa portions 55, p-type protrusion portions 59 selectively protruding from the second semiconductor region 47 toward the first principal surface 10 to the inside of the first semiconductor region 46 are formed. Referring to FIG. 11, the protrusion portion 59 may extend upward in a parabolic shape from the boundary portion 60 between the first semiconductor region 46 and the second semiconductor region 47 and have an apex portion in the vicinity of the first principal surface 10. In this form, the protrusion portion 59 has an apex portion at a position away from the first principal surface 10 toward the second principal surface 11 side. A part of the drift region 21 may be formed on both sides of the protrusion portion 59 in the first direction X. The portion of the drift region 21 is sandwiched between the protrusion portion 59 and the first trench structure 17.

Referring to FIG. 8, the protrusion portion 59 is selectively formed in the drift mesa portion 55 in the second direction Y. In this form, the plurality of protrusion portions 59 are located at intervals along the second direction Y. Each protrusion portion 59 is formed across the first trench structure 17 on one side and the first trench structure 17 on the other side in the first direction X. As a result, the drift region 21 is divided by the protrusion portion 59 at a plurality of locations along the second direction Y.

The protrusion portion 59 has a p-type impurity concentration higher than that of the second semiconductor region 47. The p-type impurity concentration of the protrusion portion 59 may be 1×10¹⁶ cm⁻³ or more and 1×1022 cm⁻³ or less (in this form, about 1×10¹⁹ cm⁻³).

Referring to FIG. 8, the plurality of protrusion portions 59 partition the drift region 21 into a plurality of contact regions 61 and a plurality of current regions 62 in the second direction Y. Each contact region 61 is a region where the protrusion portion 59 is formed in a plan view. Each current region 62 is a region where the protrusion portion 59 is not formed in a plan view and is formed by the first semiconductor region 46 (drift region 21) from the boundary portion 60 to the first principal surface 10.

In the second direction Y, the contact region 61 may be shorter than the current region 62. For example, the length of the contact region 61 in the second direction Y may be 0.1 μm or more and 100 μm or less, and the length of the current region 62 in the second direction Y may be 1 μm or more and 3000 μm or less.

A first impurity region 63 is further formed in the plurality of drift mesa portions 55. In FIG. 8, the first impurity region 63 is omitted. The first impurity region 63 is selectively formed in the contact region 61 out of the contact region 61 and the current region 62. The first impurity region 63 is formed in contact with the apex portion of the protrusion portion 59 in the surface layer portion of the first principal surface 10. The first impurity region 63 has an n-type impurity concentration higher than that of the first semiconductor region 46. The n-type impurity concentration of the first impurity region 63 may be 1×10¹⁵ cm⁻³ or more and 1×10²⁰ cm⁻³ or less (in this form, about 1×10¹⁸ cm⁻³).

The semiconductor device 1A includes a principal surface insulating film 64 that selectively covers the first principal surface 10. The principal surface insulating film 64 may be a part of the insulating layer 9 described above. The principal surface insulating film 64 covers the plurality of first trench structures 17 and the plurality of trench connection structures 18 on the first principal surface 10. In this form, the principal surface insulating film 64 covers the entire first principal surface 10 and is continuous with the first to fourth side surfaces 12A to 12D.

The principal surface insulating film 64 may have a thickness of 0.1 μm or more and 2 μm or less. The thickness of the principal surface insulating film 64 preferably exceeds the thickness of the gate insulating film 49. The principal surface insulating film 64 includes at least one of a silicon oxide film, a silicon nitride film, an aluminum oxide film, a zirconium oxide film, a hafnium oxide film, or a tantalum oxide film. The principal surface insulating film 64 is preferably formed of a silicon oxide film.

In this form, the principal surface insulating film 64 is formed of the same material as the embedded insulator 51, and is formed integrally with the embedded insulator 51. That is, the principal surface insulating film 64 enters the plurality of first trenches 48 from above the first principal surface 10 as a part of the embedded insulator 51. In other words, the principal surface insulating film 64 is formed of an insulating film in which portions of the plurality of embedded insulators 51 protruding from the plurality of first trenches 48 are integrated in a film shape on the first principal surface 10.

Referring to FIGS. 8 and 9, the semiconductor device 1A includes a plurality of first electrodes 65 electrically connected to the first semiconductor region 46 in the plurality of first mesa portions 53. In this form, the plurality of first electrodes 65 are provided as the “first lower contact 23.” The plurality of first electrodes 65 penetrate the principal surface insulating film 64 and are connected to the plurality of first mesa portions 53, respectively. Specifically, the plurality of first electrodes 65 are located in a plurality of first connection openings 66 formed in the principal surface insulating film 64.

Each of the plurality of first electrodes 65 is formed of metal. In this form, each of the plurality of first electrodes 65 has a laminated structure including a first barrier film 67 and a first electrode body 68. The first barrier film 67 is formed in a film shape along the inner wall of the first connection opening 66. The first barrier film 67 may be formed of a titanium-based metal film. The first barrier film 67 may have a single-layer structure or a laminated structure including one or both of a titanium film and a titanium nitride film.

The first electrode body 68 is embedded in the first connection opening 66 with the first barrier film 67 interposed therebetween, and is electrically connected to the first mesa portion 53 (first contact region 22) with the first barrier film 67 interposed therebetween. The first electrode body 68 may include at least one of tungsten, aluminum, copper, an aluminum alloy, and a copper alloy. In this form, the first electrode body 68 includes tungsten. As a matter of course, the plurality of first electrodes 65 may not have the first barrier film 67 and may be constituted only by the first electrode body 68.

Referring to FIGS. 8 and 10, the semiconductor device 1A includes a plurality of second electrodes 69 electrically connected to the first semiconductor region 46 in the plurality of second mesa portions 54. The plurality of second electrodes 69 are provided as “second lower contacts 25” in this form. The plurality of second electrodes 69 penetrate the principal surface insulating film 64 and are connected to the plurality of second mesa portions 54. Specifically, each of the plurality of second electrodes 69 is located in a plurality of second connection openings 70 formed in the principal surface insulating film 64.

Each of the plurality of second electrodes 69 is formed of metal. In this form, each of the plurality of second electrodes 69 has a laminated structure including the second barrier film 71 and the second electrode body 72. The second barrier film 71 is formed in a film shape along the inner wall of the second connection opening 70. The second barrier film 71 may be formed of a titanium-based metal film. The second barrier film 71 may have a single-layer structure or a laminated structure including one or both of a titanium film and a titanium nitride film.

The second electrode body 72 is embedded in the second connection opening 70 with the second barrier film 71 interposed therebetween, and is electrically connected to the second mesa portion 54 (second contact region 24) with the second barrier film 71 interposed therebetween. The second electrode body 72 may include at least one of tungsten, aluminum, copper, an aluminum alloy, and a copper alloy. The second electrode body 72 includes tungsten in this form. As a matter of course, the plurality of second electrodes 69 may not have the second barrier film 71 and may be constituted only by the second electrode body 72.

Referring to FIGS. 8 and 11, the semiconductor device 1A includes a plurality of second trench structures 73 formed on the first principal surface 10 in the plurality of drift mesa portions 55.

In this form, the plurality of second trench structures 73 are formed in the corresponding drift mesa portions 55 penetrating through the principal surface insulating film 64. Specifically, each of the plurality of second trench structures 73 are formed in the drift mesa portion 55 through the plurality of base connection openings 74 formed in the principal surface insulating film 64. Referring to FIG. 8, the second trench structure 73 is selectively formed in the contact region 61 and is not formed in the current region 62.

Referring to FIG. 11, the plurality of second trench structures 73 are formed to reach the protrusion portion 59. In this form, the plurality of second trench structures 73 are formed shallower than the plurality of first trench structures 17. Specifically, the plurality of second trench structures 73 penetrate the first impurity region 63 and reach the protrusion portion 59. Each of the plurality of second trench structures 73 has a bottom wall positioned in the protrusion portion 59.

The interval between the first trench structure 17 and the second trench structure 73 may be 0.01 μm or more and 10 μm or less (preferably 0.1 μm or more and 0.5 μm or less). Each of the plurality of second trench structures 73 may have a width of 0.01 μm or more and 10 μm or less (preferably 0.1 μm or more and 0.5 μm or less) in the first direction X. The width of the plurality of second trench structures 73 may be equal to or larger than the width of the first trench structure 17 or may be smaller than the width of the first trench structure 17. Each of the plurality of second trench structures 73 may have a depth of 0.1 μm or more and 10 μm or less (preferably 0.2 μm or more and 0.5 μm or less). With this depth, a silicide layer 79 (described later) can be formed over the entire second trench structure 73.

The second trench structure 73 includes a base trench 75 and a base electrode 76. In this form, the base electrode 76 is provided as a “first base contact 26.”

The base trench 75 is formed on the first principal surface 10 penetrating through the principal surface insulating film 64, and defines the wall surface (side wall and bottom wall) of the second trench structure 73. In this form, the base trench 75 includes the base connection opening 74 formed in the principal surface insulating film 64. Specifically, the base trench 75 penetrates the principal surface insulating film 64 and the first impurity region 63 to reach the protrusion portion 59. The base trench 75 exposes the first impurity region 63 and the protrusion portion 59 from the wall surface.

The base trench 75 may be formed in a tapered shape in which the opening width narrows from the first principal surface 10 side toward the bottom wall side in a cross-sectional view. As a matter of course, the base trench 75 may be formed perpendicular to the first principal surface 10. The bottom wall side corner portion of the base trench 75 may be formed in a curved shape. As a matter of course, the entire bottom wall of the base trench 75 may be formed in a curved shape toward the second principal surface 11 side.

The base electrode 76 is embedded in the base trench 75 without an insulating film interposed therebetween. The base electrode 76 is mechanically and electrically connected to the first impurity region 63 and the protrusion portion 59 in the base trench 75, and is mechanically connected to the principal surface insulating film 64. In the base trench 75, the base electrode 76 has a part positioned on the semiconductor chip 8 side with respect to the first principal surface 10 and a part positioned on the principal surface insulating film 64 side with respect to the first principal surface 10. That is, the base electrode 76 has an upper end portion protruding upward from the first principal surface 10. The upper end portion of the base electrode 76 protrudes upward from the upper end portion of the gate electrode 50 (the upper end portion of the lead-out portion 52).

The base electrode 76 may include at least one of a metal and a non-metal conductor. The base electrode 76 is preferably formed of a conductive material different from the gate electrode 50. The base electrode 76 preferably includes a metal. In this form, the base electrode 76 has a laminated structure including the base barrier film 77 and the base electrode body 78.

The base barrier film 77 is formed in a film shape along the side wall and the bottom wall of the base trench 75, and covers the first impurity region 63, the protrusion portion 59, and the principal surface insulating film 64 in the base trench 75. The base barrier film 77 defines a recessed space in the base trench 75. The base barrier film 77 may be formed of a titanium-based metal film. The base barrier film 77 may have a single-layer structure or a laminated structure including one or both of a titanium film and a titanium nitride film. The base barrier film 77 is preferably formed of the same material as the first barrier film 67 and the second barrier film 71.

The base electrode body 78 is embedded in the base trench 75 with the base barrier film 77 interposed therebetween, and covers the first impurity region 63, the protrusion portion 59, and the principal surface insulating film 64 with the base barrier film 77 interposed therebetween. The base electrode body 78 is electrically connected to the first impurity region 63 and the protrusion portion 59 through the base barrier film 77. The base electrode body 78 may include at least one of tungsten, aluminum, copper, an aluminum alloy, and a copper alloy. The base electrode body 78 is preferably formed of the same material as the first electrode body 68 and the second electrode body 72. The base electrode body 78 includes tungsten in this form. As a matter of course, the base electrode 76 may not include the base barrier film 77, and may be constituted only by the base electrode body 78.

A silicide layer 79 is formed on an inner wall of the base trench 75. The silicide layer 79 is formed at the boundary portion between the semiconductor chip 8 and the base barrier film 77 over the entire side wall and bottom wall of the base trench 75. The silicide layer 79 may vertically cross the boundary portion between the first impurity region 63 and the protrusion portion 59 in the thickness direction of the semiconductor chip 8.

When the silicide layer 79 is formed over the entire side wall and bottom wall of the base trench 75, the surface state of the inner wall of the base trench 75 can be smoothly improved, and the base electrode body 78 and the base trench 75 can be favorably brought into contact with each other. Accordingly, the contact resistance of the base electrode body 78 can be reduced. As a result, the effect of fixing the potential of the second semiconductor region 47 to a predetermined potential can be sufficiently obtained only by forming the second trench structure 73 in the contact region 61 without forming the second trench structure 73 in the current region 62.

Referring to FIGS. 8 and 12, the semiconductor device 1A includes a plurality of third electrodes 80 electrically connected to the plurality of first trench structures 17. The plurality of third electrodes 80 are provided as “first gate contacts 27.” The plurality of third electrodes 80 penetrate the principal surface insulating film 64, and are mechanically and electrically connected to one or both of the plurality of first trench structures 17 (lead-out portions 52) and the plurality of trench connection structures 18 (connection electrodes 58).

Specifically, the plurality of third electrodes 80 are located in a plurality of third connection openings 81 formed in the principal surface insulating film 64. In this form, the plurality of third electrodes 80 are mechanically and electrically connected to the plurality of trench connection structures 18. That is, the plurality of third electrodes 80 are electrically connected to the plurality of first trench structures 17 through the plurality of trench connection structures 18.

Referring to FIG. 8, in this form, the plurality of third electrodes 80 are formed at intervals along the trench connection structure 18 in a plan view. The planar shape of the plurality of third electrodes 80 is arbitrary. The plurality of third electrodes 80 may be formed in a circular shape or a quadrangular shape in a plan view. As a matter of course, each of the plurality of third electrodes 80 may be formed in a band shape extending along the corresponding trench connection structure 18 in a plan view.

Each of the plurality of third electrodes 80 is formed of metal. In this form, each of the plurality of third electrodes 80 has a laminated structure including the third barrier film 82 and the third electrode body 83. The third barrier film 82 is formed in a film shape along the inner wall of the third connection opening 81. The third barrier film 82 may be formed of a titanium-based metal film. The third barrier film 82 may have a single-layer structure or a laminated structure including one or both of a titanium film and a titanium nitride film. The third barrier film 82 is preferably formed of the same material as the first barrier film 67, the second barrier film 71, and the base barrier film 77.

The third electrode body 83 is embedded in the third connection opening 81 with the third barrier film 82 interposed therebetween, and is electrically connected to the lead-out portion 52 (connection electrode 58) with the third barrier film 82 interposed therebetween. The third electrode body 83 may include at least one of tungsten, aluminum, copper, an aluminum alloy, and a copper alloy. The third electrode body 83 is preferably formed of the same material as the first electrode body 68. The third electrode body 83 includes tungsten in this form. As a matter of course, the plurality of third electrodes 80 may not have the third barrier film 82 and may be constituted only by the third electrode body 83.

Referring to FIGS. 9 to 12, the semiconductor device 1A includes a p-type bottom wall impurity region 84 formed in a region along the bottom wall of the first trench structure 17 in the second semiconductor region 47. In this form, the bottom wall impurity region 84 is formed in the second semiconductor region 47 and has a p-type impurity concentration higher than that of the second semiconductor region 47. The p-type impurity concentration of the bottom wall impurity region 84 may be 1×10¹⁶ cm⁻³ or more and 1×10¹⁹ cm⁻³ or less (in this form, about 1×10¹⁷ cm⁻³).

The bottom wall impurity region 84 is formed in a band shape extending along the bottom wall of the first trench structure 17 with a space from the plurality of second trench structures 73 in a plan view. The bottom wall impurity region 84 opposes the gate electrode 50 with the gate insulating film 49 interposed therebetween at the bottom wall of the first trench structure 17. The bottom wall impurity region 84 may cover the bottom wall and the side wall of the first trench structure 17 at the lower end portion of the first trench structure 17.

The bottom wall impurity region 84 may cover the bottom wall of the trench connection structure 18 in the second semiconductor region 47. In this case, the bottom wall impurity region 84 may be formed in a band shape extending along the bottom wall of the trench connection structure 18 in a plan view. As a matter of course, the bottom wall impurity region 84 may expose the bottom wall of the trench connection structure 18.

The bottom wall impurity region 84 may have a thickness of 10 nm or more and 500 nm or less. A thickness of the bottom wall impurity region 84 is preferably 100 nm or more and 300 nm or less. The thickness of the bottom wall impurity region 84 is a distance between the bottom wall of the first trench structure 17 and the bottom portion of the bottom wall impurity region 84. The bottom wall impurity region 84 has a width exceeding the width of the bottom wall of the first trench structure 17 in the first direction X. The width of the bottom wall impurity region 84 is defined by the width of the most bulging region in the bottom wall impurity region 84. The width of the bottom wall impurity region 84 may exceed the opening width of the first trench structure 17. The width of the bottom wall impurity region 84 may be 0.1 μm or more and 0.5 μm or less.

Referring to FIGS. 9 to 12, the semiconductor device 1A includes a first interlayer insulating film 85 laminated on the principal surface insulating film 64. The first interlayer insulating film 85 may be a part of the insulating layer 9 described above. The first interlayer insulating film 85 may include at least one of silicon oxide and silicon nitride. The first interlayer insulating film 85 covers the entire region of the principal surface insulating film 64 and is continuous with the first to fourth side surfaces 12A to 12D. The first interlayer insulating film 85 may have a flat surface extending along the first principal surface 10. The flat surface of the first interlayer insulating film 85 may have a grinding mark.

The first wiring layer 28 is formed on the first interlayer insulating film 85. The first wiring layer 28 may include at least one of titanium, tungsten, aluminum, copper, an aluminum alloy, a copper alloy, and conductive polysilicon. The first wiring layer 28 may include at least one of a Cu film (Cu film having a purity of 99% or more), a pure Al film (Al film having a purity of 99% or more), an AlCu alloy film, an AlSi alloy film, and an AlSiCu alloy film.

As described above, the first wiring layer 28 includes the first gate wiring layer 30, the first lower wiring layer 31, the second lower wiring layer 32, and the first base wiring layer 33. The first gate wiring layer 30 is connected to the first gate contact 27 (FIG. 12), and the first lower wiring layer 31 is connected to the first lower contact 23 (FIG. 9). The second lower wiring layer 32 is connected to the second lower contact 25 (FIG. 10), and the first base wiring layer 33 is connected to the first base contact 26 (FIG. 11).

Referring to FIGS. 9 to 12, the semiconductor device 1A includes a second interlayer insulating film 86 laminated on the first interlayer insulating film 85 to cover the first wiring layer 28. The second interlayer insulating film 86 may be a part of the insulating layer 9 described above. The second interlayer insulating film 86 may include at least one of silicon oxide and silicon nitride. The second interlayer insulating film 86 covers the entire region of the first interlayer insulating film 85 and is continuous with the first to fourth side surfaces 12A to 12D. The second interlayer insulating film 86 may have a flat surface extending along the first principal surface 10. The flat surface of the second interlayer insulating film 86 may have a grinding mark.

The second wiring layer 29 is formed on the second interlayer insulating film 86. The second wiring layer 29 may include at least one of titanium, tungsten, aluminum, copper, an aluminum alloy, a copper alloy, and conductive polysilicon. The second wiring layer 29 may include at least one of a Cu film (Cu film having a purity of 99% or more), a pure Al film (Al film having a purity of 99% or more), an AlCu alloy film, an AlSi alloy film, and an AlSiCu alloy film.

As described above, the second wiring layer 29 includes the second gate wiring layer 34, the first upper wiring layer 35, the second upper wiring layer 36, and the second base wiring layer 37. The second gate wiring layer 34 is connected to the first gate wiring layer 30 through a second gate contact 38 penetrating the second interlayer insulating film 86 (FIG. 6), and the first upper wiring layer 35 is connected to the first lower wiring layer 31 through a first upper contact 40 penetrating the second interlayer insulating film 86 (FIG. 6). The second upper wiring layer 36 is connected to the second lower wiring layer 32 through the second upper contact 41 penetrating the second interlayer insulating film 86 (FIG. 6), and the second base wiring layer 37 is connected to the first base wiring layer 33 through the second base contact 39 penetrating the second interlayer insulating film 86 (FIG. 6).

Referring to FIG. 12, the semiconductor device 1A includes an uppermost insulating film 87 formed on the second interlayer insulating film 86. In FIGS. 9 to 11, the uppermost insulating film 87 is omitted. The uppermost insulating film 87 may be a part of the insulating layer 9 described above. The uppermost insulating film 87 may be referred to as a “passivation film.” The uppermost insulating film 87 may have a laminated structure including an inorganic insulating film (inorganic film) and an organic insulating film (organic film) laminated in this order from the second interlayer insulating film 86 side. As a matter of course, the uppermost insulating film 87 may have a single-layer structure formed of an inorganic insulating film (inorganic film) or an organic insulating film (organic film). The inorganic insulating film is preferably formed of an insulating material different from that of the second interlayer insulating film 86. The inorganic insulating film may be formed of, for example, a silicon nitride film. The organic insulating film may be formed of a photosensitive resin. The organic insulating film may include at least one of a polyimide film, a polyamide film, and a polybenzoxazole film.

The plurality of external terminals 4 to 7 are formed on the uppermost insulating film 87 (see FIG. 7). As described above, the plurality of external terminals 4 to 7 include the base terminal 4, the gate terminal 5, the first source/drain terminal 6, and the second source/drain terminal 7. The base terminal 4 is connected to the second base wiring layer 37 through a base terminal contact 43 penetrating the uppermost insulating film 87 (FIG. 7), and the gate terminal 5 is connected to the second gate wiring layer 34 through the gate terminal contact 42 penetrating the uppermost insulating film 87 (FIG. 7). The first source/drain terminal 6 is connected to the first upper wiring layer 35 through the first terminal contact 44 penetrating the uppermost insulating film 87 (FIG. 7), and the second source/drain terminal 7 is connected to the second upper wiring layer 36 through the second terminal contact 45 penetrating the uppermost insulating film 87 (FIG. 7).

Referring to FIGS. 9 to 12, the semiconductor device 1A includes a rear surface protection film 88 covering the second principal surface 11 of the semiconductor chip 8. In this form, the rear surface protection film 88 covers the entire region of the second principal surface 11, and further covers the first to fourth side surfaces 12A to 12D (FIG. 12). The rear surface protection film 88 may have a single-layer structure formed of an inorganic insulating film (inorganic film) or an organic insulating film (organic film). The inorganic insulating film may be formed of, for example, a silicon nitride film. The organic insulating film may be formed of a photosensitive resin. The organic insulating film may include at least one of a polyimide film, a polyamide film, and a polybenzoxazole film.

Referring to FIGS. 9 to 11, the semiconductor device 1A includes a first pn junction portion 89 and a second pn junction portion 90 formed inside the semiconductor chip 8. The first pn junction portion 89 is formed at the boundary portion 60 between the first semiconductor region 46 and the second semiconductor region 47 on the first mesa portion 53 side. As a result, the first body diode D1 including the second semiconductor region 47 as the anode region and the first semiconductor region 46 as the cathode region is formed in the first mesa portion 53.

The second pn junction portion 90 is formed at the boundary portion 60 between the first semiconductor region 46 and the second semiconductor region 47 on the second mesa portion 54 side. As a result, the second body diode D2 including the second semiconductor region 47 as the anode region and the first semiconductor region 46 as the cathode region is formed in the second mesa portion 54. The anode of the second body diode D2 (second pn junction portion 90) is electrically connected to the anode of the first body diode D1 (first pn junction portion 89) through the second semiconductor region 47).

### (2) Manufacturing Process of Semiconductor Device 1A

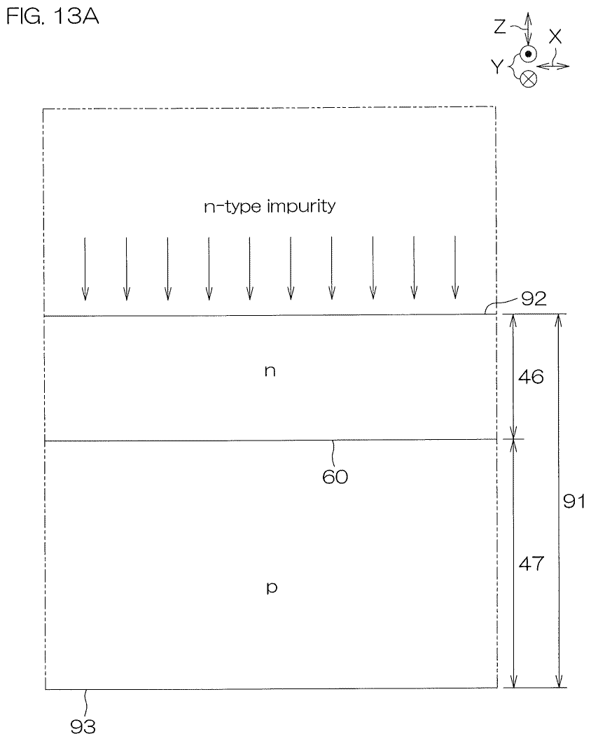

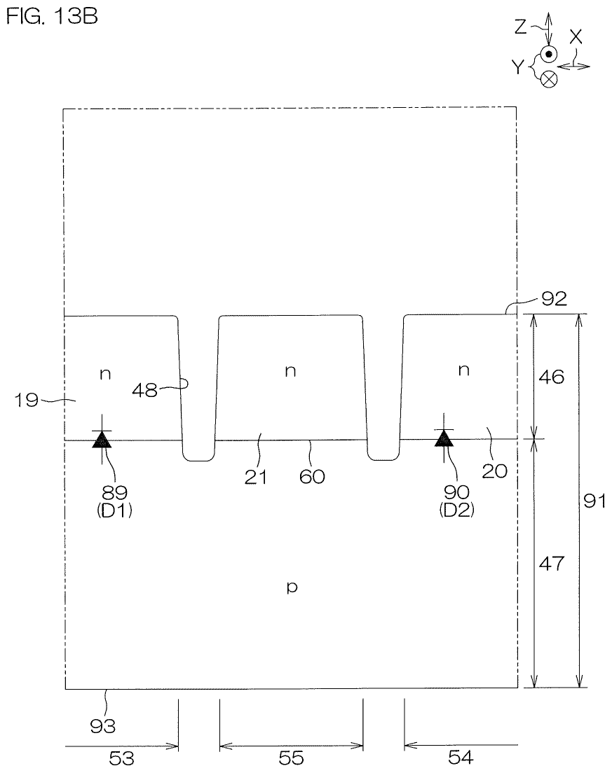

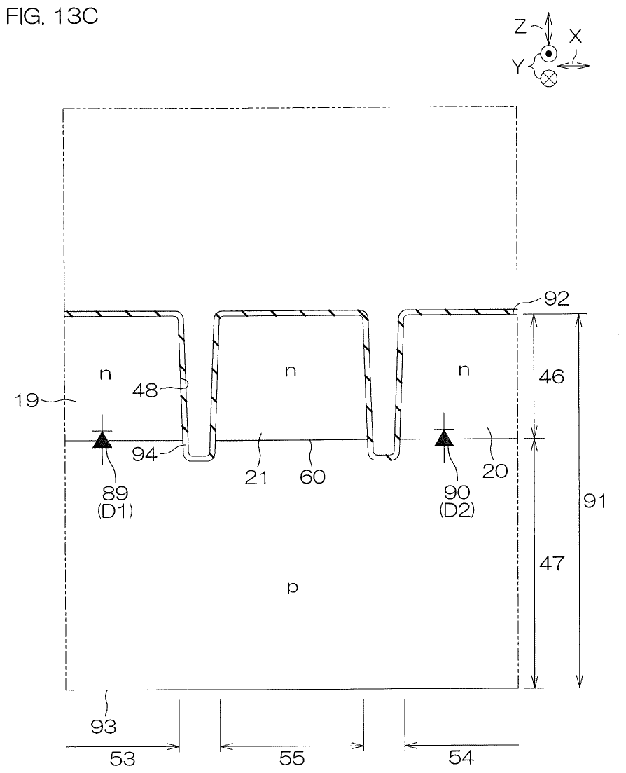

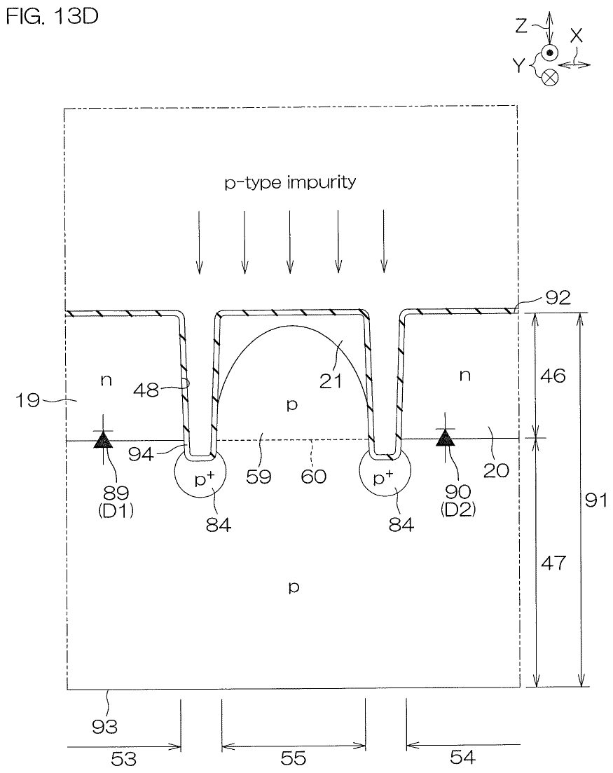

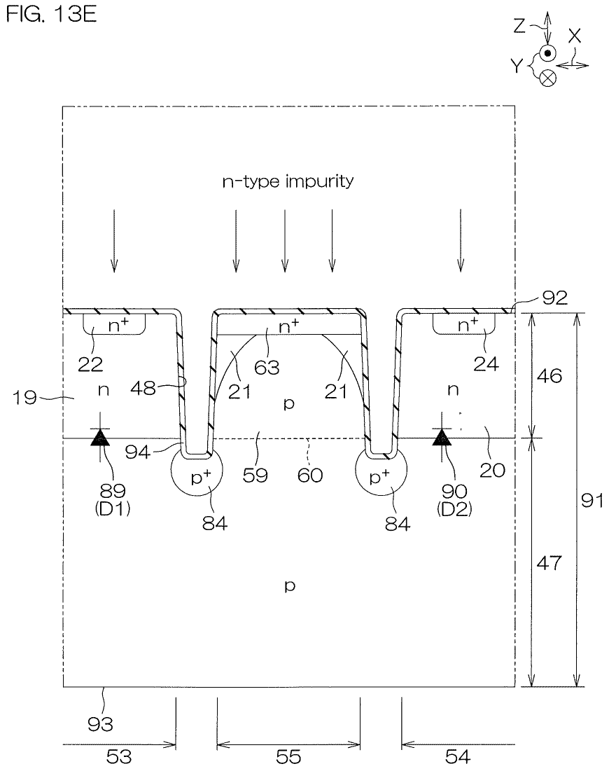

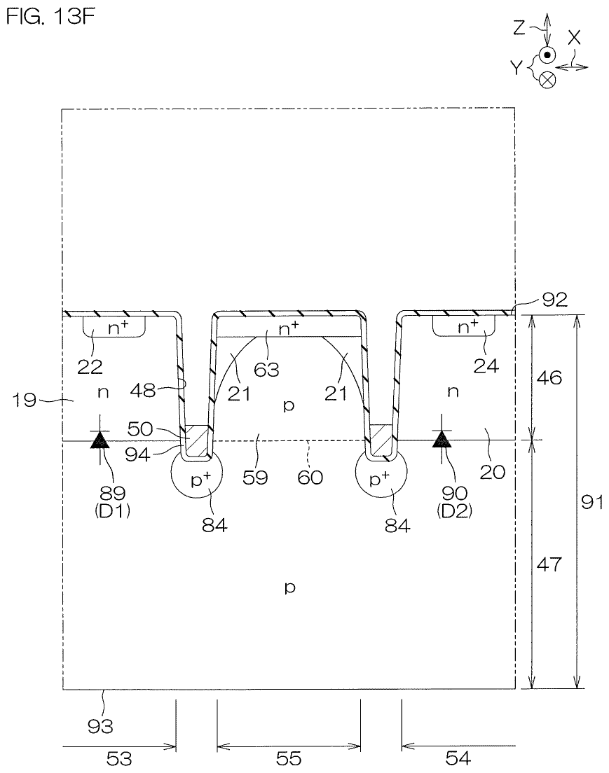

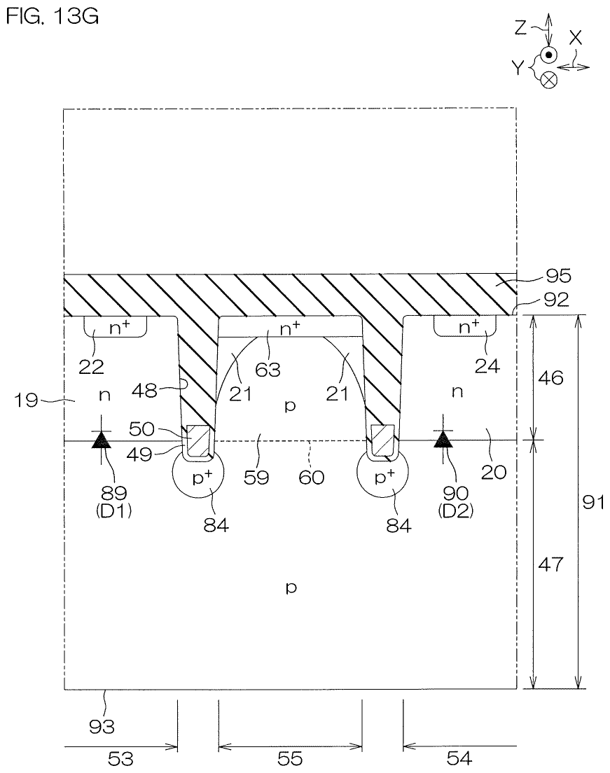

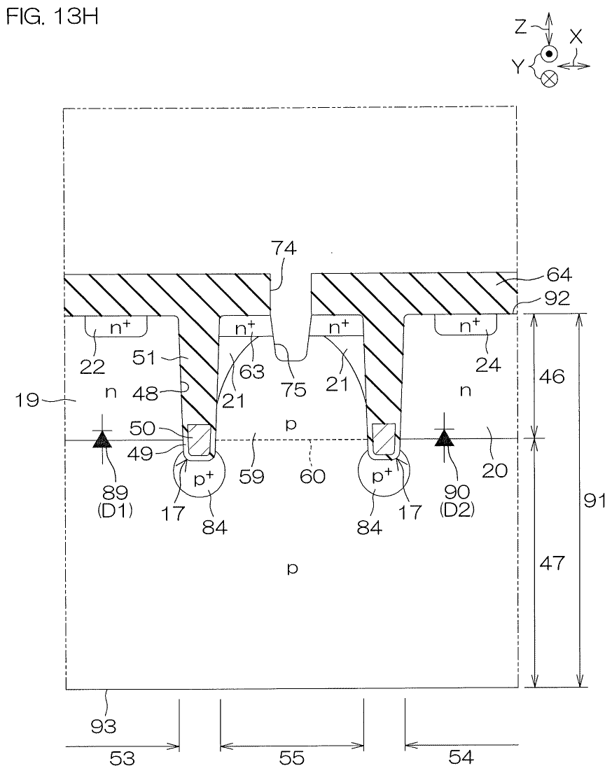

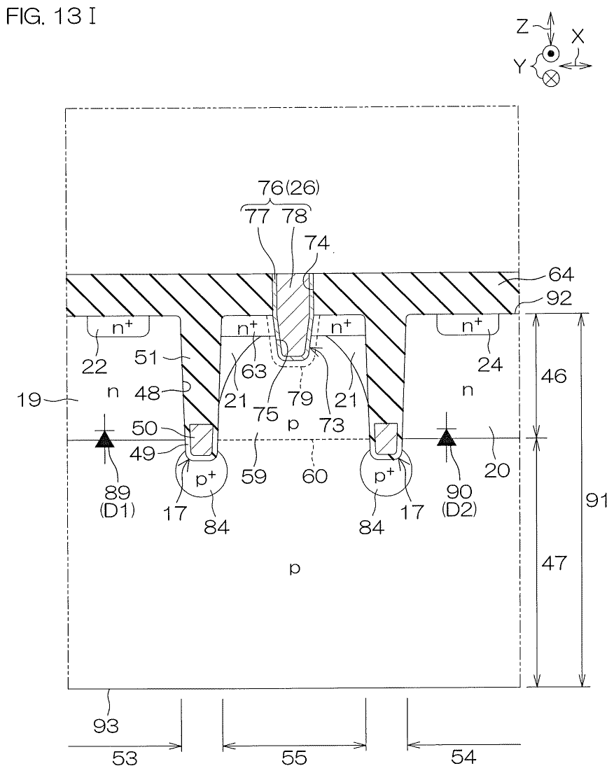

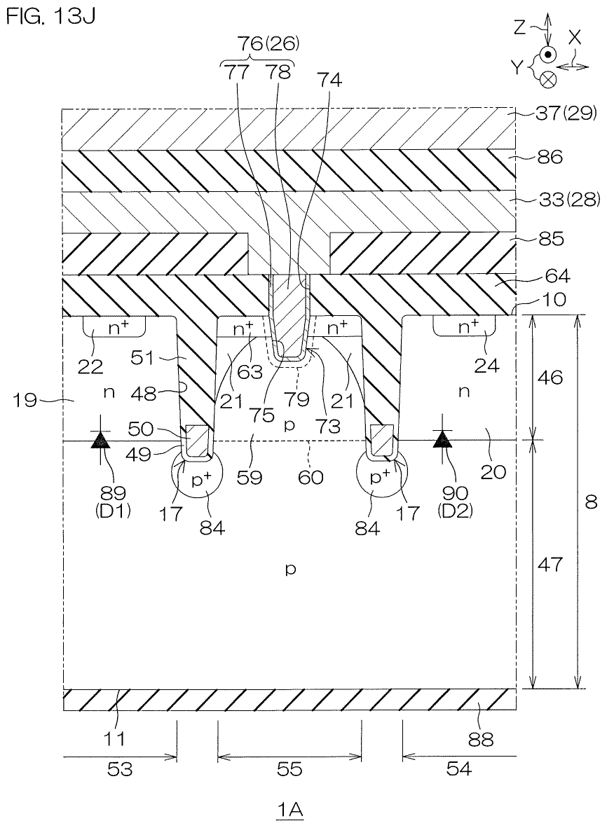

Next, an example of a method of manufacturing the semiconductor device 1A will be described. FIGS. 13A to 13J are cross-sectional views illustrating an example of a method of manufacturing the semiconductor device 1A illustrated in FIG. 1. FIGS. 13A to 13J are cross-sectional views of a region corresponding to FIG. 11.

Referring to FIG. 13A, a disk-shaped wafer 91 is prepared. The wafer 91 includes a first wafer principal surface 92 on one side and a second wafer principal surface 93 on the other side.

The wafer 91 is formed of a p-type semiconductor substrate entirely formed of the second semiconductor region 47. Next, the first semiconductor region 46 is formed on the surface layer portion of the first wafer principal surface 92. The first semiconductor region 46 is formed by introducing n-type impurities into the surface layer portion of the first wafer principal surface 92 by an ion implantation method. The n-type impurity may be introduced into the entire surface layer portion of the first wafer principal surface 92 without an ion implantation mask.

As a matter of course, the n-type impurity may be introduced into a region where the first semiconductor region 46 is to be formed in the surface layer portion of the first wafer principal surface 92 through the ion implantation mask. Furthermore, the first semiconductor region 46 may be formed by growing silicon from the second semiconductor region 47 (semiconductor substrate) by an epitaxial growth method. In this case, the first wafer principal surface 92 is formed by the crystal plane (crystal growth plane) of the first semiconductor region 46.

Referring to FIG. 13B, a plurality of first trenches 48 and a plurality of connection trenches 56 are formed on the first wafer principal surface 92. In this step, unnecessary portions of the wafer 91 are selectively removed by an etching method through a hard mask (not illustrated). The etching method may be a wet etching method and/or a dry etching method. The etching method is preferably a reactive ion etching (RIE) method as an example of a dry etching method. As a result, the plurality of first trenches 48 and the plurality of connection trenches 56 are formed. In addition, the plurality of mesa portions 53 to 55 are partitioned on the first wafer principal surface 92 by the plurality of first trenches 48 (the plurality of connection trenches 56). The hard mask is then removed.

Referring to FIG. 13C, a first base insulating film 94 serving as a base of the plurality of gate insulating films 49 and the plurality of connection insulating films 57 is formed on the first wafer principal surface 92. The first base insulating film 94 is formed on the first wafer principal surface 92 including the inner walls of the plurality of first trenches 48 and the inner walls of the plurality of connection trenches 56. The first base insulating film 94 may be formed by an oxidation treatment method and/or a CVD method (preferably, a thermal oxidation treatment method).

Referring to FIG. 13D, a plurality of bottom wall impurity regions 84 are formed in a region along the bottom walls of the plurality of first trenches 48 and the bottom walls of the plurality of connection trenches 56 in the second semiconductor region 47. Further, in parallel therewith, the protrusion portion 59 is selectively formed in the drift mesa portion 55. In this step, first, an ion implantation mask (not illustrated) having a predetermined pattern is formed on the first wafer principal surface 92. Next, a p-type impurity is selectively introduced into the second semiconductor region 47 by an ion implantation method through the ion implantation mask. As a result, a plurality of bottom wall impurity regions 84 and protrusion portions 59 are formed. The ion implantation mask is then removed.

Referring to FIG. 13E, the plurality of first contact regions 22, the plurality of second contact regions 24, and the plurality of first impurity regions 63 are formed. In this step, first, an ion implantation mask (not illustrated) having a predetermined pattern is formed on the first wafer principal surface 92. Next, n-type impurities are selectively introduced into the first semiconductor region 46 by an ion implantation method through the ion implantation mask. As a result, the plurality of first contact regions 22, the plurality of second contact regions 24, and the plurality of first impurity regions 63 are formed. The ion implantation mask is then removed.

Referring to FIG. 13F, a first base electrode (not illustrated) serving as a base of the plurality of gate electrodes 50, the plurality of lead-out portions 52, and the plurality of connection electrodes 58 is formed on the first wafer principal surface 92. The first base electrode is formed in a film shape to cover the first wafer principal surface 92 by filling the plurality of first trenches 48 and the plurality of connection trenches 56. In this form, the first base electrode includes conductive polysilicon. The first base electrode may be formed by a CVD method. Next, an unnecessary portion of the first base electrode is removed. As a result, the plurality of gate electrodes 50, the plurality of lead-out portions 52, and the plurality of connection electrodes 58 are formed.

Referring to FIG. 13G, a second base insulating film 95 serving as a base of the embedded insulator 51 and the principal surface insulating film 64 is formed on the first wafer principal surface 92. In this form, the second base insulating film 95 is formed of a silicon oxide film. The second base insulating film 95 may be formed by a CVD method. The CVD method of the second base insulating film 95 is preferably a high density plasma (HDP)-CVD method.

The second base insulating film 95 covers the first wafer principal surface 92, the plurality of lead-out portions 52, and the connection electrode 58 by filling a recessed space defined by the plurality of lead-out portions 52 in the plurality of first trenches 48. As a result, the embedded insulator 51 positioned in the first trench 48 and the principal surface insulating film 64 positioned on the first wafer principal surface 92 are formed.

Referring to FIG. 13H, the plurality of first connection openings 66, the plurality of second connection openings 70, the plurality of third connection openings 81, and the plurality of base trenches 75 (base connection openings 74) are formed on the first wafer principal surface 92. In this step, first, a resist mask (not illustrated) having a predetermined pattern is formed on the principal surface insulating film 64. Next, an unnecessary portion of the principal surface insulating film 64 is selectively removed by an etching method through a resist mask. The etching method may be a wet etching method and/or a dry etching method (preferably the RIE method). Thereby, the plurality of first connection openings 66, the plurality of second connection openings 70, the plurality of third connection openings 81, and the plurality of base connection openings 74 are formed in the principal surface insulating film 64.

Next, an unnecessary portion of the wafer 91 is removed by an etching method through the resist mask. The etching method may be a wet etching method and/or a dry etching method (preferably the RIE method). An unnecessary portion of the wafer 91 penetrates the first impurity region 63 and is removed until the protrusion portion 59 is exposed. Thereby, the plurality of base trenches 75 each including the base connection opening 74 are formed on the first wafer principal surface 92. The resist mask is then removed.

Referring to FIG. 13I, a second base electrode (not illustrated) serving as a base of the plurality of first electrodes 65, the plurality of second electrodes 69, the plurality of base electrodes 76, and the plurality of third electrodes 80 is formed on the principal surface insulating film 64. In this form, the second base electrode has a base barrier film and an electrode body film laminated in this order from the wafer 91 side. Next, an unnecessary portion of the second base electrode is selectively removed by an etching method. The etching method may be a wet etching method and/or a dry etching method (preferably the RIE method). The second base electrode is removed until the principal surface insulating film 64 is exposed. As a result, the plurality of first electrodes 65, the plurality of second electrodes 69, the plurality of base electrodes 76, and the plurality of third electrodes 80 are formed. After these electrodes are formed, the silicide layer 79 is formed on the inner wall of the base trench 75 by annealing processing (for example, 500° C. or more and 1100° C. or less).

Thereafter, referring to FIG. 13J, the first interlayer insulating film 85, the first wiring layer 28, the second interlayer insulating film 86, the second wiring layer 29, the uppermost insulating film 87, the rear surface protection film 88, and the external terminals 4 to 7 are formed, and the wafer 91 is selectively cut in the thickness direction. The semiconductor device 1A is manufactured through the steps including the above-described steps.

### (3) Operation and Technical Effects of Semiconductor Device 1A

FIG. 14 is a cross-sectional view illustrating the current path 97 of the semiconductor device 1A according to the first preferred embodiment of the present disclosure. FIG. 15 is a plan view illustrating the current path 97 of the semiconductor device 1A according to the first preferred embodiment of the present disclosure.

The semiconductor device 1A has a trench gate lateral type MISFET structure. In this MISFET structure, a gate potential is applied to the first trench structure 17 (gate electrode 50), a drain potential is applied to the first mesa portion 53, and a source potential is applied to the second mesa portion 54. As a result, the channel 96 is formed in a region below the first trench structure 17 in the second semiconductor region 47, and the lateral current path 97 connecting the first electrode 65 (first mesa portion 53) and the second electrode 69 (second mesa portion 54) is formed.

As illustrated in FIG. 14, the current path 97 is a path through which a current flows in the order of the first mesa portion 53 (first semiconductor region 46)→the bottom wall impurity region 84 (high-concentration p-type region)→the drift mesa portion 55 (first semiconductor region 46)→the bottom wall impurity region 84 (high-concentration p-type region)→the second mesa portion 54 (first semiconductor region 46). That is, the current path 97 is hardly formed in the second semiconductor region 47. Therefore, even when the semiconductor chip 8 is formed by a single structure of a high resistance (in this form, 10 Ω·cm or more and 100 Ω·cm or less) semiconductor substrate, an increase in the on-resistance of the semiconductor device 1A can be suppressed. As a result, since it is not necessary to form an epitaxial layer on the wafer 91 in the manufacturing process of the semiconductor device 1A, the manufacturing process can be simplified, and the material and cost can be reduced.

In the semiconductor device 1A, as illustrated in FIG. 8, the drift region 21 is divided into the contact region 61 and the current region 62 in the second direction Y. The base electrode 76 for fixing the potential (substrate potential) of the second semiconductor region 47 is selectively formed in the contact region 61, and is not formed in the current region 62. As a result, the current path 97 connecting the first electrode 65 and the second electrode 69 at the shortest distance can be formed in the current region 62. That is, since the contact region 61 for fixing the substrate potential and the current region 62 for the current path 97 are separately located, a current can flow without bypassing the base electrode 76, so that the on-resistance can be reduced.

As illustrated in FIG. 11, in the contact region 61, the protrusion portion 59 extends toward the first principal surface 10. Thereby, the contact point with respect to the second semiconductor region 47 can be raised toward the first principal surface 10 side from the boundary portion 60 between the first semiconductor region 46 and the second semiconductor region 47. Therefore, it is not necessary to form the second trench structure 73 reaching the boundary portion 60, and the substrate potential can be fixed by the relatively shallow second trench structure 73. Since the base trench 75 is shallow, it is possible to secure a contact with respect to the substrate potential with a simple structure.

Referring to FIG. 11, for example, when the second trench structure 73 has a depth reaching the second principal surface 11 side from the boundary portion 60, the silicide layer 79 may be formed only locally on the inner wall of the base trench 75. Specifically, there is a case where the silicide layer 79 is locally formed on the bottom wall of the base trench 75 and the upper end portion of the side wall, and the silicide layer 79 is not formed on the other portion of the inner wall. On the other hand, in the structure illustrated in FIG. 11, since the base trench 75 is shallow, the silicide layer 79 can be formed over the entire second trench structure 73. Therefore, the surface state of the inner wall of the base trench 75 can be smoothly improved, and the base electrode body 78 and the base trench 75 can be favorably brought into contact with each other. Accordingly, the contact resistance of the base electrode body 78 can be reduced.

Since the contact region 61 for fixing the substrate potential is formed in the active region 15, it is not necessary to form an outer peripheral structure for fixing the substrate potential in the outer peripheral region 16. Therefore, the area of the outer peripheral region 16 can be reduced, and the area of the active region 15 can be enlarged. As a result, the current characteristics of the semiconductor device 1A can be improved. For example, in the semiconductor device 1A, the occupancy of the active region 15 on the first principal surface 10 may be 10% or more and 99.9% or less.

### (4) Modified Example of Semiconductor Device 1A

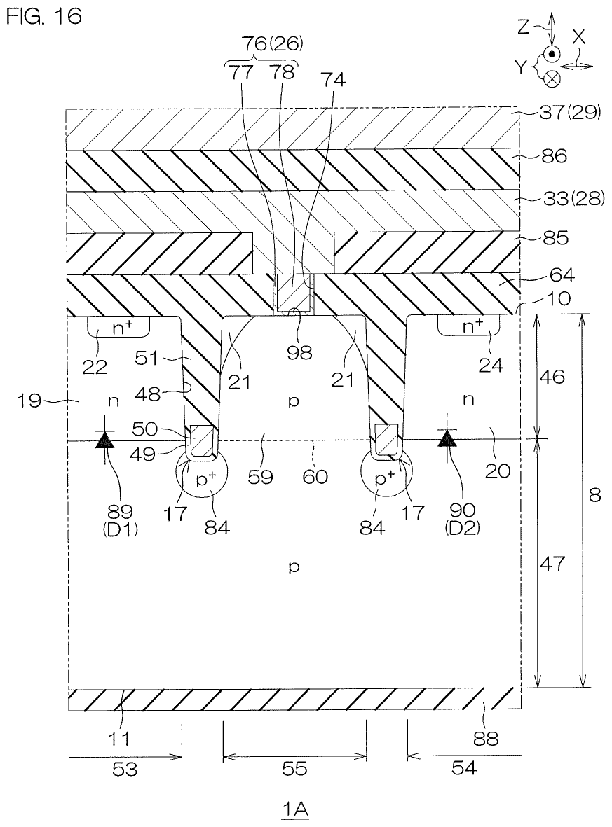

Next, modified examples of the semiconductor device 1A will be described with reference to FIGS. 16 to 18.

FIG. 16 is a cross-sectional view illustrating a first modified example of the semiconductor device 1A according to the first preferred embodiment of the present disclosure, and is a cross-sectional view corresponding to FIG. 11.

Referring to FIG. 16, the protrusion portion 59 may penetrate the drift mesa portion 55 from the second semiconductor region 47 and reach the first principal surface 10. Accordingly, the protrusion portion 59 may have an apex portion 98 exposed from first principal surface 10 in the contact region 61. In this case, the base electrode 76 may not be formed as the second trench structure 73. The base electrode 76 may be embedded in the base connection opening 74 and have a bottom portion on the first principal surface 10. Thus, the base electrode 76 is connected to the protrusion portion 59 at the first principal surface 10. According to this configuration, since the step of forming the second trench structure 73 can be omitted, the manufacturing step can be simplified, and the material and cost can be reduced.

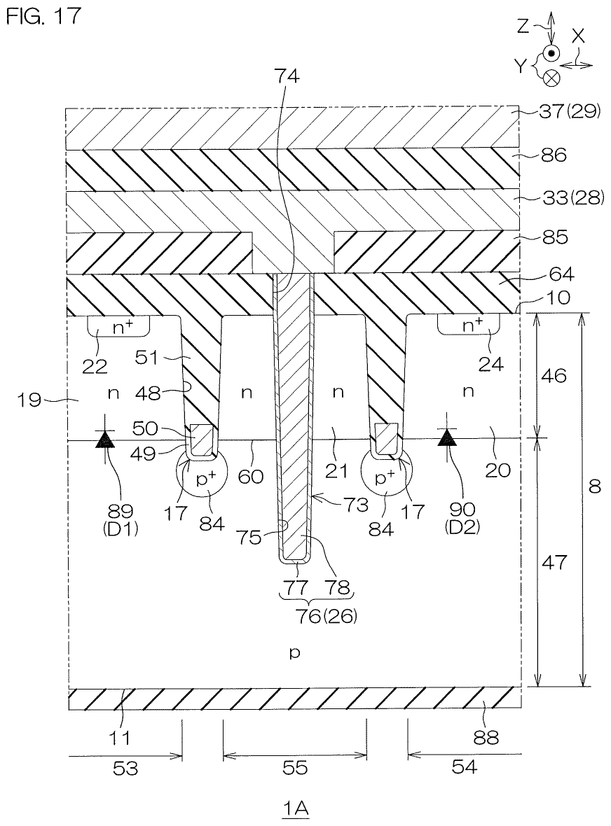

FIG. 17 is a cross-sectional view illustrating a second modified example of the semiconductor device 1A according to the first preferred embodiment of the present disclosure, and is a cross-sectional view corresponding to FIG. 11.

Referring to FIG. 17, the second trench structure 73 may be deeper than the first trench structure 17. Specifically, the base trench 75 deeper than the first trench 48 may cross the boundary portion 60 and reach the second semiconductor region 47. As a result, the step of forming the protrusion portion 59 can be omitted, so that the manufacturing step can be simplified, and the material and cost can be reduced.

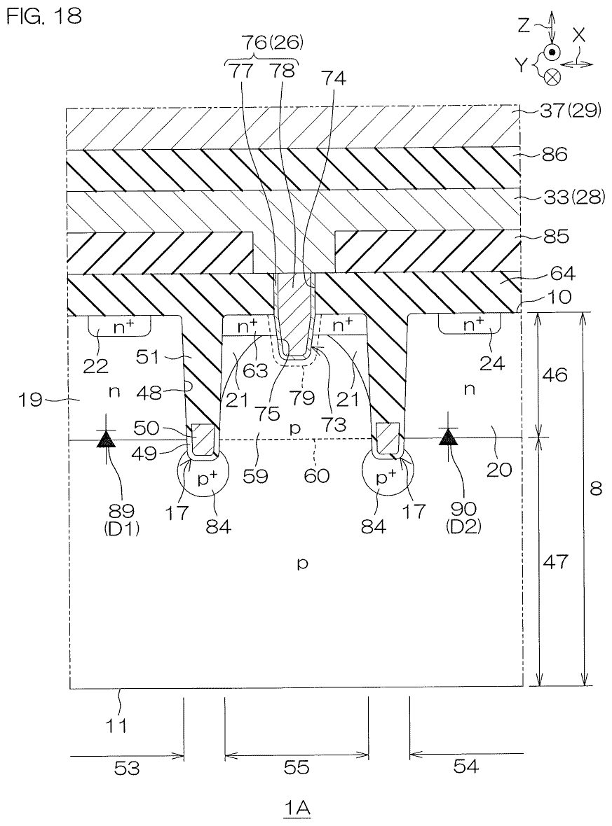

FIG. 18 is a cross-sectional view illustrating a third modified example of the semiconductor device 1A according to the first preferred embodiment of the present disclosure, and is a cross-sectional view corresponding to FIG. 11.

Referring to FIG. 18, the rear surface protection film 88 may not be formed on the second principal surface 11 of the semiconductor chip 8. The second principal surface 11 of the semiconductor chip 8 may be an exposed surface. As a result, since the step of forming the rear surface protection film 88 can be omitted, the manufacturing step can be simplified, and the material and cost can be reduced.

### Second Preferred Embodiment

### (1) Structure of Semiconductor Device 1B

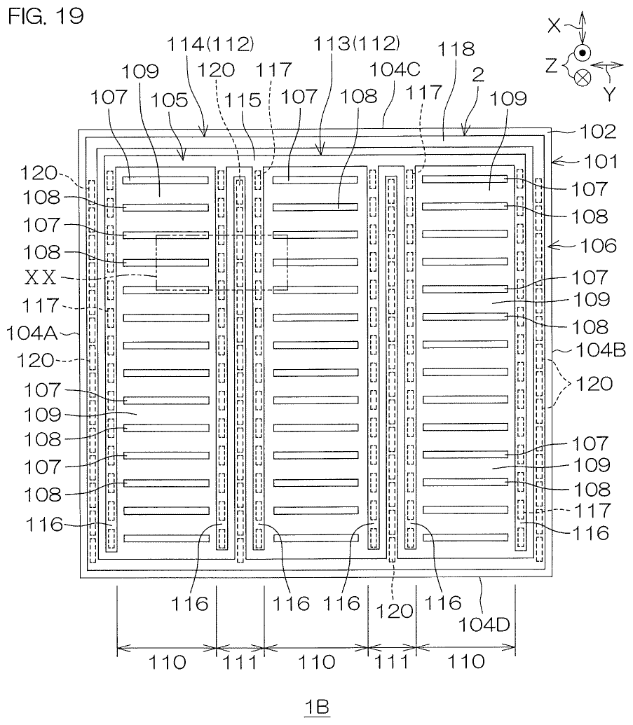

FIG. 19 is a schematic plan view illustrating an internal structure of a semiconductor device 1B according to a second preferred embodiment of the present disclosure. In the second preferred embodiment, the description of the external structure of the semiconductor device 1B such as the arrangement of the external terminals 4 to 7 illustrated in FIGS. 2 and 3 will be omitted, and the internal structure of the semiconductor device 1B will be mainly described.

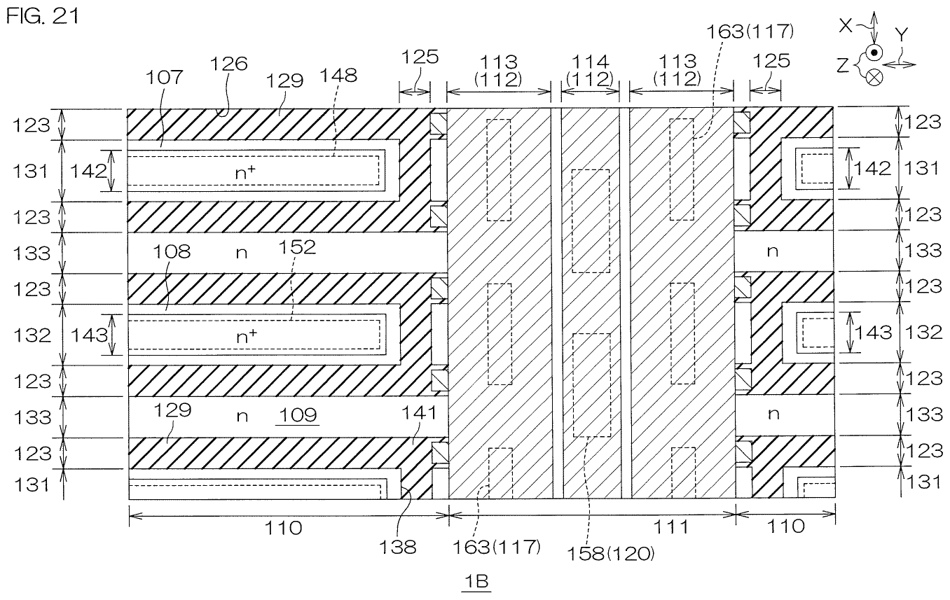

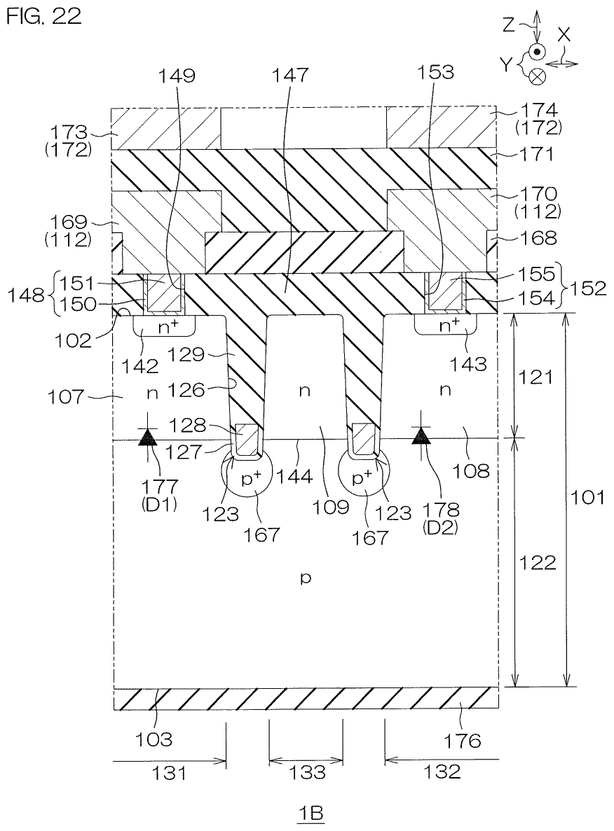

The semiconductor device 1B includes a semiconductor chip 101. The semiconductor chip 101 is formed in a rectangular parallelepiped shape. The semiconductor chip 101 includes a first principal surface 102 on one side, a second principal surface 103 on the other side (see FIG. 22 and subsequent drawings), and side surfaces 104A, 104B, 104C, and 104D connecting the first principal surface 102 and the second principal surface 103. Specifically, the side surfaces 104A to 104D include the first side surface 104A, the second side surface 104B, the third side surface 104C, and the fourth side surface 104D.

An active region 105 and an outer peripheral region 106 surrounding the active region 105 are set on the first principal surface 102 of the semiconductor chip 101.

The outer peripheral region 106 may coincide with an annular peripheral edge portion along the side surfaces 104A to 104D of the semiconductor chip 104. The outer peripheral region 106 may be an annular region from the side surfaces 104A to 104D of the semiconductor chip 101 to the inside by about several μm. The active region 105 may be a central region of the semiconductor chip 101 surrounded by the outer peripheral region 106. The active region 105 may be, for example, a region where most of the element structure of the MISFET 2 is formed.

In the active region 105, an element structure of the MISFET 2 is formed. In this form, the element structure is a trench gate lateral type metal insulator semiconductor field effect transistor (MISFET) structure.

The MISFET 2 includes a first source/drain region 107, a second source/drain region 108, and a drift region 109 as an element structure formed in the active region 105.

In this form, the plurality of first source/drain regions 107 and the plurality of second source/drain regions 108 are alternately located at intervals in the first direction X. The drift region 109 is sandwiched between the first source/drain region 107 and the second source/drain region 108 adjacent to each other. As a result, the first source/drain region 107 and the second source/drain region 108 oppose each other with the drift region 109 interposed therebetween. In FIG. 19, a set of the first source/drain region 107, the drift region 109, the second source/drain region 108, and the drift region 109 is repeatedly located in the first direction X in order from the upper side of the drawing.

On the first principal surface 102, the repetitive structure of the plurality of first source/drain regions 107, the plurality of second source/drain regions 108, and the plurality of drift regions 109 is divided into a plurality of sections and aggregated. The plurality of sections include a plurality of cell regions 110. The plurality of cell regions 110 are partitioned by a plurality of wiring regions 111 extending in the first direction X. In this form, two wiring regions 111 that divide the first principal surface 102 into three extend in the first direction X. A region having a constant width sandwiched between the two wiring regions 111 and a region outside each wiring region 111 in the second direction Y are the cell region 110. Thereby, a plurality of (in FIG. 19, three) cell regions 110 are located at intervals in the second direction Y. The wiring region 111 extends between the adjacent cell regions 110 in the first direction X and crosses the vicinity of each end portion of the plurality of first source/drain regions 107 and the plurality of second source/drain regions 108.

In each cell region 110, the first source/drain region 107 and the second source/drain region 108 are formed in a band shape extending in the second direction Y. The plurality of first source/drain regions 107, the plurality of second source/drain regions 108, and the plurality of drift regions 109 are located with regularity in which the same type of regions are aligned in the second direction Y.

In FIG. 19, a column in which the plurality of first source/drain regions 107 are aligned in the second direction Y and a column in which the plurality of second source/drain regions 108 are aligned in the second direction Y are alternately formed from the upper side of the drawing. A row in which the plurality of drift regions 109 are aligned in the second direction Y is formed between these regions. Thereby, the plurality of first source/drain regions 107, the plurality of second source/drain regions 108, and the plurality of drift regions 109 do not oppose different types of regions in the second direction Y. In other words, in FIG. 19, the plurality of first source/drain regions 107, the plurality of second source/drain regions 108, and the plurality of drift regions 109 extending in a band shape in the second direction Y may be divided into a plurality of portions by the plurality of wiring regions 111, and each portion may constitute one first source/drain region 107, one second source/drain region 108, and one drift region 109.

A plurality of wiring layers are formed on the first principal surface 102 of the semiconductor chip 101, and the plurality of external terminals described above are connected to the uppermost layer of the plurality of wiring layers. The plurality of wiring layers form a multilayer wiring structure, and only a first wiring layer 112 is illustrated in FIG. 19.

The first wiring layer 112 may be referred to as a “first metal.” The first wiring layer 112 includes a first gate wiring layer 113 and a first base wiring layer 114. The first wiring layer 112 includes other wiring layers, which will be described later. The first gate wiring layer 113 and the first base wiring layer 114 are wiring layers physically independent from each other.

The first gate wiring layer 113 includes a gate outer peripheral portion 115 extending along the outer peripheral region 106 and a gate branch portion 116 extending on the wiring region 111 and the outer peripheral edge of the semiconductor chip 101 from the gate outer peripheral portion 115 toward the inside of the semiconductor chip 101. The gate outer peripheral portion 115 linearly extends along the third side surface 104C on one side (in this form, the third side surface 104C side) in the first direction X of the plurality of cell regions 110. A part of the gate branch portion 116 is formed in a linear shape extending in pairs from the middle in the longitudinal direction of the gate outer peripheral portion 115 toward each wiring region 111. The pair of gate branch portions 116 are parallel to each other. The other portion of the gate branch portion 116 extends linearly on the outer peripheral region 106 from each of both end portions of the gate outer peripheral portion 115.

The first gate wiring layer 113 is connected to the first gate contact 117. In this form, the plurality of first gate contacts 117 are covered with the gate branch portion 116. In each gate branch portion 116, the plurality of first gate contacts 117 are located at intervals in the first direction X.

The first base wiring layer 114 includes a base outer peripheral portion 118 extending along the outer peripheral region 106 and a base branch portion 119 extending on the wiring region 111 from the base outer peripheral portion 118 toward the inside of the semiconductor chip 101.

The base outer peripheral portion 118 is formed in a closed ring shape collectively surrounding the plurality of cell regions 110 and the first gate wiring layer 113. In this form, the base outer peripheral portion 118 is formed in a quadrangular annular shape in a plan view. The base branch portion 119 is formed in a linear shape extending one by one from the middle in the longitudinal direction of one side of the base outer peripheral portion 118 toward each wiring region 111. In this form, each base branch portion 119 is located between the pair of gate branch portions 116 located in the wiring region 111 and is sandwiched between the pair of gate branch portions 116.

The first base wiring layer 114 is connected to the first base contact 120. In this form, the plurality of first base contacts 120 are covered with the base branch portion 119. In each base branch portion 119, the plurality of first base contacts 120 are located at intervals in the first direction X.

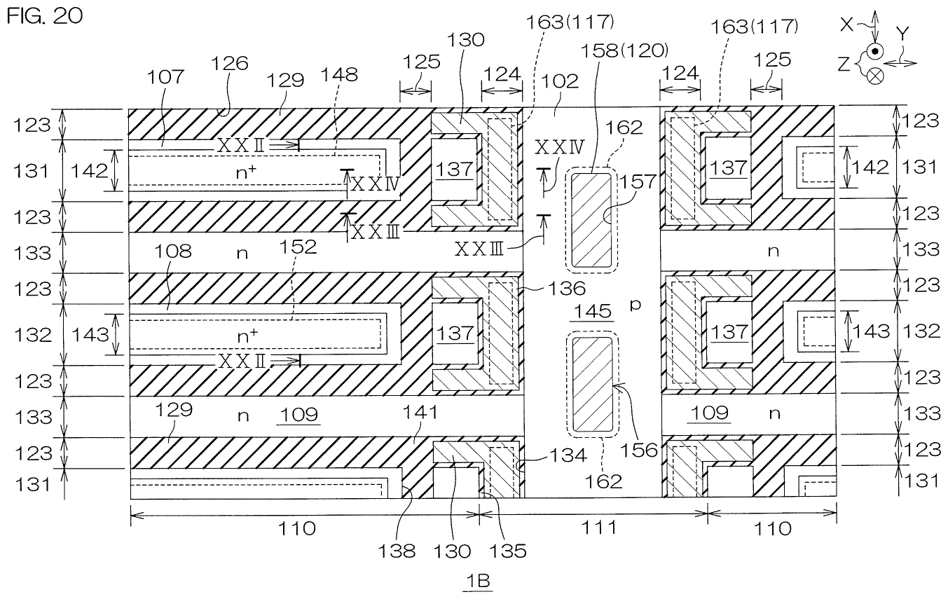

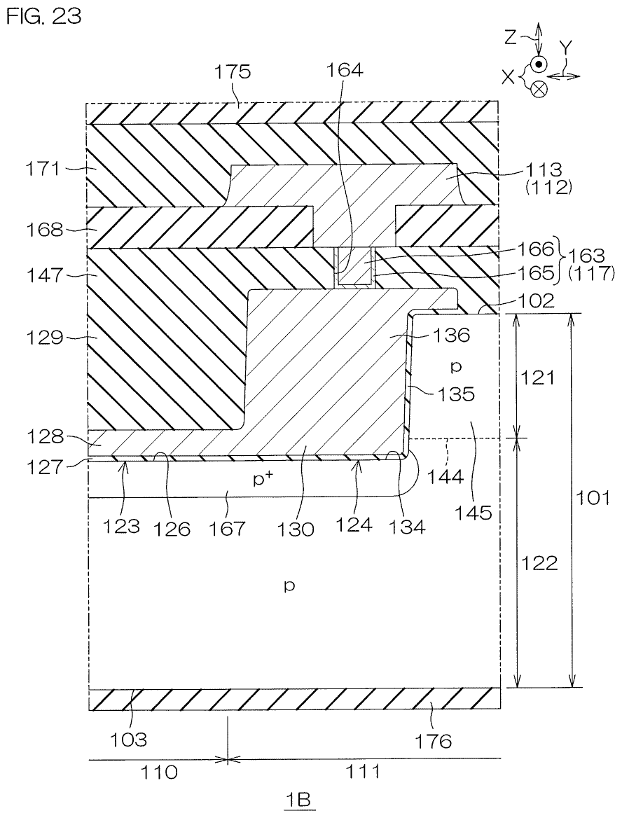

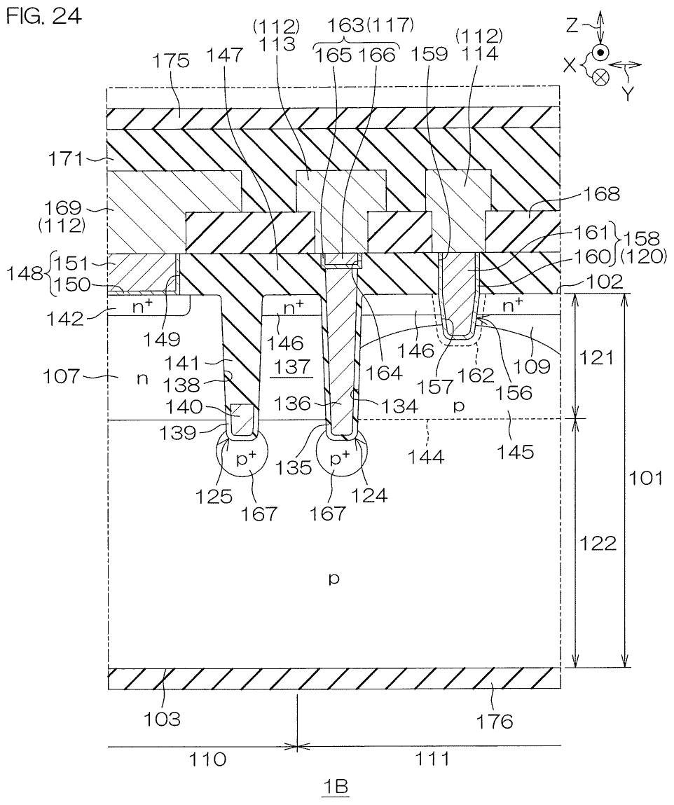

FIG. 20 is an enlarged view of a part surrounded by a two-dot chain line XX in FIG. 19. FIG. 21 is an enlarged view of a part surrounded by a two-dot chain line XX in FIG. 19. FIG. 22 is a cross-sectional view taken along line XXII-XXII of FIG. 20. FIG. 23 is a cross-sectional view taken along line XXIII-XXIII of FIG. 20. FIG. 24 is a cross-sectional view taken along line XXIV-XXIV of FIG. 20.

Referring to FIGS. 20 to 24, the semiconductor device 1B includes a semiconductor chip 101. The semiconductor chip 101 is a semiconductor chip 101 including a single layer. The semiconductor chip 101 formed of a single layer has a single structure of a semiconductor substrate having no epitaxial layer. In this form, the semiconductor chip 101 includes a single crystal of Si (silicon) or a wide bandgap semiconductor without an epitaxial layer. The wide band gap semiconductor is a semiconductor having a band gap exceeding a band gap of Si. The semiconductor chip 101 may be an Si chip or a silicon carbide (SiC) chip.

The semiconductor device 1B includes an n-type (first conductivity type) first semiconductor region 121 formed in a region on the first principal surface 102 side in the semiconductor chip 101. The first semiconductor region 121 may be referred to as a “drift layer.” The first semiconductor region 121 is formed in the semiconductor chip 101 with a space from the second principal surface 103 toward the first principal surface 102 side. The first semiconductor region 121 is formed in a layer shape extending along the first principal surface 102 in the surface layer portion of the first principal surface 102, and is exposed from the entire region of the first principal surface 102 and a part of the first to fourth side surfaces 104A to 104D.

As a matter of course, the first semiconductor region 121 may be formed in the inner portion of the first principal surface 102 with a space from the first to fourth side surfaces 104A to 104D in a plan view. The first semiconductor region 121 may have an n-type impurity concentration of 1×10¹⁴ cm⁻³ or more and 1×10¹⁸ cm⁻³ or less. The first semiconductor region 121 may have a thickness of 0.1 μm or more and 10 μm or less (preferably 0.5 μm or more and 2 μm or less).

The semiconductor device 1B includes a p-type (second conductivity type) second semiconductor region 122 formed in a region closer to the second principal surface 103 than the first semiconductor region 121 in the semiconductor chip 101. The second semiconductor region 122 may be referred to as a “base layer.” The second semiconductor region 122 may have a p-type impurity concentration of 1×10¹³ cm⁻³ or more and 1×10¹⁶ cm⁻³ or less. More specifically, in the thickness direction of the semiconductor chip 101, the p-type impurity concentration of the second semiconductor region 122 is 1×10¹³ cm⁻³ or more and 1×10¹⁶ cm⁻³ or less over an entire region from the second principal surface 103 to the first semiconductor region 121.

As described above, the reason why the p-type impurity concentration of the second semiconductor region 122 is substantially constant in the thickness direction of the semiconductor chip 101 is that the semiconductor chip 101 includes a semiconductor substrate having a single structure without an epitaxial layer. Normally, when an epitaxial layer is grown on a semiconductor substrate (base substrate), even when the epitaxial layer has the same conductivity type as that of the base substrate, the impurity concentration of the epitaxial layer is made relatively low to secure a withstand voltage. On the other hand, the impurity concentration of the base substrate is increased in order to reduce the ohmic resistance of the rear surface electrode formed on the second principal surface 103.

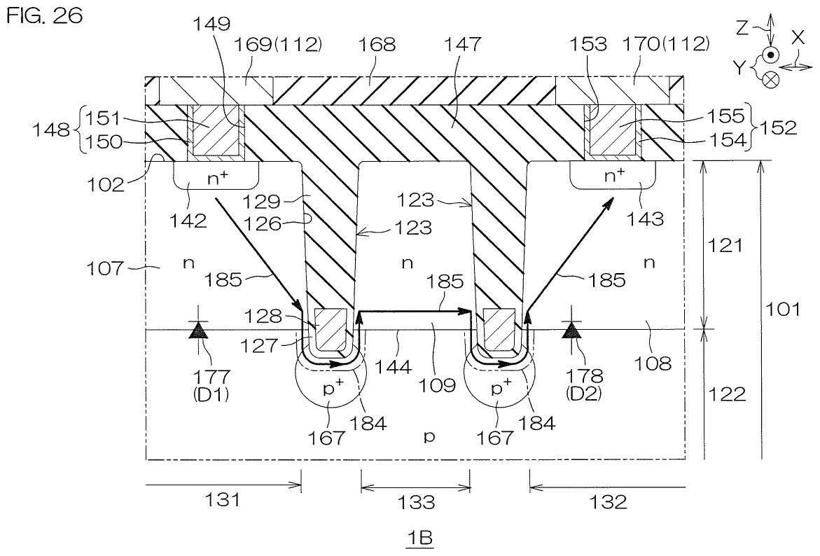

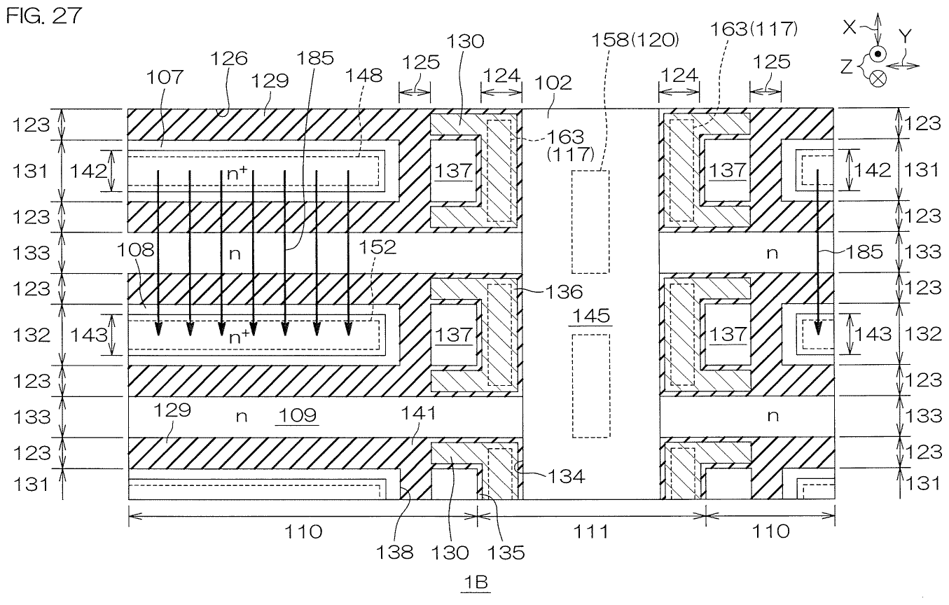

However, in this form, since the MISFET 2 is of a lateral type and a current path 185 (see FIGS. 26 and 27) is only in the lateral direction along the first principal surface 102, no current flows in the thickness direction of the second semiconductor region 122. Therefore, even when the p-type impurity concentration of the second semiconductor region 122 is low as a whole, there is little concern that the on-resistance increases. For example, the resistance value of the second semiconductor region 122 may be 10 Ω·cm or more and 100 Ω·cm or less over an entire region from the second principal surface 103 to the first semiconductor region 121 in the thickness direction of the semiconductor chip 101.

The second semiconductor region 122 is formed in a layer shape extending along the first principal surface 102 (first semiconductor region 121) in the semiconductor chip 101, and is exposed from a part of the first to fourth side surfaces 104A to 104D. The second semiconductor region 122 is electrically connected to the first semiconductor region 121 in the semiconductor chip 101. Specifically, the second semiconductor region 122 forms a pn junction portion with the first semiconductor region 121. The second semiconductor region 122 may have a thickness of 0.5 μm or more and 755 μm or less.

The MISFET 2 includes a first trench structure 123, a trench connection structure 124, and a trench withstand voltage structure 125 as a trench structure formed on the first principal surface 102.

The plurality of first trench structures 123 may be referred to as “trench gate structures.” The plurality of first trench structures 123 are located at intervals in the first direction X, and each formed in a band shape extending in the second direction Y. The plurality of first trench structures 123 are formed in a stripe shape extending in the second direction Y in a plan view. Each of the plurality of first trench structures 123 has a first end portion on one side and a second end portion on the other side in the second direction Y.

The plurality of first trench structures 123 penetrate the first semiconductor region 121 to reach the second semiconductor region 122. In this form, each of the plurality of first trench structures 123 has a bottom wall positioned in the second semiconductor region 122. The plurality of first trench structures 123 are arranged to control inversion and non-inversion of a channel (a channel 184 to be described later) in the second semiconductor region 122.

The plurality of first trench structures 123 may be located at intervals (pitches) of 0.03 μm or more and 10 μm or less (preferably 0.1 μm or more and 0.3 μm or less). The plurality of first trench structures 123 are preferably located at substantially equal intervals in the first direction X. Each of the plurality of first trench structures 123 may have a width of 0.01 μm or more and 10 μm or less (preferably 0.1 μm or more and 0.5 μm or less) in the first direction X. Each of the plurality of first trench structures 123 may have a depth of 0.2 μm or more and 30 μm or less (preferably 0.5 μm or more and 10 μm or less).

Hereinafter, the internal structure of one first trench structure 123 will be described. The first trench structure 123 includes a first trench 126, a gate insulating film 127 (control insulating film), a gate electrode 128 (control electrode), and an embedded insulator 129.

The first trench 126 may be referred to as a “gate trench.” The first trench 126 is formed on the first principal surface 102 and defines the wall surface (side wall and bottom wall) of the first trench structure 123. The first trench 126 exposes the first semiconductor region 121 and the second semiconductor region 122 from the wall surface.

The first trench 126 may be formed in a tapered shape in which the opening width narrows from the first principal surface 102 side toward the bottom wall side in a cross-sectional view. As a matter of course, the first trenches 126 may be formed perpendicular to the first principal surface 102. The bottom wall side corner portion of the first trench 126 may be formed in a curved shape. As a matter of course, the entire bottom wall of the first trench 126 may be formed in a curved shape toward the second principal surface 103 side.

The gate insulating film 127 covers the side wall and the bottom wall of the first trench 126 in a film shape. In this form, the gate insulating film 127 covers the side wall and the bottom wall on the bottom wall side of the first trench 126, and defines the recessed space on the bottom wall side of the first trench 126. The gate insulating film 127 may have a thickness of 5 nm or more and 1000 nm or less in the normal direction of the wall surface of the first trench 126. The gate insulating film 127 includes at least one of a silicon oxide film, a silicon nitride film, an aluminum oxide film, a zirconium oxide film, a hafnium oxide film, or a tantalum oxide film. The gate insulating film 127 is preferably formed of a silicon oxide film. The gate insulating film 127 is particularly preferably formed of oxide (thermal oxide film) of the semiconductor chip 101.

The gate electrode 128 is embedded in the first trench 126 with the gate insulating film 127 interposed therebetween. Specifically, the gate electrode 128 is embedded in a recessed space defined by the gate insulating film 127 on the bottom wall side of the first trench 126, and opposes the second semiconductor region 122 with the gate insulating film 127 interposed therebetween.

The gate electrode 128 crosses the depth position of the boundary portion between the first semiconductor region 121 and the second semiconductor region 122 in the depth direction of the first trench 126.

The gate electrode 128 includes a plurality of lead-out portions 130 led out from the bottom wall side to the opening side of the first trench 126. The number of the plurality of lead-out portions 130 is arbitrary. In this form, the plurality of lead-out portions 130 include a pair of lead-out portions 130 separated from each other in the second direction Y. In this form, the pair of lead-out portions 130 are formed at both end portions of the first trench 126. The plurality of lead-out portions 130 extend in the second direction Y in a plan view.

The plurality of lead-out portions 130 partition the wall surface of the first trench 126 and the opening side recess on the opening side of the first trench 126. The opening side recess is defined in a band shape extending in the second direction Y in a plan view. The plurality of lead-out portions 130 may protrude upward from the first principal surface 102. The plurality of lead-out portions 130 may be led out from the first trench 126 onto the first principal surface 102 with a part of the gate insulating film 127 interposed therebetween. As a matter of course, the plurality of lead-out portions 130 may be positioned on the bottom wall side of the first trench 126 with respect to the first principal surface 102.

The gate electrode 128 may include at least one of a metal and a non-metal conductor. The gate electrode 128 may include at least one of tungsten, aluminum, copper, an aluminum alloy, a copper alloy, and conductive polysilicon. The gate electrode 128 preferably includes a non-metal conductor (conductive polysilicon). The conductive polysilicon may be p-type polysilicon or n-type polysilicon. The conductive polysilicon is preferably n-type polysilicon.

The embedded insulator 129 is embedded on the opening side of the first trench 126 to cover the gate electrode 128 in the first trench 126. Specifically, the embedded insulator 129 is embedded in the opening side recess defined by the gate electrode 128. The embedded insulator 129 is provided as a field insulator that relaxes the electric field with respect to the first trench 126. The embedded insulator 129 is arranged such that the opposing area with respect to the first semiconductor region 121 exceeds the opposing area of the gate electrode 128 with respect to the first semiconductor region 121.

The embedded insulator 129 has a thickness exceeding the thickness of the gate electrode 128 in the depth direction of the first trench 126. The embedded insulator 129 includes at least one of a silicon oxide film, a silicon nitride film, an aluminum oxide film, a zirconium oxide film, a hafnium oxide film, or a tantalum oxide film. The embedded insulator 129 is preferably formed of a silicon oxide film. The embedded insulator 129 is preferably formed of the same material as the gate insulating film 127. In this case, the embedded insulator 129 is preferably formed of an insulating vapor deposition film and has denseness different from that of the gate insulating film 127.

The semiconductor device 1B includes a plurality of mesa portions 131 to 133 partitioned into a first principal surface 102 (first semiconductor region 121) by a plurality of first trench structures 123. The plurality of mesa portions 131 to 133 are each partitioned into a band shape extending in the second direction Y in a region between the plurality of pairs of first trench structures 123 adjacent to each other. The plurality of mesa portions 131 to 133 include a plurality of first mesa portions 131, a plurality of second mesa portions 132, and a plurality of drift mesa portions 133.

The first mesa portion 131 and the second mesa portion 132 are located at intervals in the first direction X to sandwich one drift mesa portion 133. The first mesa portion 131 forms the first source/drain region 107 and may be referred to as a “first source/drain mesa portion.” The second mesa portion 132 forms the second source/drain region 108, and may be referred to as a “second source/drain mesa portion.” The drift mesa portion 133 forms a drift region 109.

The trench connection structure 124 is connected to the first trench structure 123. The plurality of trench connection structures 124 include a trench connection structure 124 on one side connecting first end portions of the plurality of first trench structures 123 and a trench connection structure 124 on the other side connecting second end portions of the plurality of first trench structures 123.

In this form, the trench connection structure 124 connects the end portions of the pair of first trench structures 123 adjacent to each other in the first direction X. Specifically, one trench connection structure 124 is connected to each of the first end portion and the second end portion of the pair of first trench structures 123. As a result, a plurality of closed regions surrounded by the pair of first trench structures 123 and the pair of trench connection structures 124 are formed on the first principal surface 10.

The pair of first trench structures 123 and the pair of trench connection structures 124 partition the first source/drain region 107 and the second source/drain region 108. That is, the semiconductor device 1B includes, on the first principal surface 102 side, the first source/drain region 107 and the second source/drain region 108 that are surrounded by the trench structure having a rectangular shape in a plan view formed by the pair of first trench structures 123 and the pair of trench connection structures 124 and are separated from each other and independent of each other.

The plurality of trench connection structures 124 penetrate the first semiconductor region 121 to reach the second semiconductor region 122. That is, the trench connection structure 124 defines the plurality of mesa portions 131 to 133 (a plurality of first mesa portions 131, a plurality of second mesa portions 132, and a plurality of drift mesa portions 133) together with the plurality of first trench structures 123.

The trench connection structure 124 may have a width of 0.01 μm or more and 10 μm or less (preferably 0.1 μm or more and 2 μm or less) in the second direction Y. The trench connection structure 124 may have a width substantially equal to the width of the first trench structure 123. Each of the trench connection structures 124 may have a depth of 0.2 μm or more and 30 μm or less (preferably 0.5 μm or more and 10 μm or less). The trench connection structure 124 may have a depth substantially equal to the depth of the first trench structure 123.

The trench connection structure 124 includes a connection trench 134, a connection insulating film 135, and a connection electrode 136. The connection trench 134 is formed on the first principal surface 102 to communicate with the plurality of first trenches 126, and defines the wall surface (side wall and bottom wall) of the trench connection structure 124. The wall surfaces (side walls and bottom walls) of the trench connection structure 124 are integrally continuous with the wall surfaces (side walls and bottom walls) of the plurality of first trenches 126. The connection trench 134 exposes the first semiconductor region 121 and the second semiconductor region 122 from the wall surface.

The connection trench 134 may be formed in a tapered shape in which the opening width narrows from the first principal surface 102 side toward the bottom wall side in a cross-sectional view. As a matter of course, the connection trench 134 may be formed perpendicular to the first principal surface 102. The bottom wall side corner portion of the connection trench 134 may be formed in a curved shape. As a matter of course, the entire bottom wall of the connection trench 134 may be formed in a curved shape toward the second principal surface 103 side.

The connection insulating film 135 covers the side wall and the bottom wall of the connection trench 134 in a film shape. In this form, the connection insulating film 135 covers the side wall and the bottom wall on the opening side and the bottom wall side of the connection trench 134, and defines the recessed space in the connection trench 134. The connection insulating film 135 is integrally continuous with the plurality of gate insulating films 127 at a communication portion with the plurality of first trenches 126.

The connection insulating film 135 may have a thickness of 5 nm or more and 1000 nm or less. The connection insulating film 135 preferably has a thickness substantially equal to the thickness of the gate insulating film 127. The connection insulating film 135 includes at least one of a silicon oxide film, a silicon nitride film, an aluminum oxide film, a zirconium oxide film, a hafnium oxide film, or a tantalum oxide film. The connection insulating film 135 is preferably formed of the same material as the gate insulating layer.

The connection electrode 136 is embedded in the connection trench 134 with the connection insulating film 135 interposed therebetween, and opposes the first semiconductor region 121 and the second semiconductor region 122. The connection electrode 136 is continuous with the plurality of gate electrodes 128 at a communication portion with the plurality of first trenches 126. Specifically, the connection electrode 136 is continuous with the plurality of lead-out portions 130. Thus, the connection electrode 136 is fixed at the same potential as the gate electrode 128.

A portion of the connection electrode 136 continuous with the lead-out portion 130 may be included in a constituent element of the connection electrode 136 or may be included in a constituent element of the gate electrode 128. The connection electrode 136 has an upper end portion positioned on the first principal surface 102 side with respect to the upper end portion of the gate electrode 128. The connection electrode 136 may protrude upward from the first principal surface 102. The connection electrode 136 may be extended from the connection trench 134 onto the first principal surface 102 with a part of the connection insulating film 135 interposed therebetween. As a matter of course, the connection electrode 136 may be positioned on the bottom wall side of the connection trench 134 with respect to the first principal surface 102.

The connection electrode 136 may include at least one of a metal and a non-metal conductor. The connection electrode 136 may include at least one of tungsten, aluminum, copper, an aluminum alloy, a copper alloy, and conductive polysilicon. The connection electrode 136 is preferably formed of the same material as the gate electrode 128.

Referring to FIG. 20, each of the plurality of trench withstand voltage structures 125 is formed across the pair of first trench structures 123 in the first direction X. Specifically, from one to the other of the pair of first trench structures 123, each first source/drain region 107 and each second source/drain region 108 are traversed, and the first source/drain region 107 and the second source/drain region 108 are divided at each end portion.

As a result, an isolation region 137 in which the first source/drain region 107 and the second source/drain region 108 are partially isolated is formed between the trench connection structure 124 and the trench withstand voltage structure 125. The isolation region 137 is a region surrounded by the pair of first trench structure 123, the trench connection structure 124, and the trench withstand voltage structure 125. Due to the formation of the isolation region 137, the first source/drain region 107 and the second source/drain region 108 are separated from the trench connection structure 124 by the isolation region 137 in the second direction Y.

The trench withstand voltage structure 125 covers the end portions in the second direction Y of the first source/drain region 107 and the second source/drain region 108 away from the trench connection structure 124.

The plurality of trench withstand voltage structures 125 penetrate the first semiconductor region 121 to reach the second semiconductor region 122. In this form, each of the plurality of trench withstand voltage structures 125 has a bottom wall positioned in the second semiconductor region 122.

The trench withstand voltage structure 125 may have a width of 0.01 μm or more and 10 μm or less (preferably 0.1 μm or more and 2 μm or less) in the second direction Y. The trench withstand voltage structure 125 may have a width substantially equal to the width of the first trench structure 123. The trench withstand voltage structure 125 may have a depth of 0.2 μm or more and 30 μm or less (preferably 0.5 μm or more and 10 μm or less). The trench withstand voltage structure 125 may have a depth substantially equal to the depth of the first trench structure 123.

The trench withstand voltage structure 125 includes a withstand voltage trench 138, a withstand voltage insulating film 139, a withstand voltage electrode 140, and a withstand voltage insulator 141.

The withstand voltage trench 138 is formed on the first principal surface 102 and defines the wall surface (side wall and bottom wall) of the trench withstand voltage structure 125. The wall surfaces (side walls and bottom walls) of the trench withstand voltage structure 125 are integrally continuous with the wall surfaces (side walls and bottom walls) of the plurality of first trenches 126. The withstand voltage trench 138 exposes the first semiconductor region 121 and the second semiconductor region 122 from the wall surface.

The withstand voltage trench 138 may be formed in a tapered shape in which the opening width narrows from the first principal surface 102 side toward the bottom wall side in a cross-sectional view. As a matter of course, the withstand voltage trench 138 may be formed perpendicular to the first principal surface 102. The bottom wall side corner portion of the withstand voltage trench 138 may be formed in a curved shape. As a matter of course, the entire bottom wall of the withstand voltage trench 138 may be formed in a curved shape toward the second principal surface 103 side.

The withstand voltage insulating film 139 covers the side wall and the bottom wall of the withstand voltage trench 138 in a film shape. In this form, the withstand voltage insulating film 139 covers the side wall and the bottom wall on the bottom wall side of the withstand voltage trench 138, and defines the recessed space on the bottom wall side of the withstand voltage trench 138. The withstand voltage insulating film 139 is integrally continuous with the plurality of gate insulating films 127. The withstand voltage insulating film 139 may have a thickness of 5 nm or more and 1000 nm or less in the normal direction of the wall surface of the withstand voltage trench 138. The withstand voltage insulating film 139 preferably has a thickness substantially equal to the thickness of the gate insulating film 127.

The withstand voltage insulating film 139 includes at least one of a silicon oxide film, a silicon nitride film, an aluminum oxide film, a zirconium oxide film, a hafnium oxide film, or a tantalum oxide film. The withstand voltage insulating film 139 is preferably formed of the same material as the gate insulating layer.

The withstand voltage electrode 140 is embedded in the withstand voltage trench 138 with the withstand voltage insulating film 139 interposed therebetween. Specifically, the withstand voltage electrode 140 is embedded in a recessed space defined by the withstand voltage insulating film 139 on the bottom wall side of the withstand voltage trench 138, and opposes the second semiconductor region 122 with the withstand voltage insulating film 139 interposed therebetween. The withstand voltage electrode 140 is integrally continuous with the gate electrode 128. The withstand voltage electrode 140 crosses a depth position of a boundary portion between the first semiconductor region 121 and the second semiconductor region 122 in the depth direction of the withstand voltage trench 138.

The withstand voltage electrode 140 may include at least one of a metal and a non-metal conductor. The withstand voltage electrode 140 may include at least one of tungsten, aluminum, copper, an aluminum alloy, a copper alloy, and conductive polysilicon. The withstand voltage electrode 140 preferably includes a non-metal conductor (conductive polysilicon). The conductive polysilicon may be p-type polysilicon or n-type polysilicon. The conductive polysilicon is preferably n-type polysilicon.

The withstand voltage insulator 141 is embedded in the opening side of the withstand voltage trench 138 to cover the withstand voltage electrode 140 in the withstand voltage trench 138. Specifically, the withstand voltage insulator 141 is embedded in an opening side recess defined by the withstand voltage electrode 140. The withstand voltage insulator 141 is provided as a field insulator that relaxes an electric field with respect to the withstand voltage trench 138. The withstand voltage insulator 141 is arranged such that the opposing area with respect to the first semiconductor region 121 exceeds the opposing area of the withstand voltage electrode 140 with respect to the second semiconductor region 122.

The withstand voltage insulator 141 has a thickness exceeding the thickness of the withstand voltage electrode 140 in the depth direction of the withstand voltage trench 138. The withstand voltage insulator 141 includes at least one of a silicon oxide film, a silicon nitride film, an aluminum oxide film, a zirconium oxide film, a hafnium oxide film, or a tantalum oxide film. The withstand voltage insulator 141 is preferably formed of a silicon oxide film. The withstand voltage insulator 141 is preferably formed of the same material as the withstand voltage insulating film 139. In this case, it is preferable that the withstand voltage insulator 141 is formed of an insulating vapor deposition film and has denseness different from that of the withstand voltage insulating film 139.

In the plurality of first mesa portions 131, the first source/drain region 107 is formed by the first semiconductor region 121. A first contact region 142 is formed in a surface layer portion of the first source/drain region 107. The first contact region 142 has an n-type impurity concentration higher than that of the first semiconductor region 121. The n-type impurity concentration of the first contact region 142 may be 1×10¹⁸ cm⁻³ or more and 1×10²¹ cm⁻³ or less (in this form, about 1×10¹⁹ cm⁻³).

The first contact region 142 is preferably formed in a central portion of the corresponding first mesa portion 131 in a plan view. The first contact region 142 has a length less than the length of the first trench structure 123 in the second direction Y, and is formed with a space from both end portions of the first trench structure 123 inward. Both end portions of the first contact region 142 oppose the trench withstand voltage structure 125 with a part of the first semiconductor region 121 interposed therebetween.

The first contact region 142 extends in the lateral direction (second direction Y) along the first principal surface 102 in a cross-sectional view. Specifically, the first contact region 142 is formed at a depth position on the first principal surface 102 side with respect to the upper end portion of the gate electrode 128. The first contact region 142 opposes the embedded insulator 129 with a part of the first semiconductor region 121 interposed therebetween in the lateral direction along the first principal surface 102. The first contact region 142 is separated from the upper end portion of the gate electrode 128 toward the first principal surface 102 side, and does not oppose the gate electrode 128 in the lateral direction along the first principal surface 102. As a result, the electric field applied to the plurality of first trench structures 123 is relaxed.

The first contact region 142 may have a thickness of 10 nm or more and 150 nm or less (preferably 50 nm or more and 100 nm or less). The first contact region 142 is preferably formed at an interval of 0.1 μm or more and 2 μm or less (preferably 0.5 μm or more and 1.5 μm or less) from the upper end portion of the gate electrode 128 in the thickness direction (normal direction Z) of the semiconductor chip 101.

In the plurality of second mesa portions 132, the second source/drain region 108 is formed by the first semiconductor region 121. A second contact region 143 is formed in the surface layer portion of the second source/drain region 108. The second contact region 143 has an n-type impurity concentration higher than that of the first semiconductor region 121. The n-type impurity concentration of the second contact region 143 may be 1×10¹⁸ cm⁻³ or more and 1×10²¹ cm⁻³ or less (in this form, about 1×10¹⁹ cm⁻³).

The second contact region 143 is preferably formed in a central portion of the corresponding second mesa portion 132 in a plan view. The second contact region 143 has a length less than the length of the first trench structure 123 in the second direction Y, and is formed with a space from both end portions of the first trench structure 123 inward. Both end portions of the second contact region 143 oppose the trench withstand voltage structure 125 with a part of the first semiconductor region 121 interposed therebetween in the second direction Y.

The second contact region 143 extends in the lateral direction (second direction Y) along the first principal surface 102 in a cross-sectional view. Specifically, the second contact region 143 is formed at a depth position on the first principal surface 102 side with respect to the upper end portion of the gate electrode 128. The second contact region 143 opposes the embedded insulator 129 with a part of the first semiconductor region 121 interposed therebetween in the lateral direction along the first principal surface 102. The second contact region 143 is separated from the upper end portion of the gate electrode 128 toward the first principal surface 102 side, and does not oppose the gate electrode 128 in the lateral direction along the first principal surface 102. As a result, the electric field applied to the plurality of first trench structures 123 is relaxed.

The second contact region 143 may have a thickness of 10 nm or more and 150 nm or less (preferably 50 nm or more and 100 nm or less). The second contact region 143 is preferably formed at an interval of 0.1 μm or more and 2 μm or less (preferably 0.5 μm or more and 1.5 μm or less) from the upper end portion of the gate electrode 128 in the thickness direction (normal direction Z) of the semiconductor chip 101.

In the plurality of drift mesa portions 133, the drift region 109 is formed by the first semiconductor region 121. In this form, the drift region 109 is formed by the first semiconductor region 121 over an entire region from the boundary portion 144 between the first semiconductor region 121 and the second semiconductor region 122 to the first principal surface 102. The width of the drift region 109 in the first direction X is narrower than the width of the drift region 21 of the first preferred embodiment. For example, the width of the drift region 21 is 0.2 μm or more and 10 μm or less, whereas the width of the drift region 109 is 0.01 μm or more and 0.3 μm or less.

The wiring region 111 is formed by the first semiconductor region 121 between the adjacent cell regions 110. The wiring region 111 is integrally continuous with the end portion of the drift region 109 in the second direction Y.

In the wiring region 111, a p-type protrusion portion 145 that selectively protrudes from the second semiconductor region 122 toward the first principal surface 102 to the inside of the first semiconductor region 121 is formed. Referring to FIG. 24, the protrusion portion 145 may extend upward in a parabolic shape from the boundary portion 144 between the first semiconductor region 121 and the second semiconductor region 122 and have an apex portion in the vicinity of the first principal surface 102. In this form, the protrusion portion 145 has an apex portion at a position away from the first principal surface 102 toward the second principal surface 103 side. A part of the wiring region 111 (drift region 109) may be formed between the apex portion of the protrusion portion 145 and the first principal surface 102. Referring to FIG. 20, the protrusion portion 145 is formed in a band shape extending in the first direction X. Since the protrusion portion 145 is formed in the wiring region 111 (in this form, a region where the current path 185 (described later) is not formed), the protrusion portion 145 can be formed in a band shape. As a result, a contact for substrate potential can be formed at an arbitrary position in the wiring region 111. As a matter of course, the plurality of protrusion portions 145 may be located at intervals in the first direction X.

The protrusion portion 145 has a p-type impurity concentration higher than that of the second semiconductor region 122. The p-type impurity concentration of the protrusion portion 145 may be 1×10¹⁶ cm⁻³ or more and 1×1022 cm⁻³ or less (in this form, about 1×10¹⁹ cm⁻³).

In the plurality of isolation regions 137 and wiring regions 111, a first impurity region 146 is further formed. In FIG. 20, the first impurity region 146 is omitted. The first impurity region 146 is formed in contact with the apex portion of the protrusion portion 145 in the surface layer portion of the first principal surface 102. The first impurity region 146 has an n-type impurity concentration higher than that of the first semiconductor region 121. The n-type impurity concentration of the first impurity region 146 may be 1×10¹⁵ cm⁻³ or more and 1×10²⁰ cm⁻³ or less (in this form, about 1×10¹⁸ cm⁻³).

The semiconductor device 1B includes a principal surface insulating film 147 that selectively covers the first principal surface 102. The principal surface insulating film 147 may be a part of the insulating layer 9 described above. The principal surface insulating film 147 covers the plurality of first trench structures 123, the plurality of trench connection structures 124, and the plurality of trench withstand voltage structures 125 on the first principal surface 102. In this form, the principal surface insulating film 147 covers the entire first principal surface 102 and is continuous with the first to fourth side surfaces 104A to 104D.

The principal surface insulating film 147 may have a thickness of 0.1 μm or more and 2 μm or less. The thickness of the principal surface insulating film 147 preferably exceeds the thickness of the gate insulating film 127. The principal surface insulating film 147 includes at least one of a silicon oxide film, a silicon nitride film, an aluminum oxide film, a zirconium oxide film, a hafnium oxide film, or a tantalum oxide film. The principal surface insulating film 147 is preferably formed of a silicon oxide film.

In this form, the principal surface insulating film 147 is formed of the same material as the embedded insulator 129 and the withstand voltage insulator 141, and is formed integrally with the embedded insulator 129 and the withstand voltage insulator 141. That is, the principal surface insulating film 147 enters the plurality of first trenches 126 and the withstand voltage trench 138 from above the first principal surface 102 as a part of the embedded insulator 129 and the withstand voltage insulator 141. In other words, the principal surface insulating film 147 is formed of an insulating film in which a part of the plurality of embedded insulators 129 protruding from the plurality of first trenches 126 and a part of the plurality of withstand voltage insulators 141 protruding from the plurality of withstand voltage trenches 138 are integrated in a film shape on the first principal surface 102.

The semiconductor device 1B includes a plurality of first electrodes 148 electrically connected to the first semiconductor region 121 in the plurality of first mesa portions 131. In this form, the plurality of first electrodes 148 are provided as “first lower contacts.” The plurality of first electrodes 148 penetrate the principal surface insulating film 147 and are connected to the plurality of first mesa portions 131, respectively. Specifically, the plurality of first electrodes 148 are located in a plurality of first connection openings 149 formed in the principal surface insulating film 147.

Each of the plurality of first electrodes 148 is formed of metal. In this form, each of the plurality of first electrodes 148 has a laminated structure including the first barrier film 150 and the first electrode body 151. The first barrier film 150 is formed in a film shape along the inner wall of the first connection opening 149. The first barrier film 150 may be formed of a titanium-based metal film. The first barrier film 150 may have a single-layer structure or a laminated structure including one or both of a titanium film and a titanium nitride film.

The first electrode body 151 is embedded in the first connection opening 149 with the first barrier film 150 interposed therebetween, and is electrically connected to the first mesa portion 131 (first contact region 142) with the first barrier film 150 interposed therebetween. The first electrode body 151 may include at least one of tungsten, aluminum, copper, an aluminum alloy, and a copper alloy. In this form, the first electrode body 151 includes tungsten. As a matter of course, the plurality of first electrodes 148 may not have the first barrier film 150 and may be constituted only by the first electrode body 151.

The semiconductor device 1B includes a plurality of second electrodes 152 electrically connected to the first semiconductor region 121 in the plurality of second mesa portions 132. The plurality of second electrodes 152 are provided as “second lower contacts” in this form. The plurality of second electrodes 152 penetrate the principal surface insulating film 147 and are connected to the plurality of second mesa portions 132. Specifically, the plurality of second electrodes 152 are located in a plurality of second connection openings 153 formed in the principal surface insulating film 147.

Each of the plurality of second electrodes 152 is formed of metal. In this form, each of the plurality of second electrodes 152 has a laminated structure including the second barrier film 154 and the second electrode body 155. The second barrier film 154 is formed in a film shape along the inner wall of the second connection opening 153. The second barrier film 154 may be formed of a titanium-based metal film. The second barrier film 154 may have a single-layer structure or a laminated structure including one or both of a titanium film and a titanium nitride film.

The second electrode body 155 is embedded in the second connection opening 153 with the second barrier film 154 interposed therebetween, and is electrically connected to the second mesa portion 132 (second contact region 143) with the second barrier film 154 interposed therebetween. The second electrode body 155 may include at least one of tungsten, aluminum, copper, an aluminum alloy, and a copper alloy. The second electrode body 155 includes tungsten in this form. As a matter of course, the plurality of second electrodes 152 may not have the second barrier film 154 and may be constituted only by the second electrode body 155.

The semiconductor device 1B includes a plurality of second trench structures 156 formed on the first principal surface 102 in the wiring region 111.

In this form, the plurality of second trench structures 156 are located at intervals in the first direction X. For example, when the plurality of protrusion portions 145 are formed at intervals in the first direction X, the plurality of second trench structures 156 may be formed in each protrusion portion 145 on a one-to-one basis. Each second trench structure 156 is located at a position opposing each drift region 109 in the vicinity of the end portion of each drift region 109 in the second direction Y. In this form, the second trench structure 156 is located adjacent to each of both end portions of the drift region 109 in the second direction Y.

The second trench structure 156 is formed to reach the protrusion portion 145. In this form, the second trench structure 156 is formed shallower than the first trench structure 123. Specifically, the second trench structure 156 penetrates the first impurity region 146 and reaches the protrusion portion 145. Each of the second trench structures 156 has a bottom wall positioned in the protrusion portion 145.

The width of the second trench structure 156 may be equal to or larger than the width of the first trench structure 123 or may be smaller than the width of the first trench structure 123. The second trench structure 156 may have a depth of 0.1 μm or more and 10 μm or less (preferably 0.2 μm or more and 0.5 μm or less). With this depth, a silicide layer 162 (described later) can be formed over the entire second trench structure 156.

The second trench structure 156 includes a base trench 157 and a base electrode 158. In this form, the base electrode 158 is provided as a “first base contact 120.”

The base trench 157 is formed on the first principal surface 102 through the principal surface insulating film 147, and defines the wall surface (side wall and bottom wall) of the second trench structure 156. In this form, the base trench 157 includes the base connection opening 159 formed in the principal surface insulating film 147. Specifically, the base trench 157 penetrates the principal surface insulating film 147 and the first impurity region 146 to reach the protrusion portion 145. The base trench 157 exposes the first impurity region 146 and the protrusion portion 145 from the wall surface.

The base trench 157 may be formed in a tapered shape in which the opening width narrows from the first principal surface 102 side toward the bottom wall side in a cross-sectional view. As a matter of course, the base trench 157 may be formed perpendicular to the first principal surface 102. The bottom wall side corner portion of the base trench 157 may be formed in a curved shape. As a matter of course, the entire bottom wall of the base trench 157 may be formed in a curved shape toward the second principal surface 103 side.

The base electrode 158 is embedded in the base trench 157 without an insulating film interposed therebetween. The base electrode 158 is mechanically and electrically connected to the first impurity region 146 and the protrusion portion 145 in the base trench 157, and is mechanically connected to the principal surface insulating film 147. In the base trench 157, the base electrode 158 has a part positioned on the semiconductor chip 101 side with respect to the first principal surface 102 and a part positioned on the principal surface insulating film 147 side with respect to the first principal surface 102. That is, the base electrode 158 has an upper end portion protruding upward from the first principal surface 102. The upper end portion of the base electrode 158 protrudes upward from the upper end portion of the gate electrode 128 (the upper end portion of the lead-out portion 130).

The base electrode 158 may include at least one of a metal and a non-metal conductor. The base electrode 158 is preferably formed of a conductive material different from the gate electrode 128. The base electrode 158 preferably includes a metal. In this form, the base electrode 158 has a laminated structure including the base barrier film 160 and the base electrode body 161.

The base barrier film 160 is formed in a film shape along the side wall and the bottom wall of the base trench 157, and covers the first impurity region 146, the protrusion portion 145, and the principal surface insulating film 147 in the base trench 157. The base barrier film 160 defines a recessed space in the base trench 157. The base barrier film 160 may be formed of a titanium-based metal film. The base barrier film 160 may have a single-layer structure or a laminated structure including one or both of a titanium film and a titanium nitride film. The base barrier film 160 is preferably formed of the same material as the first barrier film 150 and the second barrier film 154.

The base electrode body 161 is embedded in the base trench 157 with the base barrier film 160 interposed therebetween, and covers the first impurity region 146, the protrusion portion 145, and the principal surface insulating film 147 with the base barrier film 160 interposed therebetween. The base electrode body 161 is electrically connected to the first impurity region 146 and the protrusion portion 145 through the base barrier film 160. The base electrode body 161 may include at least one of tungsten, aluminum, copper, an aluminum alloy, and a copper alloy. The base electrode body 161 is preferably formed of the same material as the first electrode body 151 and the second electrode body 155. The base electrode body 161 includes tungsten in this form. As a matter of course, the base electrode 158 may not include the base barrier film 160 and may be constituted only by the base electrode body 161.

The silicide layer 162 is formed on an inner wall of the base trench 157. The silicide layer 162 is formed at the boundary portion between the semiconductor chip 101 and the base barrier film 160 over the entire side wall and bottom wall of the base trench 157. The silicide layer 162 may vertically cross the boundary portion between the first impurity region 146 and the protrusion portion 145 in the thickness direction of the semiconductor chip 101.

When the silicide layer 162 is formed over the entire side wall and bottom wall of the base trench 157, the surface state of the inner wall of the base trench 157 can be smoothly improved, and the base electrode body 161 and the base trench 157 can be favorably brought into contact with each other. Thereby, the contact resistance of the base electrode body 161 can be reduced.

The semiconductor device 1B includes a plurality of third electrodes 163 electrically connected to the plurality of first trench structures 123. The plurality of third electrodes 163 are provided as “first gate contacts 117.” The plurality of third electrodes 163 penetrate the principal surface insulating film 147, and are mechanically and electrically connected to one or both of the plurality of first trench structures 123 (lead-out portions 130) and the plurality of trench connection structures 124 (connection electrodes 136).

Specifically, the plurality of third electrodes 163 are located in a plurality of third connection openings 164 formed in the principal surface insulating film 147. In this form, the plurality of third electrodes 163 are mechanically and electrically connected to the plurality of trench connection structures 124. That is, the plurality of third electrodes 163 are electrically connected to the plurality of first trench structures 123 through the plurality of trench connection structures 124.

In this form, the plurality of third electrodes 163 are formed corresponding to each trench connection structure 124 in a plan view. The planar shape of the plurality of third electrodes 163 is arbitrary. The plurality of third electrodes 163 may be formed in a circular shape or a quadrangular shape in a plan view.

Each of the plurality of third electrodes 163 is formed of metal. In this form, each of the plurality of third electrodes 163 has a laminated structure including a third barrier film 165 and a third electrode body 166. The third barrier film 165 is formed in a film shape along the inner wall of the third connection opening 164. The third barrier film 165 may be formed of a titanium-based metal film. The third barrier film 165 may have a single-layer structure or a laminated structure including one or both of a titanium film and a titanium nitride film. The third barrier film 165 is preferably formed of the same material as the first barrier film 150, the second barrier film 154, and the base barrier film 160.

The third electrode body 166 is embedded in the third connection opening 164 with the third barrier film 165 interposed therebetween, and is electrically connected to the lead-out portion 130 (connection electrode 136) with the third barrier film 165 interposed therebetween. The third electrode body 166 may include at least one of tungsten, aluminum, copper, an aluminum alloy, and a copper alloy. The third electrode body 166 is preferably formed of the same material as the first electrode body 151. The third electrode body 166 includes tungsten in this form. As a matter of course, the plurality of third electrodes 163 may not have the third barrier film 165 and may be constituted only by the third electrode body 166.

The semiconductor device 1B includes a p-type bottom wall impurity region 167 formed in a region along the bottom wall of the first trench structure 123 in the second semiconductor region 122. In this form, the bottom wall impurity region 167 is formed in the second semiconductor region 122 and has a p-type impurity concentration higher than that of the second semiconductor region 122. The p-type impurity concentration of the bottom wall impurity region 167 may be 1×10¹⁶ cm⁻³ or more and 1×10¹⁹ cm⁻³ or less (in this form, about 1×10¹⁷ cm⁻³).

The bottom wall impurity region 167 is formed in a band shape extending along the bottom wall of the first trench structure 123 with a space from the plurality of second trench structures 156 in a plan view. The bottom wall impurity region 167 opposes the gate electrode 128 with the gate insulating film 127 interposed therebetween at the bottom wall of the first trench structure 123. The bottom wall impurity region 167 may cover the bottom wall and the side wall of the first trench structure 123 at the lower end portion of the first trench structure 123.

The bottom wall impurity region 167 may cover the bottom wall of the trench connection structure 124 in the second semiconductor region 122. In this case, the bottom wall impurity region 167 may be formed in a band shape extending along the bottom wall of the trench connection structure 124 in a plan view. As a matter of course, the bottom wall impurity region 167 may expose the bottom wall of the trench connection structure 124.

The bottom wall impurity region 167 may cover the bottom wall of the trench withstand voltage structure 125 in the second semiconductor region 122. In this case, the bottom wall impurity region 167 may be formed in a band shape extending along the bottom wall of the trench withstand voltage structure 125 in a plan view. As a matter of course, the bottom wall impurity region 167 may expose the bottom wall of the trench withstand voltage structure 125.

The bottom wall impurity region 167 may have a thickness of 10 nm or more and 500 nm or less. A thickness of the bottom wall impurity region 167 is preferably 100 nm or more and 300 nm or less. The thickness of the bottom wall impurity region 167 is a distance between the bottom wall of the first trench structure 123 and the bottom portion of the bottom wall impurity region 167. The bottom wall impurity region 167 has a width exceeding the width of the bottom wall of the first trench structure 123 in the first direction X. The width of the bottom wall impurity region 167 is defined by the width of the most bulging region in the bottom wall impurity region 167. The width of the bottom wall impurity region 167 may exceed the opening width of the first trench structure 123. The width of the bottom wall impurity region 167 may be 0.1 μm or more and 0.5 μm or less.

The semiconductor device 1B includes a first interlayer insulating film 168 stacked on the principal surface insulating film 147. The first interlayer insulating film 168 may be a part of the insulating layer 9 described above. The first interlayer insulating film 168 may include at least one of silicon oxide and silicon nitride. The first interlayer insulating film 168 covers the entire region of the principal surface insulating film 147 and is continuous with the first to fourth side surfaces 104A to 104D. The first interlayer insulating film 168 may have a flat surface extending along the first principal surface 102. The flat surface of the first interlayer insulating film 168 may have a grinding mark.

The first wiring layer 112 is formed on the first interlayer insulating film 168. The first wiring layer 112 may include at least one of titanium, tungsten, aluminum, copper, an aluminum alloy, a copper alloy, and conductive polysilicon. The first wiring layer 112 may include at least one of a Cu film (Cu film having a purity of 99% or more), a pure Al film (Al film having a purity of 99% or more), an AlCu alloy film, an AlSi alloy film, and an AlSiCu alloy film.

As described above, the first wiring layer 112 includes the first gate wiring layer 113 and the first base wiring layer 114. Referring to FIG. 21, one of the pair of first gate wiring layers 113 (gate branch portions 116) extending in the wiring region 111 in the first direction X is connected to the connection electrode 136 of the cell region 110 on one side with respect to the wiring region 111. The other of the pair of first gate wiring layers 113 (gate branch portions 116) is connected to the third electrode 163 (connection electrode 136) of the cell region 110 on the other side with respect to the wiring region 111. In this form, the first gate wiring layer 113 is located to cover the trench connection structure 124 and not to cover the trench withstand voltage structure 125 in a plan view.

The first base wiring layer 114 extends in the wiring region 111 in the first direction X and is connected to the plurality of base electrodes 158 (first base contacts 120). In this form, as illustrated in FIG. 19, the plurality of first base contacts 120 are located below the base outer peripheral portion 118 and the base branch portion 119, and are connected to the base outer peripheral portion 118 and the base branch portion 119.

The first wiring layer 112 further includes a first lower wiring layer 169 and a second lower wiring layer 170. Referring to FIG. 22, the first lower wiring layer 169 penetrates the first interlayer insulating film 168 and is connected to the first electrode 148, and the second lower wiring layer 170 penetrates the first interlayer insulating film 168 and is connected to the second electrode 152.

The semiconductor device 1B includes a second interlayer insulating film 171 laminated on the first interlayer insulating film 168 to cover the first wiring layer 112. The second interlayer insulating film 171 may be a part of the insulating layer 9 described above. The second interlayer insulating film 171 may include at least one of silicon oxide and silicon nitride. The second interlayer insulating film 171 covers the entire region of the first interlayer insulating film 168 and is continuous with the first to fourth side surfaces 104A to 104D. The second interlayer insulating film 171 may have a flat surface extending along the first principal surface 102. The flat surface of the second interlayer insulating film 171 may have a grinding mark.

The second wiring layer 172 is formed on the second interlayer insulating film 171. The second wiring layer 172 may include at least one of titanium, tungsten, aluminum, copper, an aluminum alloy, a copper alloy, and conductive polysilicon. The second wiring layer 172 may include at least one of a Cu film (Cu film having a purity of 99% or more), a pure Al film (Al film having a purity of 99% or more), an AlCu alloy film, an AlSi alloy film, and an AlSiCu alloy film.

The second wiring layer 172 includes a first upper wiring layer 173, a second upper wiring layer 174, a second gate wiring layer (not illustrated), and a second base wiring layer (not illustrated). The first upper wiring layer 173 penetrates the second interlayer insulating film 171 and is connected to the first lower wiring layer 169. The second upper wiring layer 174 penetrates the second interlayer insulating film 171 and is connected to the second lower wiring layer 170. The second gate wiring layer penetrates the second interlayer insulating film 171 and is connected to the first gate wiring layer 113. The second base wiring layer penetrates the second interlayer insulating film 171 and is connected to the first base wiring layer 114.

The semiconductor device 1B includes an uppermost insulating film 175 formed on the second interlayer insulating film 171. The uppermost insulating film 175 may be a part of the insulating layer 9 described above. The uppermost insulating film 175 may be referred to as a “passivation film.” The uppermost insulating film 175 may have a laminated structure including an inorganic insulating film (inorganic film) and an organic insulating film (organic film) laminated in this order from the second interlayer insulating film 171 side. As a matter of course, the uppermost insulating film 175 may have a single-layer structure formed of an inorganic insulating film (inorganic film) or an organic insulating film (organic film). The inorganic insulating film is preferably formed of an insulating material different from that of the second interlayer insulating film 171. The inorganic insulating film may be formed of, for example, a silicon nitride film. The organic insulating film may be formed of a photosensitive resin. The organic insulating film may include at least one of a polyimide film, a polyamide film, and a polybenzoxazole film.

The plurality of external terminals 4 to 7 are formed on the uppermost insulating film 175 as in the first preferred embodiment.

The semiconductor device 1B includes a rear surface protection film 176 covering the second principal surface 103 of the semiconductor chip 101. In this form, the rear surface protection film 176 covers the entire region of the second principal surface 103, and further covers the first to fourth side surfaces 104A to 104D. The rear surface protection film 176 may have a single-layer structure formed of an inorganic insulating film (inorganic film) or an organic insulating film (organic film). The inorganic insulating film may be formed of, for example, a silicon nitride film. The organic insulating film may be formed of a photosensitive resin. The organic insulating film may include at least one of a polyimide film, a polyamide film, and a polybenzoxazole film.

Referring to FIG. 22, the semiconductor device 1B includes a first pn junction portion 177 and a second pn junction portion 178 formed inside the semiconductor chip 101. The first pn junction portion 177 is formed at a boundary portion between the first semiconductor region 121 and the second semiconductor region 122 on the first mesa portion 131 side. As a result, the first body diode D1 including the second semiconductor region 122 as the anode region and the first semiconductor region 121 as the cathode region is formed in the first mesa portion 131.

The second pn junction portion 178 is formed at a boundary portion between the first semiconductor region 121 and the second semiconductor region 122 on the second mesa portion 132 side. As a result, the second body diode D2 including the second semiconductor region 122 as the anode region and the first semiconductor region 121 as the cathode region is formed in the second mesa portion 132. The anode of the second body diode D2 (second pn junction portion 178) is electrically connected to the anode of the first body diode D1 (first pn junction portion 177) through the second semiconductor region 122.

### (2) Manufacturing Process of Semiconductor Device 1B

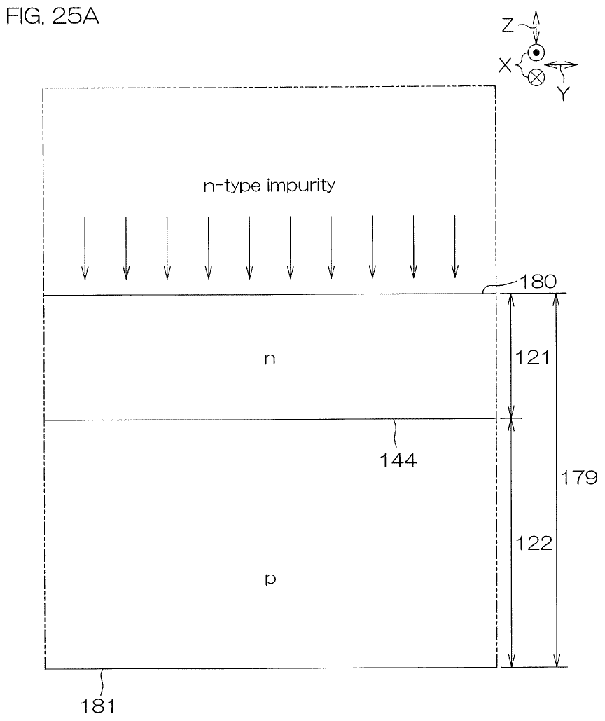

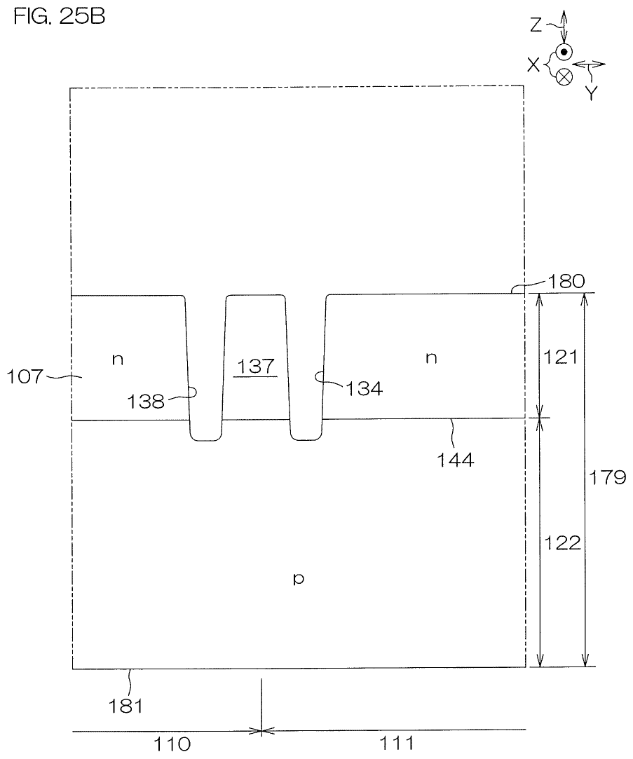

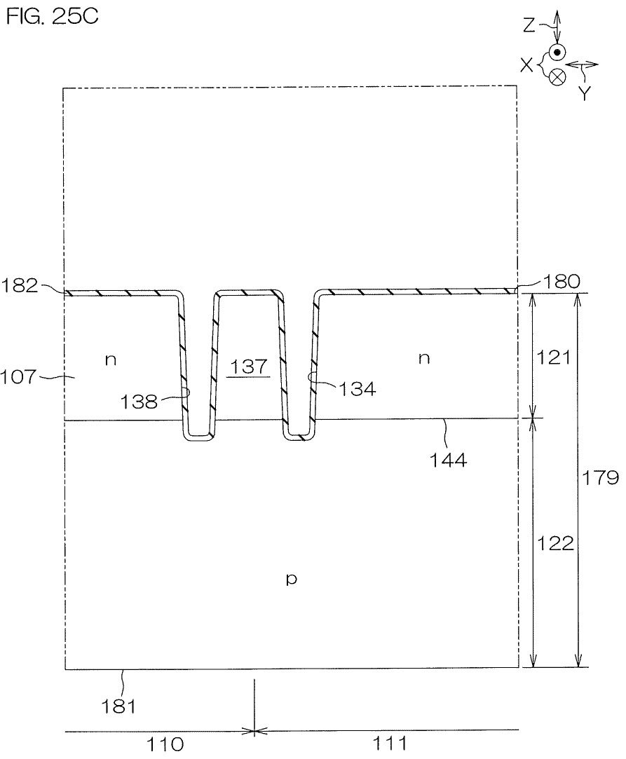

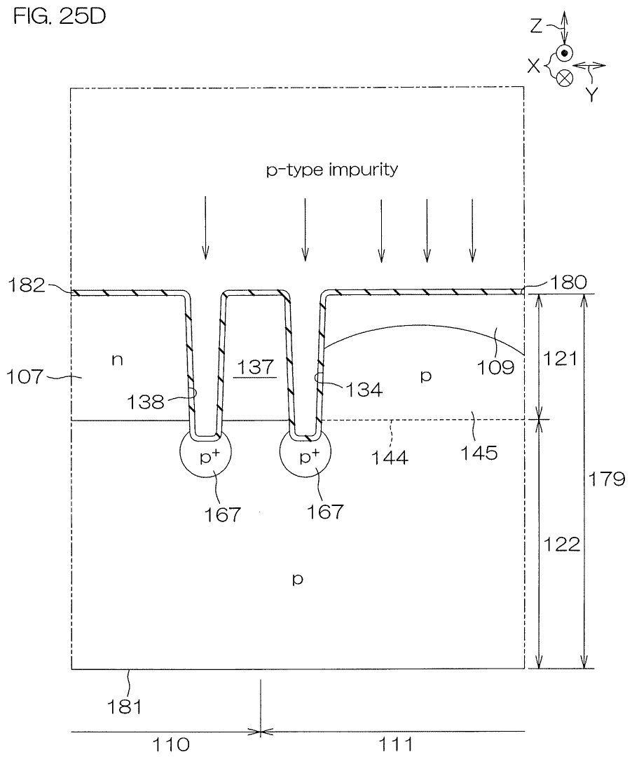

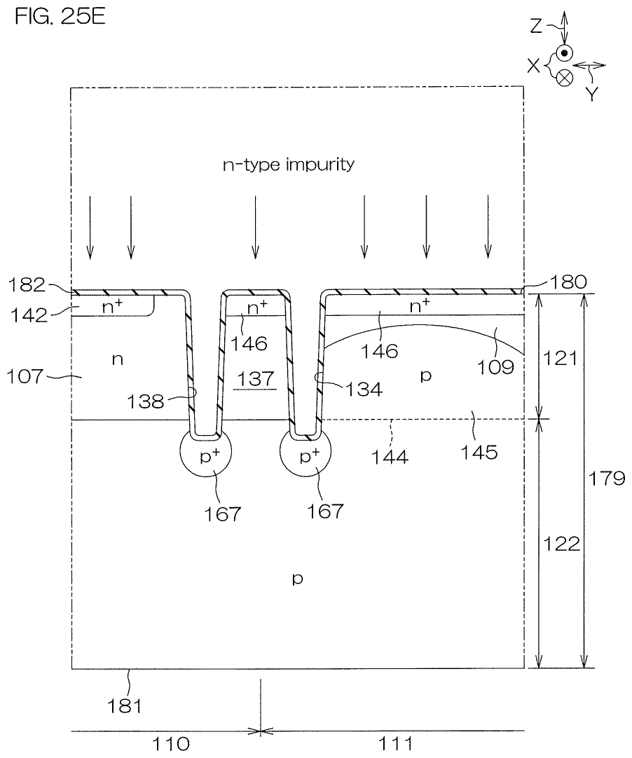

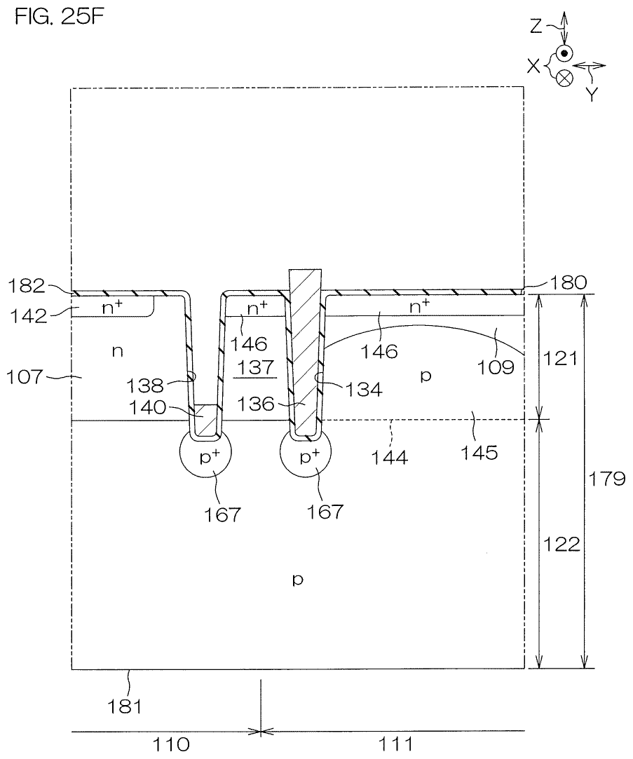

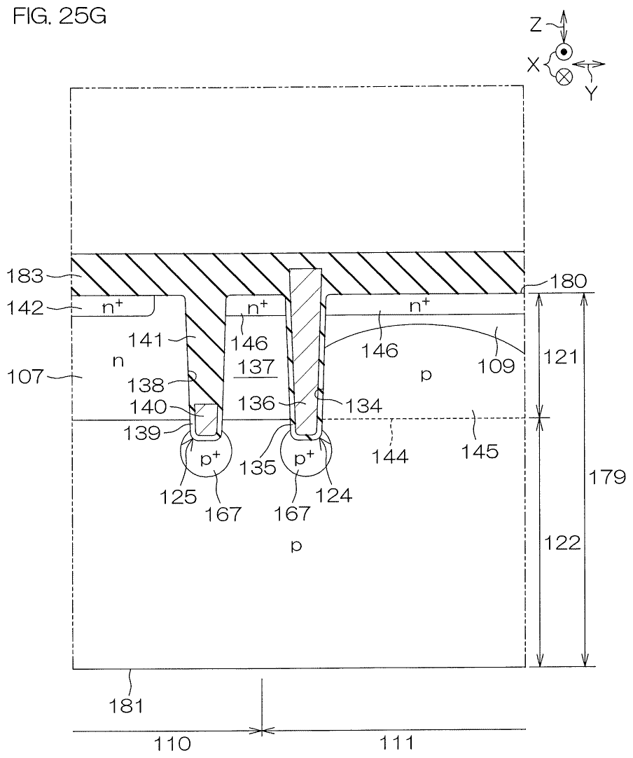

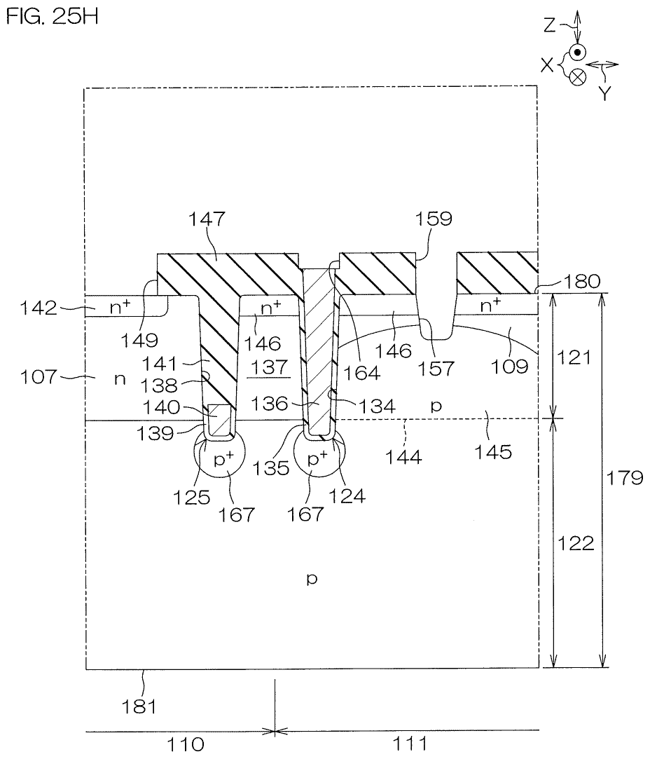

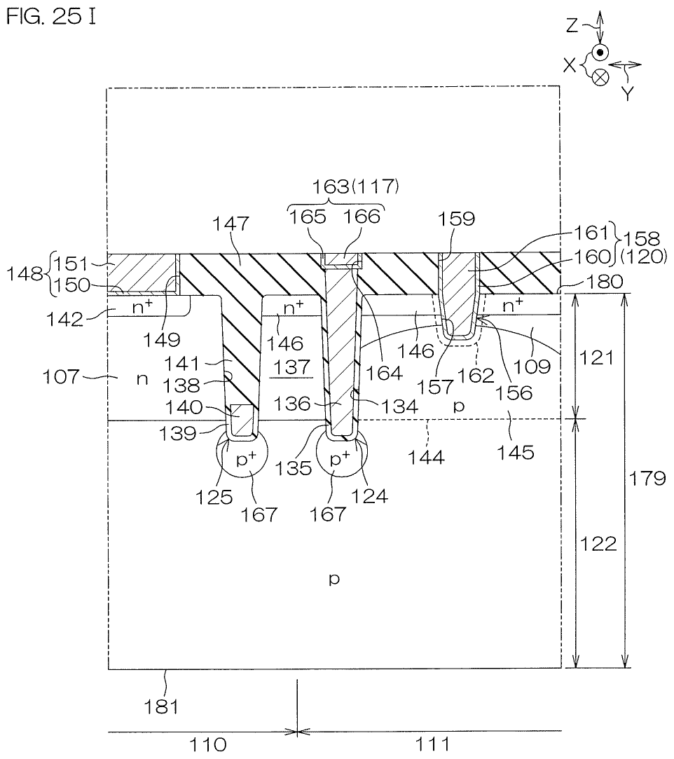

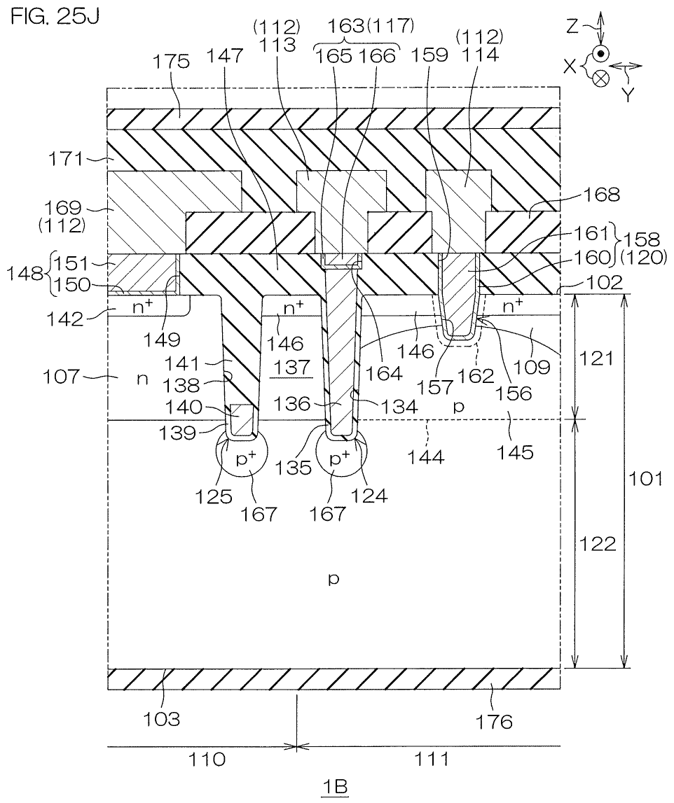

Next, an example of a method of manufacturing the semiconductor device 1B will be described. FIGS. 25A to 25J are cross-sectional views illustrating an example of a method of manufacturing the semiconductor device 1B illustrated in FIG. 1. FIGS. 25A to 25J are cross-sectional views of a region corresponding to FIG. 24.

Referring to FIG. 25A, a disk-shaped wafer 179 is prepared. The wafer 179 includes a first wafer principal surface 180 on one side and a second wafer principal surface 181 on the other side. The wafer 179 is formed of a p-type semiconductor substrate entirely formed of the second semiconductor region 122. Next, the first semiconductor region 121 is formed on the surface layer portion of the first wafer principal surface 180. The first semiconductor region 121 is formed by introducing n-type impurities into the surface layer portion of the first wafer principal surface 180 by an ion implantation method. The n-type impurity may be introduced into the entire surface layer portion of the first wafer principal surface 180 without an ion implantation mask.

As a matter of course, the n-type impurity may be introduced into a region where the first semiconductor region 121 is to be formed in the surface layer portion of the first wafer principal surface 180 through the ion implantation mask. Furthermore, the first semiconductor region 121 may be formed by growing silicon from the second semiconductor region 122 (semiconductor substrate) by an epitaxial growth method. In this case, the first wafer principal surface 180 is formed by the crystal plane (crystal growth plane) of the first semiconductor region 121.

Referring to FIG. 25B, the plurality of first trenches 126, the plurality of connection trenches 134, and the plurality of withstand voltage trenches 138 are formed on the first wafer principal surface 180. In this step, unnecessary portions of the wafer 179 are selectively removed by an etching method through a hard mask (not illustrated). The etching method may be a wet etching method and/or a dry etching method. The etching method is preferably a reactive ion etching (RIE) method as an example of a dry etching method. As a result, the plurality of first trenches 126, the plurality of connection trenches 134, and the plurality of withstand voltage trenches 138 are formed. In addition, the plurality of mesa portions 131 to 133 are partitioned on the first wafer principal surface 180 by the plurality of first trenches 126 (the plurality of connection trenches 134). The hard mask is then removed.

Referring to FIG. 25C, a first base insulating film 182 serving as a base of the plurality of gate insulating films 49, the plurality of connection insulating films 57, and the plurality of withstand voltage insulating films 139 is formed on the first wafer principal surface 180. The first base insulating film 182 is formed on the first wafer principal surface 180 including the inner walls of the plurality of first trenches 126, the inner walls of the plurality of connection trenches 134, and the inner walls of the plurality of withstand voltage trenches 138. The first base insulating film 182 may be formed by an oxidation treatment method and/or a CVD method (preferably, a thermal oxidation treatment method).

Referring to FIG. 25D, a plurality of bottom wall impurity regions 167 are formed in a region along the bottom walls of the plurality of first trenches 126 and the bottom walls of the plurality of connection trenches 134 in the second semiconductor region 122. Further, in parallel therewith, the protrusion portion 145 is selectively formed in the wiring region 111. In this step, first, an ion implantation mask (not illustrated) having a predetermined pattern is formed on the first wafer principal surface 180. Next, a p-type impurity is selectively introduced into the second semiconductor region 122 by an ion implantation method through the ion implantation mask. As a result, a plurality of bottom wall impurity regions 167 and protrusion portions 145 are formed. The ion implantation mask is then removed.

Referring to FIG. 25E, the plurality of first contact regions 142, the plurality of second contact regions 143, and the plurality of first impurity regions 146 are formed. In this step, first, an ion implantation mask (not illustrated) having a predetermined pattern is formed on the first wafer principal surface 180. Next, n-type impurities are selectively introduced into the first semiconductor region 121 by an ion implantation method through the ion implantation mask. Thereby, the plurality of first contact regions 142, the plurality of second contact regions 143, and the plurality of first impurity regions 146 are formed. The ion implantation mask is then removed.

Referring to FIG. 25F, a first base electrode (not illustrated) serving as a base of the plurality of gate electrodes 128, the plurality of lead-out portions 130, the plurality of connection electrodes 136, and the plurality of withstand voltage electrodes 140 is formed on the first wafer principal surface 180. The first base electrode is formed in a film shape to cover the first wafer principal surface 180 by filling the plurality of first trenches 126, the plurality of connection trenches 134, and the plurality of withstand voltage trenches 138. In this form, the first base electrode includes conductive polysilicon. The first base electrode may be formed by a CVD method. Next, an unnecessary portion of the first base electrode is removed. As a result, the plurality of gate electrodes 128, the plurality of lead-out portions 130, the plurality of connection electrodes 136, and the plurality of withstand voltage electrodes 140 are formed.

Referring to FIG. 25G, a second base insulating film 183 serving as a base of the embedded insulator 129, the withstand voltage insulator 141, and the principal surface insulating film 147 is formed on the first wafer principal surface 180. In this form, the second base insulating film 183 is formed of a silicon oxide film. The second base insulating film 183 may be formed by a CVD method. The CVD method of the second base insulating film 183 is preferably a high density plasma (HDP)-CVD method.

The second base insulating film 183 covers the first wafer principal surface 180, the plurality of lead-out portions 130, the plurality of withstand voltage electrodes 140, and the connection electrode 136 by filling a recessed space defined by the plurality of lead-out portions 130 in the plurality of first trenches 126 and the plurality of withstand voltage trenches 138. Thereby, the embedded insulator 129 positioned in the first trench 126, the withstand voltage insulator 141 positioned in the withstand voltage trench 138, and the principal surface insulating film 147 positioned on the first wafer principal surface 180 are formed.

Referring to FIG. 25H, the plurality of first connection openings 149, the plurality of second connection openings 153, the plurality of third connection openings 164, and the plurality of base trenches 157 (base connection openings 159) are formed in the first wafer principal surface 180. In this step, first, a resist mask (not illustrated) having a predetermined pattern is formed on the principal surface insulating film 147. Next, an unnecessary portion of the principal surface insulating film 147 is selectively removed by an etching method through a resist mask. The etching method may be a wet etching method and/or a dry etching method (preferably the RIE method). Thereby, the plurality of first connection openings 149, the plurality of second connection openings 153, the plurality of third connection openings 164, and the plurality of base connection openings 159 are formed in the principal surface insulating film 147.

Next, an unnecessary portion of the wafer 179 is removed by an etching method through the resist mask. The etching method may be a wet etching method and/or a dry etching method (preferably the RIE method). An unnecessary portion of the wafer 179 penetrates the first impurity region 146 and is removed until the protrusion portion 145 is exposed. Thereby, a plurality of base trenches 157 each including the base connection opening 159 is formed on the first wafer principal surface 180. The resist mask is then removed.

Referring to FIG. 25I, a second base electrode (not illustrated) serving as a base of the plurality of first electrodes 148, the plurality of second electrodes 152, the plurality of base electrodes 158, and the plurality of third electrodes 163 is formed on the principal surface insulating film 147. In this form, the second base electrode has a base barrier film and an electrode body film laminated in this order from the wafer 179 side. Next, an unnecessary portion of the second base electrode is selectively removed by an etching method. The etching method may be a wet etching method and/or a dry etching method (preferably the RIE method). The second base electrode is removed until the principal surface insulating film 147 is exposed. As a result, the plurality of first electrodes 148, the plurality of second electrodes 152, the plurality of base electrodes 158, and the plurality of third electrodes 163 are formed. After these electrodes are formed, the silicide layer 162 is formed on the inner wall of the base trench 157 by annealing processing (for example, 500° C. or more and 1100° C. or less).

Thereafter, referring to FIG. 25J, the first interlayer insulating film 168, the first wiring layer 112, the second interlayer insulating film 171, the second wiring layer 172, the uppermost insulating film 175, the rear surface protection film 176, and the external terminals 4 to 7 are formed, and the wafer 179 is selectively cut in the thickness direction. The semiconductor device 1B is manufactured through the steps including the above-described steps.

### (3) Operation and Technical Effects of Semiconductor Device 1B

FIG. 26 is a cross-sectional view illustrating a current path of the semiconductor device 1B according to the second preferred embodiment of the present disclosure. FIG. 27 is a plan view illustrating a current path of the semiconductor device 1B according to the second preferred embodiment of the present disclosure.

The semiconductor device 1B has a trench gate lateral type MISFET structure. In this MISFET structure, a gate potential is applied to the first trench structure 123 (gate electrode 128), a drain potential is applied to the first mesa portion 131, and a source potential is applied to the second mesa portion 132. Thereby, the channel 184 is formed in a region below the first trench structure 123 in the second semiconductor region 122, and the lateral current path 185 connecting the first electrode 148 (first mesa portion 131) and the second electrode 152 (second mesa portion 132) is formed.

As illustrated in FIG. 26, the current path 185 is a path through which a current flows in the order of the first mesa portion 131 (first semiconductor region 121)→the bottom wall impurity region 167 (high-concentration p-type region)→the drift mesa portion 133 (first semiconductor region 121)→the bottom wall impurity region 167 (high-concentration p-type region)→the second mesa portion 132 (first semiconductor region 121). That is, the current path 185 is hardly formed in the second semiconductor region 122. Therefore, even when the semiconductor chip 101 is formed by a single structure of a high resistance (in this form, 10 Ω·cm or more and 100 Ω·cm or less) semiconductor substrate, an increase in the on-resistance of the semiconductor device 1B can be suppressed. As a result, since it is not necessary to form an epitaxial layer on the wafer 179 in the manufacturing process of the semiconductor device 1B, the manufacturing process can be simplified, and the material and cost can be reduced.

In the semiconductor device 1B, as illustrated in FIG. 27, the base electrode 158 for fixing the potential (substrate potential) of the second semiconductor region 122 is formed in the wiring region 111 away from the drift region 109 in which the current path 185 is formed in the second direction Y, and is not formed in the drift region 109. As a result, the current path 185 connecting the first electrode 148 and the second electrode 152 at the shortest distance can be formed in the entire drift region 109. That is, since the wiring region 111 for fixing the substrate potential and the drift region 109 for the current path 185 are separately located, the on-resistance can be reduced.

In addition, since a space for the base electrode 158 is unnecessary in the drift region 109, the width of the drift region 109 in the first direction X can be narrowed. As a result, the resistance value of each drift region 109 can be reduced, and the number of cells located in one cell region 110 can be increased. As a result, the on-resistance can be reduced.

As illustrated in FIG. 24, in the contact region 61, the protrusion portion 59 extends toward the first principal surface 10. Thereby, the contact point with respect to the second semiconductor region 122 can be raised toward the first principal surface 10 side from the boundary portion 144 between the first semiconductor region 121 and the second semiconductor region 122. Therefore, it is not necessary to form the second trench structure 156 reaching the boundary portion 144, and the substrate potential can be fixed by the relatively shallow second trench structure 156. Since the base trench 157 is shallow, it is possible to secure a contact with respect to the substrate potential with a simple structure.

Referring to FIG. 24, for example, when the second trench structure 156 has a depth reaching the second principal surface 103 side of the boundary portion 144, the silicide layer 162 may be formed only locally on the inner wall of the base trench 157. Specifically, there is a case where the silicide layer 162 is locally formed on the bottom wall of the base trench 157 and the upper end portion of the side wall, and the silicide layer 162 is not formed on the other portion of the inner wall. On the other hand, in the structure illustrated in FIG. 24, since the base trench 157 is shallow, the silicide layer 162 can be formed over the entire second trench structure 156. Therefore, the surface state of the inner wall of the base trench 157 can be smoothly improved, and the base electrode body 161 and the base trench 157 can be favorably brought into contact with each other. Thereby, the contact resistance of the base electrode body 161 can be reduced.

Since the wiring region 111 for fixing the substrate potential is formed in the active region 105, it is not necessary to form an outer peripheral structure for fixing the substrate potential in the outer peripheral region 106. Therefore, the area of the outer peripheral region 106 can be reduced, and the area of the active region 105 can be enlarged. As a result, the current characteristics of the semiconductor device 1B can be improved. For example, in the semiconductor device 1B, the occupancy of the active region 105 on the first principal surface 102 may be 10% or more and 99.9% or less.

In addition, the end portions of the first source/drain region 107 and the second source/drain region 108 in the second direction Y are divided by the trench withstand voltage structure 125. As a result, since the trench withstand voltage structure 125 is interposed between the first and second source/drain regions 107 and 108 and the trench connection structure 124, the withstand voltage in the lateral direction along the first principal surface 102 of the semiconductor device 1B can be improved.

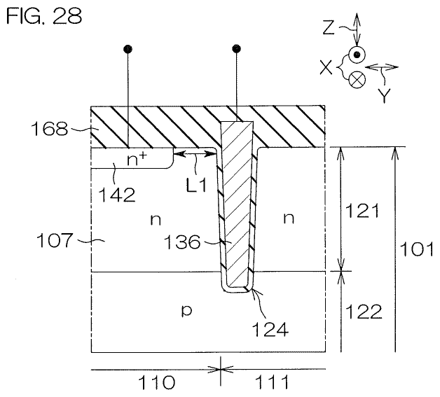

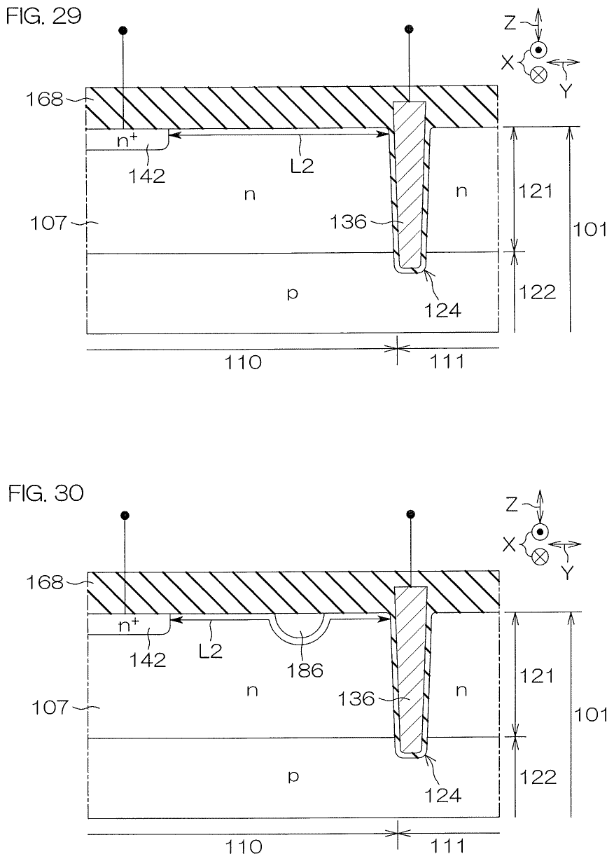

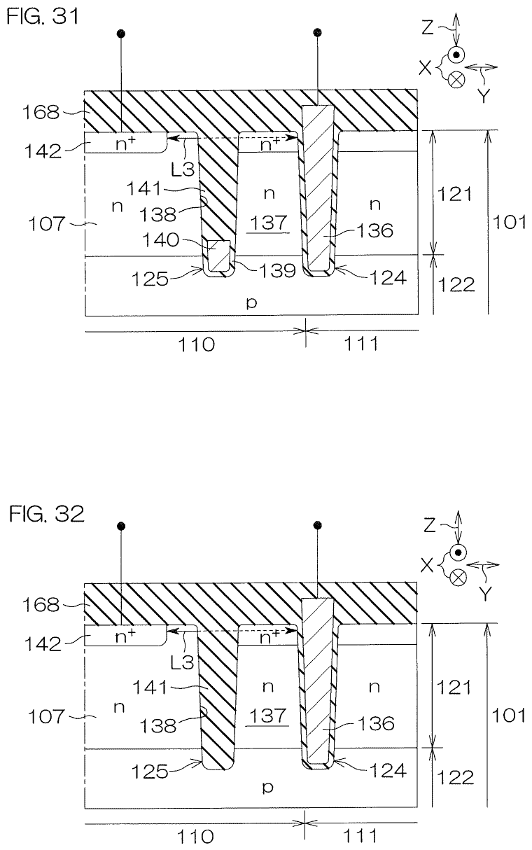

FIGS. 28 and 29 are reference examples in which the trench withstand voltage structure 125 is not formed in the semiconductor device 1B. FIGS. 30 and 31 are enlarged views of the vicinity of the trench withstand voltage structure 125. The lateral withstand voltage of the first source/drain region 107 will be described with reference to FIGS. 28 to 31, but the principle of the lateral withstand voltage of the second source/drain region 108 is the same.

In this reference example, in a region adjacent to the first source/drain region 107, the connection electrode 136 of the trench connection structure 124 is pulled up to the first principal surface 102. Therefore, the lateral withstand voltage along the first principal surface 102 depends on a distance L1 between the first contact region 142 and the connection electrode 136. Therefore, in order to improve the lateral withstand voltage, it is necessary to secure the wide distance L1.

For example, as illustrated in FIG. 29, the lateral withstand voltage can be secured by setting the distance between the first contact region 142 and the connection electrode 136 to a distance L2 larger than the distance L1 in FIG. 28. In addition, as illustrated in FIG. 30, the lateral withstand voltage can be secured by securing the distance L2 and forming the p-type withstand voltage impurity region 186 in a part of the surface layer portion of the first principal surface 102. However, in the structures of FIGS. 29 and 30, by widening the distance L2, an unnecessary space in the cell region 110 may increase, and the on-resistance may increase. In addition, in the structure of FIG. 30, it is necessary to perform the impurity implantation process by newly adding a mask, and the number of processes of the manufacturing process increases.

On the other hand, as illustrated in FIG. 31, if the trench withstand voltage structure 125 is interposed between the first source/drain region 107 and the trench connection structure 124, the electric field can be relaxed by the trench withstand voltage structure 125. As a result, even when a distance L3 between the first contact region 142 and the connection electrode 136 is short, a sufficient lateral withstand voltage can be secured. For example, in a structure in which the trench withstand voltage structure 125 is formed, the distance L3 may be 0.1 μm or more and 0.4 μm or less.

In addition, unlike the withstand voltage impurity region 186 diffused in the lateral direction by the annealing treatment, the trench withstand voltage structure 125 formed by etching the semiconductor chip 101 in the longitudinal direction is a countermeasure, so that unnecessary space in the cell region 110 can be reduced. Furthermore, since the trench withstand voltage structure 125 and the first trench structure 123 can be formed in the same process, an increase in manufacturing process cost can also be suppressed.

Furthermore, the trench withstand voltage structure 125 may have the same structure as the first trench structure 123 as illustrated in FIGS. 24 and 31, or may have a structure in which the withstand voltage insulator 141 is embedded in the entire withstand voltage trench 138 without the withstand voltage electrode 140 as illustrated in FIG. 32.

### (5) Modified Example of Semiconductor Device 1B

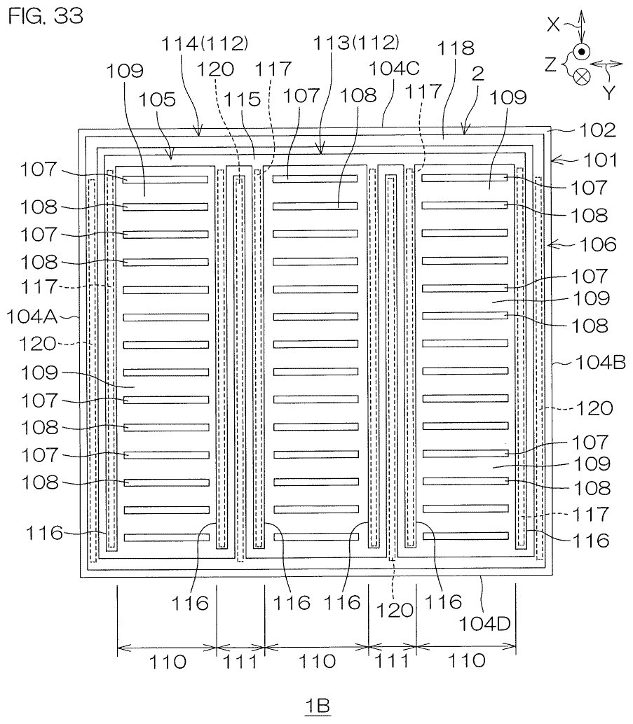

Next, modified examples of the semiconductor device 1B will be described with reference to FIGS. 33 to 35.

FIG. 33 is a cross-sectional view illustrating a first modified example of the semiconductor device 1B according to the second preferred embodiment of the present disclosure, and is a cross-sectional view corresponding to FIG. 19.

In FIG. 19, the plurality of first gate contacts 117 and the plurality of first base contacts 120 are located at intervals in the first direction X. On the other hand, as illustrated in FIG. 33, one first gate contact 117 and one first base contact 120 may be formed to cross the regions in the vicinity of the respective end portions of the plurality of first source/drain regions 107 and the plurality of second source/drain regions 108.

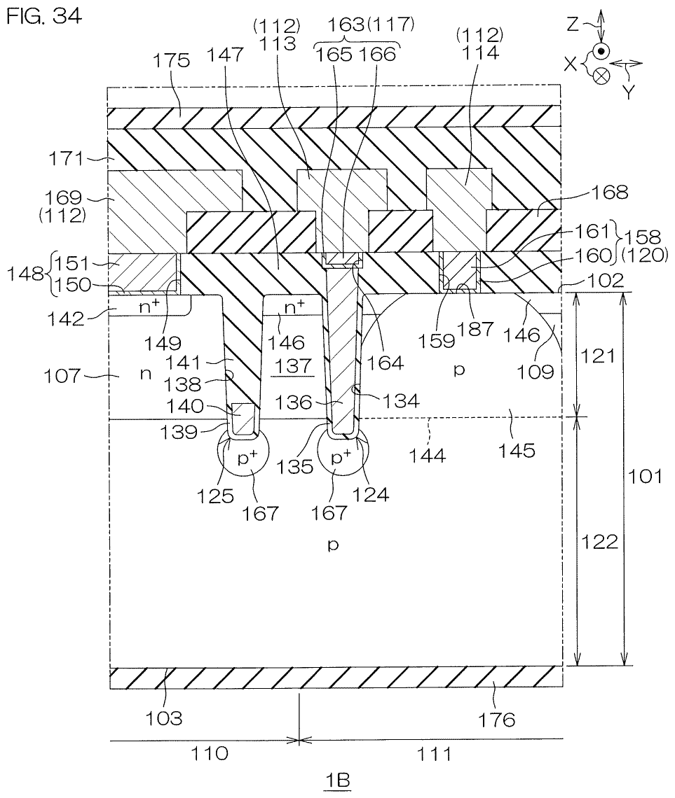

FIG. 34 is a cross-sectional view illustrating a second modified example of the semiconductor device 1B according to the second preferred embodiment of the present disclosure, and is a cross-sectional view corresponding to FIG. 24.

The protrusion portion 145 may penetrate the first semiconductor region 121 from the second semiconductor region 122 and reach the first principal surface 102. As a result, the protrusion portion 145 may have the apex portion 187 exposed from the first principal surface 102 in the wiring region 111. In this case, the base electrode 158 may not be formed as the second trench structure 156. The base electrode 158 may be embedded in the base connection opening 159 and have a bottom portion on the first principal surface 102. Thus, the base electrode 158 is connected to the protrusion portion 145 at the first principal surface 102. According to this configuration, since the step of forming the second trench structure 156 can be omitted, the manufacturing step can be simplified, and the material and cost can be reduced.

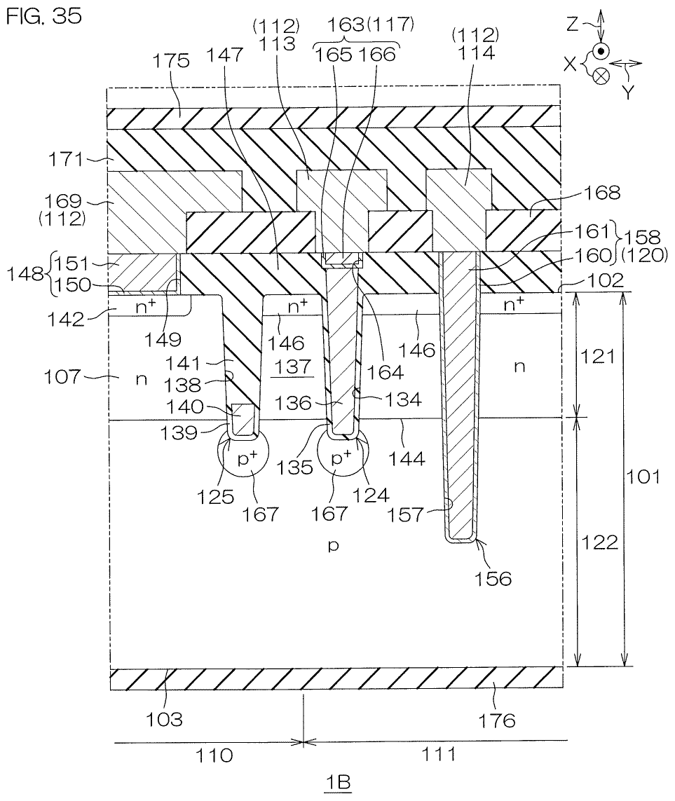

FIG. 35 is a cross-sectional view illustrating a third modified example of the semiconductor device 1B according to the first preferred embodiment of the present disclosure, and is a cross-sectional view corresponding to FIG. 24.

Referring to FIG. 35, the second trench structure 156 may be deeper than the first trench structure 123. Specifically, the base trench 157 deeper than the first trench 126 may cross the boundary portion 144 and reach the second semiconductor region 122. Thereby, the step of forming the protrusion portion 145 can be omitted, so that the manufacturing step can be simplified, and the material and cost can be reduced.

Although not illustrated, also in the semiconductor device 1B, similarly to the semiconductor device 1A illustrated in FIG. 18, the rear surface protection film 176 may not be formed on the second principal surface 103 of the semiconductor chip 101, and the second principal surface 103 may be an exposed surface.

Although the plurality of preferred embodiments of the present disclosure have been described above, each preferred embodiment can be further implemented in other forms. For example, in each of the above-described preferred embodiments, an example in which the “first conductivity type” is the “n-type” and the “second conductivity type” is the “p-type” has been described. However, a structure in which the “first conductivity type” is “p-type” and the “second conductivity type” is “n-type” may be adopted. A specific configuration in this case can be obtained by replacing the “n-type region” with the “p-type region” and at the same time replacing the “n-type region” with the “p-type region” in the above description and the accompanying drawings.

In each of the above-described preferred embodiments, when the semiconductor chip (8, 101) includes an SiC single crystal, the semiconductor chip (8, 101) preferably includes an SiC single crystal formed of hexagonal crystal. SiC single crystals composed of hexagonal crystals have a plurality of types of polytypes including 2H (Hexagonal)-SiC single crystals, 4H-SiC single crystals, and 6H-SiC single crystals according to the period of the atomic arrangement. The semiconductor chip (8, 101) is preferably formed of a 4H-SiC single crystal among a plurality of types of polytypes.

In this case, it is preferable that the first principal surface (10, 102) is formed of a silicon face ((0001) face) of an SiC single crystal, and the second principal surface (11, 103) is formed of a carbon face ((000-1) face) of an SiC single crystal. As a matter of course, the first principal surface (10, 102) may be formed of a carbon surface, and the second principal surface (11, 103) may be formed of a silicon surface. The (0001) plane and the (000-1) plane of the SiC single crystal are referred to as c-planes.

The first principal surface (10, 102) may have an off angle inclined at a predetermined angle in a predetermined off direction with respect to the c-plane of the SiC single crystal. The off direction may be the a-axis direction ([11-20] direction) of the SiC single crystal. The off angle may be 0° or more and 5.0° or less. In this case, the first direction X may be the m-axis direction of the SiC single crystal, and the second direction Y may be the a-axis direction of the SiC single crystal. As a matter of course, the first direction X may be the a-axis direction of the SiC single crystal, and the second direction Y may be the m-axis direction of the SiC single crystal.

Hereinafter, characteristic examples extracted from this specification and the accompanying drawings will be described. Hereinafter, a semiconductor device having a novel structure will be provided. Although alphanumeric characters within parentheses in the following express corresponding constituent elements, etc., in the preferred embodiments described above, these are not meant to limit the scopes of the respective items to the preferred embodiments.

### [Appendix 1-1]

A semiconductor device (1A, 1B) including:
a semiconductor chip (8, 101) formed of a single layer having a first principal surface (10, 102) and a second principal surface (11, 103) opposite to the first principal surface;
a first semiconductor region (46, 121) of a first conductivity type formed on the first principal surface (10, 102) side of the semiconductor chip (8, 101);
a second semiconductor region (47, 122) of a second conductivity type formed on the second principal surface (11, 103) side with respect to the first semiconductor region (46, 121) of the semiconductor chip (8, 101); and a first trench structure (17, 123) including a first trench (48, 126) that penetrates the first semiconductor region (46, 121) from the first principal surface (10, 102) and partitions the first semiconductor region (46, 121) into a first region (19, 107) on one side and a second region (20, 108) on the other side in a cross-sectional view, a control insulating film (49, 127) that covers an inner wall of the first trench (48, 126), and a control electrode (50, 128) that is embedded in the first trench (48, 126) with the control insulating film (49, 127) interposed therebetween and controls a channel (96, 184) in the second semiconductor region (47, 122) that makes the first region (19, 107) and the second region (20, 108) conductive in a lateral direction along the first principal surface (10, 102).

### [Appendix 1-2]

The semiconductor device (1A, 1B) according to Appendix 1-1,
wherein the second conductivity type impurity concentration of the second semiconductor region (47, 122) from the second principal surface (11, 103) to the first semiconductor region (46, 121) is 1.0×10²⁰ cm⁻³ or less in the thickness direction of the semiconductor chip (8, 101).

### [Appendix 1-3]

The semiconductor device (1A, 1B) according to Appendix 1-1 or 1-2,
wherein the second conductivity type impurity concentration of the second semiconductor region (47, 122) from the second principal surface (11, 103) to the first semiconductor region (46, 121) is substantially constant in the thickness direction of the semiconductor chip (8, 101).

### [Appendix 1-4]

The semiconductor device (1A, 1B) according to any one of Appendices 1-1 to 1-3,
wherein the second conductivity type impurity concentration of the second semiconductor region (47, 122) is 1.0×10¹³ cm⁻³ or more and 1.0×10¹⁶ cm⁻³ or less over an entire region from the second principal surface (11, 103) to the first semiconductor region (46, 121) in the thickness direction of the semiconductor chip (8, 101).

### [Appendix 1-5]

The semiconductor device (1A, 1B) according to any one of Appendices 1-1 to 1-4,
wherein a resistance value of the second semiconductor region (47, 122) is 10 Ω·cm or more and 100 Ω·cm or less.

### [Appendix 1-6]

The semiconductor device (1A, 1B) according to Appendix 1-5,
wherein a resistance value of the second semiconductor region (47, 122) is 10 Ω·cm or more and 100 Ω·cm or less over an entire region from the second principal surface (11, 103) to the first semiconductor region (46, 121) in the thickness direction of the semiconductor chip (8, 101).

### [Appendix 1-7]

The semiconductor device (1A, 1B) according to any one of Appendices 1-1 to 1-6,
wherein the semiconductor chip (8, 101) is a semiconductor substrate having no epitaxial layer.

### [Appendix 1-8]

The semiconductor device (1A, 1B) according to any one of Appendices 1-1 to 1-7,
wherein the first conductivity type impurity concentration of the first semiconductor region (46, 121) is 1.0×10¹⁴ cm⁻³ or more and 1.0×10¹⁸ cm⁻³ or less.

### [Appendix 1-9]

The semiconductor device (1A, 1B) according to any one of Appendices 1-1 to 1-8, further including:
an insulating protection film (88, 176) covering the entire second principal surface (11, 103) of the semiconductor chip (8, 101).

### [Appendix 1-10]

The semiconductor device (1A, 1B) according to any one of Appendices 1-1 to 1-8,
wherein the second principal surface (11, 103) of the semiconductor chip (8, 101) is an exposed surface.

### [Appendix 1-11]

The semiconductor device (1A, 1B) according to Appendix 1-1,
wherein the second conductivity type impurity concentration of the second semiconductor region (47, 122) is 1.0×10¹³ cm⁻³ or more and 1.0×10¹⁶ cm⁻³ or less, and the resistance value of the second semiconductor region (47, 122) is 10 Ω·cm or more and 100 ΩΩ·cm or less, over an entire region from the second principal surface (11, 103) to the first semiconductor region (46, 121) in the thickness direction of the semiconductor chip (8, 101).

### [Appendix 1-12]

The semiconductor device (1A, 1B) according to Appendix 1-11,
wherein the semiconductor chip (8, 101) is a semiconductor substrate having no epitaxial layer.

### [Appendix 1-13]

The semiconductor device (1A, 1B) according to Appendix 1-11,
wherein the semiconductor chip (8, 101) is an Si single crystal substrate or an SiC single crystal substrate having no epitaxial layer.

### [Appendix 1-14]

The semiconductor device (1A, 1B) according to Appendix 1-13, further including:
an insulating protection film (88, 176) covering the entire second principal surface (11, 103) of the semiconductor chip (8, 101).

### [Appendix 1-15]

The semiconductor device (1A, 1B) according to any one of Appendices 1-1 to 1-14, further including:
a drift region (21, 109) sandwiched between the pair of first trench structures (17, 123),
wherein the first region (19, 107) includes a first source/drain region (19, 107) opposing the drift region (21, 109) with one of first trench structures (17, 123) interposed therebetween,
the second region (20, 108) includes a second source/drain region (20, 108) opposite to the first source/drain region (19, 107) with the drift region (21, 109) interposed therebetween, and
the semiconductor device further includes: a first source/drain electrode (65, 148) electrically connected to the first source/drain region (19, 107); and a second source/drain electrode (69, 152) electrically connected to the second source/drain region (20, 108).

### [Appendix 2-1]

A semiconductor device (1A, 1B) including:
a semiconductor chip (8, 101) having a first principal surface (10, 102) and a second principal surface (11, 103) opposite to the first principal surface;
a first semiconductor region (46, 121) of a first conductivity type formed on the first principal surface (10, 102) side of the semiconductor chip (8, 101);
a second semiconductor region (47, 122) of a second conductivity type formed on the second principal surface (11, 103) side with respect to the first semiconductor region (46, 121) of the semiconductor chip (8, 101);
a first trench structure (17, 123) that penetrates the first semiconductor region (46, 121) from the first principal surface (10, 102) and includes a first trench (48, 126) that partitions the first semiconductor region (46, 121) into a first region (19, 107) on one side and a second region (20, 108) on the other side in a cross-sectional view, a control insulating film (49, 127) that covers an inner wall of the first trench (48, 126), and a control electrode (50, 128) that is embedded in the first trench (48, 126) with the control insulating film (49, 127) interposed therebetween and controls a channel (96, 184) in the second semiconductor region (47, 122) that makes the first region (19, 107) and the second region (20, 108) conductive in a lateral direction along the first principal surface (10, 102);
a first electrode (65, 148) electrically connected to the first semiconductor region (46, 121) in the first region (19, 107);
a second electrode (69, 152) electrically connected to the first semiconductor region (46, 121) in the second region (20, 108);
a protrusion portion (59, 145) of a second conductivity type that selectively protrudes from the second semiconductor region (47, 122) toward the first principal surface (10, 102) to the inside of the first semiconductor region (46, 121); and
a contact electrode (76, 158) electrically connected to the protrusion portion (59, 145) and separated from the first electrode (65, 148) and the second electrode (69, 152).

### [Appendix 2-2]

The semiconductor device (1A, 1B) according to Appendix 2-1, further including:
a second trench structure (73, 156) including a contact trench (75, 157) reaching the protrusion portion (59, 145) from the first principal surface (10, 102) and the contact electrode (76, 158) embedded in the contact trench (75, 157) and connected to the protrusion portion (59, 145) in the contact trench (75, 157).

### [Appendix 2-3]

The semiconductor device (1A, 1B) according to Appendix 2-2,
wherein the contact trench (75, 157) is shallower than the first trench (48, 126).

### [Appendix 2-4]

The semiconductor device (1A, 1B) according to Appendix 2-3,
wherein a depth of the contact trench (75, 157) is 0.2 μm or more and 0.5 μm or less.

### [Appendix 2-5]

The semiconductor device (1A, 1B) according to any one of Appendices 2-2 to 2-4,
wherein the contact electrode (76, 158) includes a barrier film (77, 160) formed in a film shape along a side wall and a bottom wall of the contact trench (75, 157) and partitioning a recessed space in the contact trench (75, 157) and an electrode body (78, 161) embedded in the contact trench (75, 157) with the barrier film (77, 160) interposed therebetween, and
the semiconductor device further includes: a silicide layer (79, 162) formed at a boundary portion between the semiconductor chip (8, 101) and the barrier film (77, 160) along a side wall and a bottom wall of the contact trench (75, 157).

### [Appendix 2-6]

The semiconductor device (1A, 1B) according to Appendix 2-5,
wherein the silicide layer (79, 162) is uniformly formed over the entire side wall and bottom wall of the contact trench (75, 157).

### [Appendix 2-7]

The semiconductor device (1A, 1B) according to any one of Appendices 2-1 to 2-6, further including:
a first impurity region (63, 146) of a first conductivity type formed in contact with an apex portion of the protrusion portion (59, 145) in a surface layer portion of the first principal surface (10, 102) and having an impurity concentration higher than an impurity concentration of the first semiconductor region (46, 121).

### [Appendix 2-8]

The semiconductor device (1A, 1B) according to any one of Appendices 2-1 to 2-7, further including:
a drift region (21, 109) sandwiched between the pair of first trench structures (17, 123),
wherein the first region (19, 107) includes a first source/drain region (19, 107) opposing the drift region (21, 109) with one of the first trench structures (17, 123) interposed therebetween,
the second region (20, 108) includes a second source/drain region (20, 108) opposite to the first source/drain region (19, 107) with the drift region (21, 109) interposed therebetween,
a current path through the channel (96, 184) is formed along a first direction (X) from the first source/drain region (19, 107) to the second source/drain region (20, 108) across the drift region (21, 109), and
the second region (20, 108) includes a contact region (61) in which the protrusion portion (59, 145) is selectively formed and the contact electrode (76, 158) is located and a current region (62) of a first conductivity type sandwiched between the pair of first trench structures (17, 123), independently of each other, in a second direction (Y) intersecting the first direction (X).

### [Appendix 2-9]

The semiconductor device (1A, 1B) according to Appendix 2-8,
wherein a plurality of the contact regions (61) are located at intervals from each other along the second direction (Y).

### [Appendix 2-10]

The semiconductor device (1A, 1B) according to Appendix 2-9,
wherein the pair of first trench structures (17, 123) are formed in a band shape extending along the second direction (Y) in a plan view, and
the plurality of contact regions (61) are formed to divide the drift region (21, 109) having a band shape in a plan view and sandwiched between the pair of first trench structures (17, 123) at a plurality of locations along the second direction (Y).

### [Appendix 2-11]

The semiconductor device (1A, 1B) according to any one of Appendices 2-8 to 2-10,
wherein the contact region (61) is shorter than the current region (62) in the second direction (Y).

[Appendix 2-12]

The semiconductor device (1A, 1B) according to Appendix 2-11,
wherein a length of the contact region (61) in the second direction (Y) is 0.1 μm or more and 100 μm or less, and a length of the current region (62) in the second direction (Y) is 1 μm or more and 3000 μm or less.

### [Appendix 2-13]

The semiconductor device (1A, 1B) according to any one of Appendices 2-1 to 2-12,
wherein the semiconductor chip (8, 101) is a semiconductor substrate having no epitaxial layer.

### [Appendix 2-14]

The semiconductor device (1A, 1B) according to any one of Appendices 2-1 to 2-13,
wherein the second conductivity type impurity concentration of the second semiconductor region (47, 122) from the second principal surface (11, 103) to the first semiconductor region (46, 121) is 1.0×10²⁰ cm⁻³ or less in the thickness direction of the semiconductor chip (8, 101).

### [Appendix 2-15]

The semiconductor device (1A, 1B) according to any one of Appendices 2-1 to 2-14,
wherein a resistance value of the second semiconductor region (47, 122) is 10 Ω·cm or more and 100 Ω·cm or less.

### [Appendix 3-1]

A semiconductor device (1A, 1B) including:
a semiconductor chip (8, 101) having a first principal surface (10, 102) and a second principal surface (11, 103) opposite thereto, and having an active region (15, 105) and an outer peripheral region (16, 106) surrounding the active region (15, 105);
a first semiconductor region (46, 121) of a first conductivity type formed on the first principal surface (10, 102) side of the semiconductor chip (8, 101);
a second semiconductor region (47, 122) of a second conductivity type formed on the second principal surface (11, 103) side with respect to the first semiconductor region (46, 121) of the semiconductor chip (8, 101);
a first trench structure (17, 123) including a first trench (48, 126) that penetrates the first semiconductor region (46, 121) from the first principal surface (10, 102) in the active region (15, 105) and partitions the first semiconductor region (46, 121) into a first region (19, 107) on one side and a second region (20, 108) on the other side in a cross-sectional view, a control insulating film (49, 127) that covers an inner wall of the first trench (48, 126), and a control electrode (50, 128) that is embedded in the first trench (48, 126) with the control insulating film (49, 127) interposed therebetween and controls a channel (96, 184) in the second semiconductor region (47, 122) that makes the first region (19, 107) and the second region (20, 108) conductive in a lateral direction along the first principal surface (10, 102);
a first electrode (65, 148) electrically connected to the first semiconductor region (46, 121) in the first region (19, 107);
a second electrode (69, 152) electrically connected to the first semiconductor region (46, 121) in the second region (20, 108); and
a contact electrode (76, 158) that is located in a drift region (21, 109) where a current path for conducting between the first electrode (65, 148) and the second electrode (69, 152) is formed in the active region (15, 105), and is electrically connected to the second semiconductor region (47, 122).

### [Appendix 3-2]

The semiconductor device (1A, 1B) according to Appendix 3-1,
wherein a pair of the first trench structures (17, 123) are formed to separate the first region (19, 107) and the drift region (21, 109) and separate the drift region (21, 109) and the second region (20, 108) from each other such that the first region (19, 107) and the second region (20, 108) oppose each other with the drift region (21, 109) interposed therebetween, and
the semiconductor device further includes: a second trench structure (73, 156) including a contact trench (75, 157) formed from the first principal surface (10, 102) toward the second principal surface (11, 103) in the drift region (21, 109), and a contact electrode (76, 158) embedded in the contact trench (75, 157) and electrically connected to the second semiconductor region (47, 122) in the contact trench (75, 157).

### [Appendix 3-3]

The semiconductor device (1A, 1B) according to Appendix 3-2, further including:
a protrusion portion (59, 145) of a second conductivity type that selectively protrudes from the second semiconductor region (47, 122) toward the first principal surface (10, 102) to the inside of the drift region (21, 109),
wherein the contact electrode (76, 158) is connected to the protrusion portion (59, 145).

### [Appendix 3-4]

The semiconductor device (1A, 1B) according to Appendix 3-3,
wherein the contact trench (75, 157) is shallower than the first trench (48, 126).

### [Appendix 3-5]

The semiconductor device (1A, 1B) according to Appendix 3-4,
wherein a depth of the contact trench (75, 157) is 0.2 μm or more and 0.5 μm or less.

### [Appendix 3-6]

The semiconductor device (1A, 1B) according to Appendix 3-4,
wherein the contact electrode (76, 158) includes a barrier film (77, 160) formed in a film shape along a side wall and a bottom wall of the contact trench (75, 157) and partitioning a recessed space in the contact trench (75, 157) and an electrode body (78, 161) embedded in the contact trench (75, 157) with the barrier film (77, 160) interposed therebetween, and
the semiconductor device further includes: a silicide layer (79, 162) formed at a boundary portion between the semiconductor chip (8, 101) and the barrier film (77, 160) along a side wall and a bottom wall of the contact trench (75, 157).

### [Appendix 3-7]

The semiconductor device (1A, 1B) according to Appendix 3-6,
wherein the silicide layer (79, 162) is uniformly formed over the entire side wall and bottom wall of the contact trench (75, 157).

### [Appendix 3-8]

The semiconductor device (1A, 1B) according to Appendix 3-2,
wherein the contact trench (75, 157) is deeper than the first trench (48, 126).

### [Appendix 3-9]

The semiconductor device (1A, 1B) according to Appendix 3-1,
wherein a pair of the first trench structures (17, 123) are formed to separate the first region (19, 107) and the drift region (21, 109) and separate the drift region (21, 109) and the second region (20, 108) from each other such that the first region (19, 107) and the second region (20, 108) oppose each other with the drift region (21, 109) interposed therebetween,
the semiconductor device further includes: a protrusion portion (59, 145) of a second conductivity type that selectively protrudes from the second semiconductor region (47, 122) to the first principal surface (10, 102) through the drift region (21, 109), and
the contact electrode (76, 158) has a bottom portion on the first principal surface (10, 102), and is connected to the protrusion portion (59, 145) at the first principal surface (10, 102).

### [Appendix 3-10]

The semiconductor device (1A, 1B) according to any one of Appendices 3-1 to 9,
wherein the first semiconductor region (46, 121) is formed over the entire active region (15, 105) and the entire outer peripheral region (16, 106), and forms a side surface of the semiconductor chip (8, 101).

### [Appendix 3-11]

The semiconductor device (1A, 1B) according to any one of Appendices 3-1 to 9,
wherein an occupancy of the active region (15, 105) in the first principal surface (10, 102) of the semiconductor chip (8, 101) is 10% or more and 99.9% or less.

### [Appendix 3-12]

The semiconductor device (1A, 1B) according to any one of Appendices 3-1 to 9,
wherein the first electrode (65, 148) is a first source/drain electrode, and the second electrode (69, 152) is a second source/drain electrode.

### [Appendix 3-13]

The semiconductor device (1A, 1B) according to any one of Appendices 3-1 to 9,
wherein the semiconductor chip (8, 101) is a semiconductor substrate having no epitaxial layer.

### [Appendix 3-14]

The semiconductor device (1A, 1B) according to Appendix 3-13,
wherein the second conductivity type impurity concentration of the second semiconductor region (47, 122) from the second principal surface (11, 103) to the first semiconductor region (46, 121) is 1.0×10²⁰ cm⁻³ or less in the thickness direction of the semiconductor chip (8, 101).

### [Appendix 3-15]

The semiconductor device (1A, 1B) according to Appendix 3-13,
wherein a resistance value of the second semiconductor region (47, 122) is 10 (Ω·cm or more and 100 Ω·cm or less.

### [Appendix 4-1]

A semiconductor device (1A, 1B) including:
a semiconductor chip (8, 101) having a first principal surface (10, 102) and a second principal surface (11, 103) opposite to the first principal surface;
a first semiconductor region (46, 121) of a first conductivity type formed on the first principal surface (10, 102) side of the semiconductor chip (8, 101);
a second semiconductor region (47, 122) of a second conductivity type formed on the second principal surface (11, 103) side with respect to the first semiconductor region (46, 121) of the semiconductor chip (8, 101);
a first trench structure (17, 123) including a first trench (48, 126) that penetrates the first semiconductor region (46, 121) from the first principal surface (10, 102) and partitions the first semiconductor region (46, 121) into a first region (19, 107) on one side and a second region (20, 108) on the other side in a first direction (X), a control insulating film (49, 127) that covers an inner wall of the first trench (48, 126), and a control electrode (50, 128) that is embedded in the first trench (48, 126) with the control insulating film (49, 127) interposed therebetween and controls a channel (96, 184) in the second semiconductor region (47, 122) that makes the first region (19, 107) and the second region (20, 108) conductive in the first direction (X);
a first electrode (65, 148) electrically connected to the first semiconductor region (46, 121) in the first region (19, 107);
a second electrode (69, 152) electrically connected to the first semiconductor region (46, 121) in the second region (20, 108); and
a contact electrode (76, 158) that is located away from a drift region (21, 109) in which a current path for conducting between the first electrode (65, 148) and the second electrode (69, 152) is formed in the semiconductor chip (8, 101) in a second direction (Y) intersecting the first direction (X), and is electrically connected to the second semiconductor region (47, 122).

### [Appendix 4-2]

The semiconductor device (1A, 1B) according to Appendix 4-1,
wherein a pair of band-shaped first trench structures (17, 123) are formed to separate the first region (19, 107) and the drift region (21, 109) and separate the drift region (21, 109) and the second region (20, 108) so that the first region (19, 107) and the second region (20, 108) oppose each other with the drift region (21, 109) interposed therebetween, and extends along the second direction (Y), and
the contact electrode (76, 158) is located adjacent to an end portion in the second direction (Y) of the band-shaped drift region (21, 109) extending along the second direction (Y).

### [Appendix 4-3]

The semiconductor device (1A, 1B) according to Appendix 4-2,
wherein a width of the drift region (21, 109) in the first direction (X) is 0.01 μm or more and 10 μm or less.

### [Appendix 4-4]

The semiconductor device (1A, 1B) according to Appendix 4-2,
wherein a pitch of the pair of first trench structures (17, 123) is 0.03 μm or more and 10 μm or less.

### [Appendix 4-5]

The semiconductor device (1A, 1B) according to Appendix 4-2,
wherein the contact electrode (76, 158) is located adjacent to each of both end portions of the drift region (21, 109) in the second direction (Y).

### [Appendix 4-6]

The semiconductor device (1A, 1B) according to any one of Appendices 4-1 to 4-5,
wherein the first region (19, 107) and the second region (20, 108) each include a band-shaped first source/drain region (19, 107) and a band-shaped second source/drain region (20, 108) extending along the second direction (Y),
a plurality of the first source/drain regions (19, 107) and a plurality of the second source/drain regions (20, 108) are alternately located at intervals in the first direction (X) such that the drift region (21, 109) is sandwiched between the first source/drain region (19, 107) and the second source/drain region (20, 108) adjacent to each other,
the semiconductor device further includes: a contact wiring layer (114) located in a band-shaped wiring region (111) extending in a direction crossing the vicinity of each end portion of the plurality of first source/drain regions (19, 107) and the plurality of second source/drain regions (20, 108), and
the contact electrode (76, 158) is located below the contact wiring layer (114) in the wiring region (111).

### [Appendix 4-7]

The semiconductor device (1A, 1B) according to Appendix 4-6,
wherein a plurality of the contact electrodes (76, 158) are located at intervals in the first direction (X), and
each of the contact electrodes (76, 158) is located at a position opposing each of the drift regions (21, 109) in the second direction (Y).

### [Appendix 4-8]

The semiconductor device (1A, 1B) according to Appendix 4-6,
wherein the one contact electrode (76, 158) extends in a direction crossing a region in the vicinity of each end portion of the plurality of first source/drain regions (19, 107) and the plurality of second source/drain regions (20, 108) below the contact wiring layer (114).

### [Appendix 4-9]

The semiconductor device (1A, 1B) according to any one of Appendices 4-6 to 4-8,
wherein a plurality of cell regions (110) in which a plurality of sets of the first source/drain region (19, 107), the second source/drain region (20, 108), and the first trench structure (17, 123) between these are located are formed at intervals in the second direction (Y), and the wiring region (111) is formed between the adjacent cell regions (110).

### [Appendix 4-10]

The semiconductor device (1A, 1B) according to Appendix 4-9, further including:
a pair of band-shaped control wiring layers (113) extending along the first direction (X) in the wiring region (111) to sandwich the contact wiring layer (114),
wherein one control wiring layer (113) is electrically connected to the control electrode (50, 128) in the cell region (110) on one side with respect to the wiring region (111), and the other control wiring layer (113) is electrically connected to the control electrode (50, 128) in the cell region (110) on the other side with respect to the wiring region (111).

### [Appendix 4-11]

The semiconductor device (1A, 1B) according to Appendix 4-9 or 4-10,
wherein the contact wiring layer (114) includes an outer peripheral portion (118) extending along an outer peripheral region of the semiconductor chip (8, 101) and a branch portion (119) extending on the wiring region (111) from the outer peripheral portion (118) toward the inside of the semiconductor chip (8, 101), and
the contact electrode (76, 158) is located below both the outer peripheral portion (118) and the branch portion (119).

### [Appendix 4-12]

The semiconductor device (1A, 1B) according to any one of Appendices 4-6 to 4-11, further including:
a protrusion portion (59, 145) of a second conductivity type that selectively protrudes from the second semiconductor region (47, 122) toward the first principal surface (10, 102) to the inside of the wiring region (111),
wherein the contact electrode (76, 158) is connected to the protrusion portion (59, 145).

### [Appendix 4-13]

The semiconductor device (1A, 1B) according to Appendix 4-12, further including:
a second trench structure (73, 156) including a contact trench (75, 157) formed from the first principal surface (10, 102) toward the second principal surface (11, 103) in the wiring region (111) and the contact electrode (76, 158) embedded in the contact trench (75, 157) and connected to the protrusion portion (59, 145) in the contact trench (75, 157).

### [Appendix 4-14]

The semiconductor device (1A, 1B) according to Appendix 4-13,
wherein the contact trench (75, 157) is shallower than the first trench (48, 126).

### [Appendix 4-15]

The semiconductor device (1A, 1B) according to Appendix 4-14,
wherein a depth of the contact trench (75, 157) is 0.2 μm or more and 0.5 μm or less.

### [Appendix 4-16]

The semiconductor device (1A, 1B) according to any one of Appendices 4-13 to 4-15,
wherein the contact electrode (76, 158) includes a barrier film (77, 160) formed in a film shape along a side wall and a bottom wall of the contact trench (75, 157) and partitioning a recessed space in the contact trench (75, 157) and an electrode body (78, 161) embedded in the contact trench (75, 157) with the barrier film (77, 160) interposed therebetween, and
the semiconductor device further includes: a silicide layer (79, 162) formed at a boundary portion between the semiconductor chip (8, 101) and the barrier film (77, 160) along a side wall and a bottom wall of the contact trench (75, 157).

### [Appendix 5-1]

A semiconductor device (1A, 1B) including:
a semiconductor chip (8, 101) having a first principal surface (10, 102) and a second principal surface (11, 103) opposite to the first principal surface;
a first semiconductor region (46, 121) of a first conductivity type formed on the first principal surface (10, 102) side of the semiconductor chip (8, 101);
a second semiconductor region (47, 122) of a second conductivity type formed on the second principal surface (11, 103) side with respect to the first semiconductor region (46, 121) of the semiconductor chip (8, 101);
a first trench structure (17, 123) including a first trench (48, 126) that penetrates the first semiconductor region (46, 121) from the first principal surface (10, 102) and partitions the first semiconductor region (46, 121) into a first region (19, 107) on one side and a second region (20, 108) on the other side in a first direction (X), a control insulating film (49, 127) that covers an inner wall of the first trench (48, 126), and a control electrode (50, 128) that is embedded in the first trench (48, 126) with the control insulating film (49, 127) interposed therebetween and controls a channel (96, 184) in the second semiconductor region (47, 122) that makes the first region (19, 107) and the second region (20, 108) conductive in the first direction (X);
a control connection structure (18, 124) connected to the control electrode (50, 128), extended from the first trench structure (17, 123) along a second direction (Y) intersecting the first direction (X), and pulled up to the first principal surface (10, 102); and a trench withstand voltage structure (125) formed between the control connection structure (18, 124) and at least one of the first region (19, 107) and the second region (20, 108).

### [Appendix 5-2]

The semiconductor device (1A, 1B) according to Appendix 5-1,
wherein the control connection structure (18, 124) includes a connection trench (56, 134) that penetrates the first semiconductor region (46, 121) from the first principal surface (10, 102) and reaches the second semiconductor region (47, 122), a connection insulating film (57, 135) that covers an inner wall of the connection trench (56, 134), and a trench connection structure (18, 124) that is embedded in the connection trench (56, 134) with the connection insulating film (57, 135) interposed therebetween and includes a connection electrode (58, 136) opposing the first semiconductor region (46, 121) and the second semiconductor region (47, 122).

### [Appendix 5-3]

The semiconductor device (1A, 1B) according to Appendix 5-2,
wherein the trench withstand voltage structure (125) includes a withstand voltage trench (138) that penetrates the first semiconductor region (46, 121) from the first principal surface (10, 102) and reaches the second semiconductor region (47, 122), and a withstand voltage insulator (141) that is embedded in the withstand voltage trench (138) and opposes the first semiconductor region (46, 121).

### [Appendix 5-4]

The semiconductor device (1A, 1B) according to Appendix 5-2,
wherein the control electrode (50, 128) is embedded in the first trench (48, 126) with a space between the first principal surface (10, 102) and a bottom wall side of the first trench (48, 126), and the first trench structure (17, 123) includes a first insulator (51, 129) embedded in the first trench (48, 126) to cover the control electrode (50, 128).

### [Appendix 5-5]

The semiconductor device (1A, 1B) according to Appendix 5-4,
wherein the trench withstand voltage structure (125) includes a withstand voltage trench (138) continuous with the first trench (48, 126), a withstand voltage insulating film (139) covering an inner wall of the withstand voltage trench (138) and integrated with the control insulating film (49, 127), a withstand voltage electrode (140) integrated with the control electrode (50, 128) and embedded in the withstand voltage trench (138) with the withstand voltage insulating film (139) interposed therebetween at a position spaced apart from the first principal surface (10, 102) on a bottom wall side of the withstand voltage trench (138), and a withstand voltage insulator (141) embedded in the withstand voltage trench (138) to cover the withstand voltage electrode (140) and integrated with the first insulator (51, 129).

### [Appendix 5-6]

The semiconductor device (1A, 1B) according to any one of Appendices 5-1 to 5-5,
wherein the first trench structure (17, 123) is formed in a band shape extending along the second direction (Y), and
the trench withstand voltage structure (125) is integrally connected to an end portion of the first trench structure (17, 123) in the second direction (Y), and extends in a bending direction from the end portion of the first trench structure (17, 123) to cover an end portion of at least one of the first region (19, 107) and the second region (20, 108) in the second direction (Y).

### [Appendix 5-7]

The semiconductor device (1A, 1B) according to Appendix 5-6,
wherein a pair of band-shaped first trench structures (17, 123) extending along the second direction (Y) are formed to sandwich the first region (19, 107), and
the trench withstand voltage structure (125) is formed across the pair of first trench structures (17, 123) in the first direction (X), and opposes an end portion of the first region (19, 107) sandwiched between the pair of first trench structures (17, 123) in the second direction (Y).

### [Appendix 5-8]

The semiconductor device (1A, 1B) according to Appendix 5-6 or 5-7,
wherein a pair of band-shaped first trench structures (17, 123) extending along the second direction (Y) are formed to sandwich the second region (20, 108), and the trench withstand voltage structure (125) is formed across the pair of first trench structures (17, 123) in the first direction (X), and opposes an end portion of the second region (20, 108) sandwiched between the pair of first trench structures (17, 123) in the second direction (Y).

### [Appendix 5-9]

The semiconductor device (1A, 1B) according to Appendix 5-2,
wherein the first region (19, 107) and the second region (20, 108) each include a band-shaped first source/drain region (19, 107) and a band-shaped second source/drain region (20, 108) extending along the second direction (Y),
each of the first source/drain region (19, 107) and the second source/drain region (20, 108) is sandwiched between a pair of band-shaped first trench structures (17, 123) in the first direction (X) and is sandwiched between a pair of trench connection structures (18, 124) integrated with the pair of first trench structures (17, 123) in the second direction (Y) to be surrounded by the pair of first trench structures (17, 123) and the pair of trench connection structures (18, 124), and
the trench withstand voltage structure (125) crosses the first source/drain region (19, 107) and the second source/drain region (20, 108) from one first trench structure (17, 123) toward the other first trench structure (17, 123), and divides the first source/drain region (19, 107) and the second source/drain region (20, 108).

### [Appendix 5-10]

The semiconductor device (1A, 1B) according to Appendix 5-9,
wherein the plurality of first source/drain regions (19, 107) and the plurality of second source/drain regions (20, 108) are alternately located at intervals in the first direction (X) such that a drift region (21, 109) is sandwiched between the first source/drain region (19, 107) and the second source/drain region (20, 108) adjacent to each other, and
the semiconductor device further includes: a control wiring layer (113) located in a band-shaped wiring region (111) extending in a direction crossing the vicinity of each end portion of the plurality of first source/drain regions (19, 107) and the plurality of second source/drain regions (20, 108), and
the control wiring layer (113) is located to cover the trench connection structure (18, 124) and not to cover the trench withstand voltage structure (125) in a plan view, and is connected to the connection electrode (58, 136).

### [Appendix 5-11]

The semiconductor device (1A, 1B) according to Appendix 5-10,
wherein a plurality of cell regions (110) in which a plurality of sets of the first source/drain region (19, 107), the second source/drain region (20, 108), and the first trench structure (17, 123) between these are located are formed at intervals in the second direction (Y), and
the wiring region (111) is formed between the adjacent cell regions (110).

### [Appendix 5-12]

The semiconductor device (1A, 1B) according to Appendix 5-11,
wherein a pair of band-shaped control wiring layers (113) extending along the first direction (X) in the wiring region (111) are formed,
one control wiring layer (113) is connected to the connection electrode (58, 136) in the cell region (110) on one side with respect to the wiring region (111), and the other control wiring layer (113) is connected to the connection electrode (58, 136) in the cell region (110) on the other side with respect to the wiring region (111).

### [Appendix 5-13]

The semiconductor device (1A, 1B) according to any one of Appendices 5-9 to 5-12, further including:
a first source/drain electrode (65, 148) connected to the first source/drain region (19, 107); and
a second source/drain electrode (69, 152) connected to the second source/drain region (20, 108).

### [Appendix 5-14]

The semiconductor device (1A, 1B) according to any one of Appendices 5-1 to 5-13,
wherein the semiconductor chip (8, 101) is a semiconductor substrate having no epitaxial layer.

### [Appendix 5-15]

The semiconductor device (1A, 1B) according to any one of Appendices 5-1 to 5-14, wherein the second conductivity type impurity concentration of the second semiconductor region (47, 122) from the second principal surface (11, 103) to the first semiconductor region (46, 121) is 1.0×10²⁰ cm⁻³ or less in the thickness direction of the semiconductor chip (8, 101).

### [Appendix 5-16]

The semiconductor device (1A, 1B) according to any one of Appendices 5-1 to 5-15,
wherein a resistance value of the second semiconductor region (47, 122) is 10 Ω·cm or more and 100 Ω2·cm or less.

1. A semiconductor device comprising:
a semiconductor chip formed of a single layer having a first principal surface and a second principal surface opposite to the first principal surface;
a first semiconductor region of a first conductivity type formed on the first principal surface side of the semiconductor chip;
a second semiconductor region of a second conductivity type formed on the second principal surface side with respect to the first semiconductor region of the semiconductor chip; and
a first trench structure including a first trench that penetrates the first semiconductor region from the first principal surface and partitions the first semiconductor region into a first region on one side and a second region on the other side in a cross-sectional view, a control insulating film that covers an inner wall of the first trench, and a control electrode that is embedded in the first trench with the control insulating film interposed therebetween and controls a channel in the second semiconductor region that makes the first region and the second region conductive in a lateral direction along the first principal surface.

2. The semiconductor device according to claim 1, wherein a second conductivity type impurity concentration of the second semiconductor region from the second principal surface to the first semiconductor region is 1.0×10²⁰ cm⁻³ or less in a thickness direction of the semiconductor chip.

3. The semiconductor device according to claim 1, wherein a second conductivity type impurity concentration of the second semiconductor region from the second principal surface to the first semiconductor region is substantially constant in a thickness direction of the semiconductor chip.

4. The semiconductor device according to claim 1, wherein a second conductivity type impurity concentration of the second semiconductor region is 1.0×10¹³ cm⁻³ or more and 1.0×10¹⁶ cm⁻³ or less over an entire region from the second principal surface to the first semiconductor region in a thickness direction of the semiconductor chip.

5. The semiconductor device according to claim 1, wherein a resistance value of the second semiconductor region is 10 Ω·cm or more and 100 Ω·cm or less.

6. The semiconductor device according to claim 5, wherein a resistance value of the second semiconductor region is 10 Ω·cm or more and 100 Ω·cm or less over an entire region from the second principal surface to the first semiconductor region in a thickness direction of the semiconductor chip.

7. The semiconductor device according to claim 1, wherein the semiconductor chip is a semiconductor substrate having no epitaxial layer.

8. The semiconductor device according to claim 1, wherein a first conductivity type impurity concentration of the first semiconductor region is 1.0×10¹⁴ cm⁻³ or more and 1.0×10¹⁸ cm⁻³ or less.

9. The semiconductor device according to claim 1, further comprising:
an insulating protection film covering the entire second principal surface of the semiconductor chip.

10. The semiconductor device according to claim 1, wherein the second principal surface of the semiconductor chip is an exposed surface.

11. The semiconductor device according to claim 1, wherein a second conductivity type impurity concentration of the second semiconductor region is 1.0×10¹³ cm⁻³ or more and 1.0×10¹⁶ cm⁻³ or less and a resistance value of the second semiconductor region is 10 Ω·cm or more and 100 Ω·cm or less over an entire region from the second principal surface to the first semiconductor region in a thickness direction of the semiconductor chip.

12. The semiconductor device according to claim 11, wherein the semiconductor chip is a semiconductor substrate having no epitaxial layer.

13. The semiconductor device according to claim 11, wherein the semiconductor chip is an Si single crystal substrate or an SiC single crystal substrate having no epitaxial layer.

14. The semiconductor device according to claim 13, further comprising:
an insulating protection film covering the entire second principal surface of the semiconductor chip.

15. The semiconductor device according to claim 1, further comprising:
a drift region sandwiched between the pair of first trench structures,
wherein the first region includes a first source/drain region opposing the drift region with one of the first trench structures interposed therebetween,
the second region includes a second source/drain region opposite to the first source/drain region with the drift region interposed therebetween, and
the semiconductor device further comprises:
a first source/drain electrode electrically connected to the first source/drain region; and
a second source/drain electrode electrically connected to the second source/drain region.
